(19) United States
(12) Patent Application Publication
(10) Pub. No.: US 2022/0107393 A1
(43) Pub. Date: Apr. 7, 2022

(54) LIGHT SOURCE UNIT, LIGHT SOURCE DEVICE, AND DISTANCE MEASURING DEVICE

(71) Applicant: SONY SEMICONDUCTOR SOLUTIONS CORPORATION, KANAGAWA (JP)

(72) Inventor: HIROSHI TSUTSUMITAKE, KANAGAWA (JP)

(21) Appl. No.: 17/310,475

(22) PCT Filed: Dec. 27, 2019
(86) PCT No.: PCT/JP2019/051557

§ 371 Date: Aug. 5, 2021

(30) Foreign Application Priority Data
Feb. 14, 2019 (JP) 2019-024735
Mar. 7, 2019 (JP) 2019-041799

(51) Int. Cl. G01S 7/481; H01S 5/02257; G02B 5/02; G02B 27/09; G01S 17/10

(52) U.S. Cl. CPC G01S 7/4811; H01S 5/02257; G02B 5/0284; H04N 5/232121; G02B 27/0983; G01S 17/10; G02B 5/021

(57) ABSTRACT

Provided is a light source unit capable of enhancing safety and/or generating reflected light having a desired cross-sectional shape, a light source device, and a distance measuring device including the light source unit or the light source device. The light source unit according to the present technology includes a light source and a holder that holds the light source. The holder has a diffuse reflection surface that reflects and diffuses at least part of light from the light source toward an object. The light source device according to the present technology includes a light source and a reflection member that reflects at least part of light from the light source to generate reflected light, in which the reflection member includes a plurality of curved mirrors regularly arranged along a reference plane that the light from the light source enters, and each of the plurality of curved mirrors has curvatures in a first axis direction and a second axis direction orthogonal to each other in the reference plane.

### TECHNICAL FIELD

The technology according to the present disclosure (hereinafter, also referred to as “present technology”) relates to a light source unit, a light source device, and a distance measuring device. More specifically, the present disclosure relates to a light source unit, a light source device, and the like that irradiate an object with light.

### BACKGROUND ART

Patent Document 1 discloses a light emitting device including a light source and a diffuser plate that diffuses and transmits light from the light source toward an object.

Patent Document 2 discloses a technology for generating reflected light by reflecting light from a light source with a reflective diffuser plate.

### CITATION LIST

### Patent Document

### Patent Document 1: Japanese Patent Application Laid-Open No. 2013-11511

### Patent Document 2: Japanese Patent Application Laid-Open No. 2016-186601

### SUMMARY OF THE INVENTION

### Problems to be Solved by the Invention

In the light emitting device disclosed in Patent Document 1, there is room for improvement in terms of enhancing safety.

In the technology disclosed in Patent Document 2, there is room for improvement in generating reflected light having a desired cross-sectional shape.

Therefore, an object of the present technology is to provide a light source unit capable of enhancing safety and/or generating reflected light having a desired cross-sectional shape, a light source device, and a distance measuring device including the light source unit or the light source device.

### Solutions to Problems

The present technology provides a light source unit including a light source and a holder configured to hold the light source, in which the holder has a diffuse reflection surface that reflects and diffuses at least part of light from the light source toward an object.

In the light source unit according to the present technology, at least part of the light from the light source is reflected and diffused by the diffuse reflection surface (is changed in a traveling direction) and heads toward the object. In this case, even if the diffuse reflection surface is damaged or falls off, at least part of the light from the light source is not diffused by the diffuse reflection surface and goes in a direction different from the direction toward the object.

The holder may have a recess in which the light source is housed, and the diffuse reflection surface may be located in the recess, and reflect and diffuse the at least part of light from the light source toward an opening of the recess.

The holder may have a window that covers the opening of the recess.

The diffuse reflection surface may be inclined with respect to an emission direction of the light source.

An inclination angle of the diffuse reflection surface with respect to the emission direction of the light source may be 30° to 60°.

An emission surface of the light source and the diffuse reflection surface may face each other.

The light emitted from the light source may directly enter the diffuse reflection surface.

The light source may be provided on a bottom surface of the recess, and an angle made by the emission direction of the light source with respect to the bottom surface may be 0° to 45°.

The diffuse reflection surface may be located between the light source and a part of a peripheral wall of the recess.

The peripheral wall of the recess may have a light-shielding property.

At least a part of an inner peripheral surface of the peripheral wall of the recess may have a light attenuation function.

The diffuse reflection surface may be provided on the peripheral wall of the recess.

The diffuse reflection surface may be provided on the window.

The diffuse reflection surface may be provided on the bottom surface of the recess.

The holder may include a diffuse reflection portion having the diffuse reflection surface, and at least one surface of the diffuse reflection portion other than the diffuse reflection surface may have the light attenuation function.

The light attenuation function is implemented by any one of fine unevenness processing, an antireflection film, and black coating.

The holder may include the diffuse reflection portion having the diffuse reflection surface, and the light source unit may further include a light receiving element that receives at least part of the light emitted from the light source and via the diffuse reflection portion.

The light source may be a laser light source.

The present technology also provides a distance measuring device including the light source unit, a light receiving unit configured to receive light emitted from the light source unit and reflected by an object, and a control unit configured to calculate a distance to the object on the basis of at least an output of the light receiving unit.

The light receiving unit may include a sensor having a first light receiving region that receives light emitted from the light source unit and reflected by an object and a second light receiving region that receives light emitted from the light source and via the diffuse reflection surface.

The present technology also provides a light source device including a light source, and a reflection member configured to reflect at least part of light from the light source to generate reflected light, in which the reflection member includes a plurality of curved mirrors regularly arranged along a reference plane that the light from the light source enters, and each of the plurality of curved mirrors has curvatures in a first axis direction and a second axis direction orthogonal to each other in the reference plane.

In the light source device according to the present technology, the light from the light source enters the plurality of curved mirrors regularly arranged along the reference plane. The light having entered each curved mirror is reflected and diffused in a direction corresponding to the first axis direction and a direction corresponding to the second axis direction while maintaining regularity with each other.

The plurality of curved mirrors may be regularly arranged according to a target shape of a cross section perpendicular to an optical axis of the reflected light.

Each of the plurality of curved mirrors may be inclined with respect to the reference plane, and a shape viewed from a third axis direction orthogonal to the first axis direction may be a shape according to the target shape of a cross section perpendicular to an optical axis of the reflected light.

The third axis direction may approximately coincide with an optical axis direction of the light from the light source.

In each of the plurality of curved mirrors, a length in the first axis direction of the shape viewed from the third axis direction, a length in a fourth axis direction orthogonal to both the first axis direction and the third axis direction in the shape viewed from the third axis direction, a curvature in the first axis direction, and a curvature in the second axis direction may be set according to a ratio of a length in a direction corresponding to the first axis direction and a length in a direction corresponding to the fourth axis direction in the target shape.

In each of the plurality of curved mirrors, a ratio of the length in the fourth axis direction orthogonal to both the first axis direction and the third axis direction to the length in the first axis direction in the shape viewed from the third axis direction may be equal to a ratio of the length in a direction corresponding to the fourth axis direction to the length in a direction corresponding to the first axis direction in the target shape, the curvatures in the first axis direction may be equal to each other, and the curvatures in the second axis direction may be equal to each other.

The plurality of curved mirrors may be at least three curved mirrors, and may be two-dimensionally arranged as viewed from the third axis direction.

The plurality of curved mirrors may be at least four curved mirrors and may be arranged in a two-dimensional grid manner in the first axis direction and in the fourth axis direction orthogonal to both the first axis direction and the third axis direction as viewed from the third axis direction.

The plurality of curved mirrors may include the curved mirrors having curvatures with opposite positive and negative properties in the first axis direction and the second axis direction.

The positive and negative properties of the curvatures in the first axis direction of at least the two curved mirrors arranged in the fourth axis direction as viewed from the third axis direction may be equal to each other, and the positive and negative properties of the curvatures in the second axis direction of at least the two curved mirrors arranged in the first axis direction as viewed from the third axis direction may be equal to each other.

At least one of the plurality of curved mirrors may have a convex curve shape in a cut end cut in a plane orthogonal to the fourth axis direction orthogonal to both the first axis direction and the third axis direction, and 0°<α≤60° may be satisfied where an angle formed by a tangent line at each end of a convex curve drawn by the cut end and a line segment connecting both ends of the convex curve is α/2.

At least one of the plurality of curved mirrors may have a convex curve shape in a cut end cut in a plane orthogonal to the first axis direction, and 0°<β≤60°−(⅔)φ may be satisfied where an angle formed by a tangent line at each end of a convex curve drawn by the cut end and a line segment connecting both ends of the convex curve is β/2, and an angle formed by the fourth axis direction orthogonal to both the first axis direction and the third axis direction as viewed from the first axis direction with respect to the reference plane is 90°−φ.

At least one of the plurality of curved mirrors may have a concave curve shape in a cut end cut in the plane orthogonal to the fourth axis direction orthogonal to both the first axis direction and the third axis direction, and 0°<α≤90° may be satisfied where an angle formed by a tangent line at each end of a concave curve drawn by the cut end and a line segment connecting both ends of the concave curve is α/2.

At least one of the plurality of curved mirrors may have a concave curve shape in a cut end cut in the plane orthogonal to the first axis direction, and 0°<β≤90°−φ may be satisfied where the angle formed by a tangent line at each end of a concave curve drawn by the cut end and a line segment connecting both ends of the concave curve is β/2, and the angle formed by the fourth axis direction orthogonal to both the first axis direction and the third axis direction as viewed from the first axis direction with respect to the reference plane is 90°−φ.

The cut end may have an arc shape.

The plurality of curved mirrors may be set to have curvatures in the first axis direction that are equal to each other and have curvatures in the second axis direction that are equal to each other.

In the plurality of curved mirrors, the ratios of the length in the fourth axis direction orthogonal to both the first axis direction and the third axis direction with respect to the length in the first axis direction in the shape viewed from the third axis direction may be set to be equal to each other.

In the plurality of curved mirrors, the lengths in the first axis direction may be equal to each other and the lengths in the fourth axis direction may be equal to each other in the shape viewed from the third axis direction.

The light source may be a laser light source.

The present technology provides a distance measuring device including the light source device, a light receiving device configured to receive light emitted from the light source device and reflected by an object, and a control device configured to calculate a distance to the object on the basis of an output of the light receiving device.

### BRIEF DESCRIPTION OF DRAWINGS

FIG. 1A is a plan view schematically illustrating a configuration of a distance measuring device according to a first embodiment of the present technology. FIG. 1B is a sectional view taken along line A-A of FIG. 1A.

FIG. 2 is a cross-sectional view schematically illustrating a configuration of a light source unit of a comparative example.

FIG. 3 is a cross-sectional view illustrating a state in which a diffuser plate of the light source unit of the comparative example is removed.

FIG. 4 is a cross-sectional view schematically illustrating a configuration of a light source unit included in the distance measuring device according to the first embodiment.

FIG. 5 is a cross-sectional view illustrating a state in which a transmissive member of the light source unit included in the distance measuring device according to the first embodiment is detached from a package.

FIG. 6 is a cross-sectional view illustrating a state in which a diffuse reflection member of the light source unit included in the distance measuring device according to the first embodiment is displaced.

FIG. 7 is a cross-sectional view schematically illustrating a configuration of a light source unit of a second embodiment.

FIG. 8 is a cross-sectional view illustrating a state in which a transmissive member and a diffuse reflection member of the light source unit of the second embodiment are detached from a package.

FIG. 9 is a cross-sectional view illustrating a state in which the diffuse reflection member of the light source unit of the second embodiment is detached from the transmissive member.

FIG. 10 is a cross-sectional view schematically illustrating a configuration of a light source unit of a third embodiment.

FIG. 11 is a cross-sectional view illustrating a state in which a transmissive member of the light source unit of the third embodiment is detached from a package.

FIG. 12 is a cross-sectional view illustrating a state in which a diffuse reflection member of the light source unit of the third embodiment is detached from a peripheral wall.

FIG. 13 is a cross-sectional view schematically illustrating a configuration of a light source unit of a modification of the third embodiment.

FIG. 14 is a cross-sectional view schematically illustrating a configuration of a light source unit of a fourth embodiment.

FIG. 15 is a cross-sectional view schematically illustrating a configuration of a light source unit of a fifth embodiment.

FIG. 16 is a cross-sectional view schematically illustrating a configuration of a light source unit of a sixth embodiment.

FIG. 17A is a plan view schematically illustrating a configuration of a distance measuring device according to a seventh embodiment of the present technology. FIG. 17B is a sectional view taken along line B-B of FIG. 17A.

FIG. 18A is a plan view schematically illustrating a configuration of a distance measuring device according to an eighth embodiment of the present technology. FIG. 18B is a sectional view taken along line A-A of FIG. 18A.

FIG. 19 is a cross-sectional view schematically illustrating a configuration of a light source device according to the eighth embodiment.

FIGS. 20A and 20B are diagrams for describing a perfect diffuse reflector.

FIG. 21 is a diagram illustrating a state in which desired reflected light (irradiation light) is generated by the light source device according to the eighth embodiment.

FIG. 22 is a diagram for describing a change in a reflection angle of reflected light by rotating a plane mirror by an angle δ.

FIG. 23 is a diagram illustrating a relationship between an arbitrary cross section parallel to a C cross section of a convex mirror of a reflection member of the eighth embodiment and a diffusion angle of light by the cross section.

FIG. 24 is a diagram illustrating a relationship between an arbitrary cross section parallel to a B cross section of a convex mirror of the reflection member of the eighth embodiment and a diffusion angle of light by the cross section.

FIG. 25 is a view of the reflection member of the eighth embodiment viewed from a direction orthogonal to a reference plane.

FIG. 26 is a view of the reflection member of the eighth embodiment as viewed from an optical axis direction of light from a light source.

FIG. 27 is a process diagram (No. 1) for describing a method of manufacturing the reflection member according to the eighth embodiment.

FIGS. 28A to 28C are process diagrams (No. 2 to No. 4) for describing the method for manufacturing the reflection member according to the eighth embodiment.

FIGS. 29A to 29C are process diagrams (No. 5 to No. 7) for describing the method for manufacturing the reflection member according to the eighth embodiment.

FIG. 30A is a perspective view of a reflection member of a ninth embodiment, FIG. 30B is a view of the reflection member of the ninth embodiment as viewed from a direction orthogonal to a reference plane, and FIG. 30C is a view of the reflection member of the ninth embodiment as viewed from an optical axis direction of light from the light source.

FIG. 31 is a diagram illustrating a relationship between an arbitrary cross section parallel to a C cross section of a concave mirror of the reflection member of the ninth embodiment and a diffusion angle of light by the cross section.

FIG. 32 is a diagram illustrating a relationship between an arbitrary cross section parallel to a B cross section of a concave mirror of the reflection member of the ninth embodiment and a diffusion angle of light by the cross section.

FIG. 33A is a view of a reflection member of Example 1 of a tenth embodiment as viewed from a direction orthogonal to a reference plane, FIG. 33B is a view of a reflection member of an example 2 of the tenth embodiment as viewed from a direction orthogonal to a reference plane, and FIG. 33C is a view of the reflection member of Example 1 or 2 of the tenth embodiment as viewed from an optical axis direction of light from a light source. FIG. 33D is a perspective view of the reflection member of Example 1 of the tenth embodiment. FIG. 33E is a perspective view of the reflection member of Example 2 of the tenth embodiment.

FIG. 34 is a diagram for describing a change in a reflection angle of light at a reflection surface by a spread angle of emitted light of a light source.

FIG. 35 is a diagram illustrating an example in which a collimator lens is arranged between a light source and a reflection member.

FIG. 36 is a diagram for describing a method of correcting an angle of a reflection surface with respect to a spread angle of emitted light of a light source.

FIGS. 37A to 37C are diagrams illustrating arrangement examples (No. 1 to No. 3) of curved mirrors in respective reflection members.

FIG. 38A is a plan view schematically illustrating a configuration of a distance measuring device according to an eleventh embodiment. FIG. 38B is a sectional view taken along line B-B of FIG. 38A.

FIG. 39 is a block diagram illustrating an example of a schematic configuration of a vehicle control system.

FIG. 40 is an explanatory diagram illustrating an example of installation positions of a vehicle exterior information detection unit and an imaging unit.

FIG. 41 is a diagram schematically illustrating an overall configuration of an operating room system.

FIG. 42 is a diagram illustrating a display example of an operation screen on a centralized operation panel.

FIG. 43 is a diagram illustrating an example of a state of a surgical operation to which the operating room system is applied.

FIG. 44 is a block diagram illustrating an example of functional configurations of a camera head and a CCU illustrated in FIG. 43.

### MODE FOR CARRYING OUT THE INVENTION

A favorable embodiment of the present technology will be described in detail with reference to the appended drawings. Note that, in the present specification and drawings, redundant description of configuration elements having substantially the same functional configuration is omitted by providing the same sign. The embodiments below describe representative embodiments of the present technology, and the scope of the present technology is not construed in a narrow manner by the embodiments. Even in the case where it is described in the present specification that each of the light source unit, the light source device, and the distance measuring device according to the present technology has a plurality of effects, each of the light source unit, the light source device, and the distance measuring device according to the present technology may have at least one effect. The effects described in the present specification are merely examples and are not limited, and other effects may be exhibited.

Furthermore, description will be given in the following order.

1. Configuration of Distance Measuring Device According to First Embodiment of Present Technology

(1) Configuration of Light Source Unit

(2) Configuration of Light Receiving Unit

(3) Configuration of Control Unit

2. Operation of Distance Measuring Device According to First Embodiment of Present Technology

(1) Operation of Light Source Unit

(2) Operation of Light Receiving Unit

(3) Operation of Control Unit

3. Effect of Distance Measuring Device According to First Embodiment of Present Technology

(1) Effect of Light Source Unit

(2) Effect of Distance Measuring Device

4. Light Source Unit According to Second Embodiment of Present Technology

(1) Configuration of Light Source Unit

(2) Effect of Light Source Unit

5. Light Source Unit According to Third Embodiment of Present Technology

(1) Configuration of Light Source Unit

(2) Effect of Light Source Unit

6. Light Source Unit According to Modification of Third Embodiment of Present Technology

(1) Configuration of Light Source Unit

(2) Effect of Light Source Unit

7. Light Source Unit According to Fourth Embodiment of Present Technology

(1) Configuration of Light Source Unit

(2) Effect of Light Source Unit

8. Light Source Unit According to Fifth Embodiment of Present Technology

(1) Configuration of Light Source Unit

(2) Effect of Light Source Unit

9. Light Source Unit According to Sixth Embodiment of Present Technology

(1) Configuration of Light Source Unit

(2) Effect of Light Source Unit

10. Effect Common to Light Source Units According to Fourth to Sixth Embodiments of Present Technology

11. Distance Measuring Device According to Seventh Embodiment of Present Technology

(1) Configuration of Distance Measuring Device

(2) Operation of Distance Measuring Device

(3) Effect of Distance Measuring Device and Object System

12. Configuration of Distance Measuring Device According to Eighth Embodiment of Present Technology

(1) Overall Configuration of Distance Measuring Device

(2) Overall Configuration of Light Source Device

(3) Configuration of Light Receiving Device

(4) Configuration of Control Device

(5) Configuration of Reflection Member

(6) Method of Manufacturing Reflection Member

13. Operation of Distance Measuring Device According to Eighth Embodiment of Present Technology

(1) Overall Operation of Distance Measuring Device

(2) Operation of Light Source Device

(3) Operation of Light Receiving Device

(4) Operation of Control Device

14. Effect of Distance Measuring Device According to Eighth Embodiment of Present Technology

(1) Effect of Light Source Device

(2) Effect of Distance Measuring Device and Object System

15. Reflection Member According to Ninth Embodiment of Present Technology

16. Reflection Member According to Tenth Embodiment of Present Technology

(1) Reflection Member of Example 1

(2) Reflection Member of Example 2

17. Light Source Device According to Modification of Present Technology

18. Distance Measuring Device According to Eleventh Embodiment of Present Technology

(1) Configuration of Distance Measuring Device

(2) Operation of Distance Measuring Device

(3) Effect of Distance Measuring Device and Object System

19. Applications to Moving Bodies

20. Applications to Operating Room System

21. Applications to Image Display Device

1. Configuration of Distance Measuring Device According to First Embodiment of Present Technology

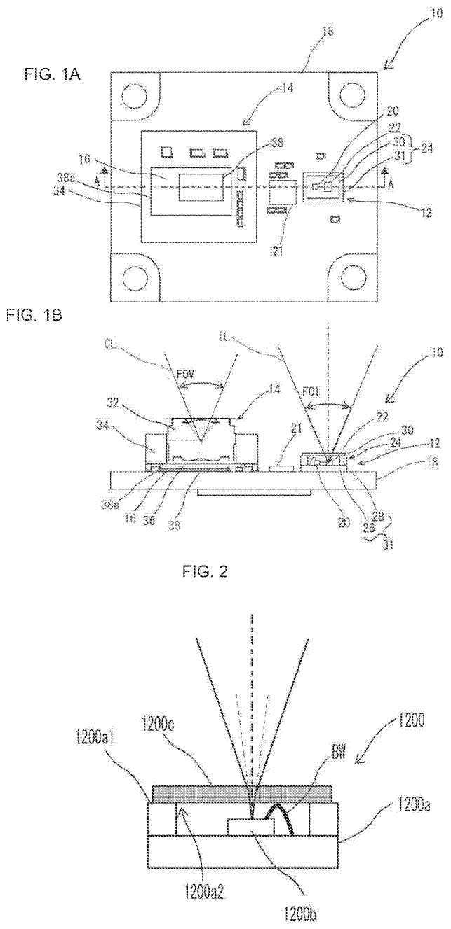

FIG. 1A is a plan view of a distance measuring device 10 according to a first embodiment of the present technology. FIG. 1B is a sectional view taken along line A-A of FIG. 1A. The distance measuring device 10 is used to, for example, measure a distance to an object, a shape of the object, and the like. Note that, in FIG. 1A, illustration of some members (lens unit 32, bandpass filter 36, and the like) illustrated in FIG. 1B is omitted from the viewpoint of avoiding complexity of the drawings.

The distance measuring device 10 is mounted on an object. Examples of the object on which the distance measuring device is mounted include moving bodies such as vehicles, aircrafts (including drones), ship, and robots, and electronic devices such as smartphones and tablets. An object system is configured by including the distance measuring device 10 and the object (for example, a moving body, an electronic device, or the like) on which the distance measuring device 10 is mounted.

As illustrated in FIGS. 1A and 1B, the distance measuring device 10 includes a light source unit 12 that irradiates an object with light, a light receiving unit 14 that receives reflected light from the object, and a control unit 16 that controls the light source unit 12 and the light receiving unit 14. That is, the distance measuring device 10 is a distance measuring device using the principle of time of flight (TOF) having light emitting/receiving and calculating functions. The light source unit 12, the light receiving unit 14, and the control unit 16 are mounted on a same circuit board 18. Moreover, a multi-pin connector for supplying power and exchanging data with an outside is mounted on the circuit board 18. Note that at least two of the light source unit 12, the light receiving unit 14, and the control unit 16 do not have to be mounted on the same circuit board.

By the way, in a light source unit 1200 of a comparative example illustrated in FIG. 2, a laser light source 1200b is mounted on a bottom surface of a package 1200a having an approximately U-shape in cross section such that an emission direction of the laser light source 1200b faces an opposite side of a bottom surface side (an opening 1200a2 side of the package 1200a). A transmissive diffuser plate 1200c is attached to an opening end 1200a1 of the package 1200a so as to cover the opening 1200a2. In the light source unit 1200 of the comparative example, the diffuser plate 1200c having a light transmissive property also functions as a sealing member for sealing an inside of the package 1200a. At least part of light emitted from the laser light source 1200b is transmitted through the diffuser plate 1200c while being diffused by the diffuser plate 1200c.

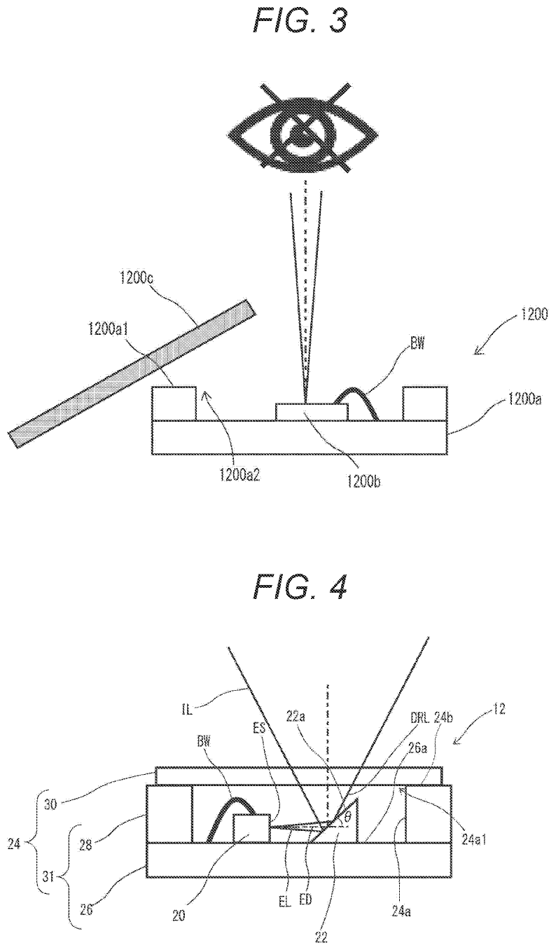

Here, if a strong impact is applied to a device in which the light source unit 1200 of the comparative example is mounted and the diffuser plate 1200c is damaged or falls off the package 1200a, there is a possibility that the laser light from the laser light source 1200b is not diffused and the object is irradiated with the laser light as is (with high intensity) (see FIG. 3). That is, there is room for improving safety in the light source unit 1200 of the comparative example. The light emitting device disclosed in Patent Document 1 also has room for improving safety as in the light source unit 1200 of the comparative example.

Therefore, after diligent studies, the inventor has succeeded in developing the light source unit 12 capable of improving safety, as will be described in detail below.

(1) Configuration of Light Source Unit

As illustrated in FIG. 4, the light source unit 12 includes a light source 20 and a holder 24 that holds the light source 20.

As the light source 20, for example, a laser light source such as an end face emitting-type semiconductor laser (laser diode: LD) or a surface emitting-type semiconductor laser (surface emitting laser: VCSEL) is used. The light source 20 is mounted on a substrate 26 by die bonding, and is electrically connected to wiring on the substrate 26 by a bonding wire BW. Here, for example, infrared light is used as emitted light EL of the light source 20, but light in another wavelength band may be used. The light source 20 is driven by a light source drive circuit 21 (driver circuit). Here, the light source drive circuit 21 is arranged at a position on the circuit board 18 between the light source unit 12 and the light receiving unit 14 (see FIGS. 1A and 1B).

Note that the light source 20 may be a light source other than the laser light source (for example, a light emitting diode: LED) but the light source 20 is favorably a light source that emits high-power light such as a laser light source.

The holder 24 has a diffuse reflection surface 22a that reflects and diffuses at least part of the light from the light source 20 toward an object.

That is, the light source unit 12 irradiates the object with at least part of the light (diffused reflected light DRL) emitted from the light source 20 and reflected and diffused by the diffuse reflection surface 22a as irradiation light IL.

More specifically, the holder 24 has a recess 24a in which the light source 20 is housed. The diffuse reflection surface 22a is located in the recess 24a and reflects and diffuses at least part of the light from the light source 20 toward an opening 24a1 of the recess 24a.

Moreover, the holder 24 has a window 30 that covers the opening 24a1 of the recess 24a. At least part of the light (diffused reflected light DRL) emitted from the light source 20 and reflected and diffused by the diffuse reflection surface 22a toward the opening 24a1 is transmitted through the window 30. The light transmitted through the window 30, of the diffused reflected light DRL, is the irradiation light IL.

More specifically, the holder 24 is provided on the circuit board 18 (see FIGS. 1A and 1B), and includes a package 31 having the recess 24a, a diffuse reflection member 22 having the diffuse reflection surface 22a, and a transmissive member as the window 30 (hereinafter also called “transmissive member 30”).

The package 31 is an open box-shaped member, and has a substrate 26 (base member) having the bottom surface of the recess 24a as one surface, and a peripheral wall 28 having an inner peripheral surface of the recess 24a as an inner peripheral surface. The substrate 26 and the peripheral wall 28 are integrally formed using a material such as ceramic. Note that, in the package 31, the substrate 26 and the peripheral wall 28 may be separate bodies.

The light source 20 and the diffuse reflection member 22 are mounted on one surface (substrate surface) of the substrate 26, that is, on the bottom surface of the recess 24a. Hereinafter, the one surface of the substrate 26 (the bottom surface of the recess 24a) on which at least the light source 20 is mounted is also referred to as a “mounting surface 26a”.

The peripheral wall 28 is provided on the mounting surface 26a so as to surround the light source 20 and the diffuse reflection member 22.

As an example, the transmissive member 30 is a glass-made or resin-made plate-shaped member having a light transmissive property, and is attached using an adhesive or the like to an opening end surface 24b (an end surface of the peripheral wall 28 on the opposite side of an end surface on the substrate 26 side) of the holder 24 so as to cover the opening 24a1. The transmittance or reflectance of the transmissive member 30 is set so as to transmit most (for example, 99% or more) of the light in a wavelength band (for example, an infrared region) of the emitted light EL of the light source 20.

The light source 20 and the diffuse reflection member 22 are sealed in the package 31 by the transmissive member 30. Thereby, invasion of foreign substances (for example, grit and dust, and moisture) into the package 31 can be suppressed and the parts (the light source 20, the diffuse reflection member 22, and the like) in the package 31 can be protected (for example, adhesion of foreign substances to the light source 20 or the diffuse reflection member 22 can be suppressed, and occurrence of problems such as short-circuit of wiring due to the invaded foreign substances can be suppressed).

The diffuse reflection member 22 is mounted on the mounting surface 26a such that the diffuse reflection surface 22a is located on an optical path of the light from the light source 20. The diffuse reflection surface 22a is inclined with respect to an emission direction ED of the light source 20. That is, the diffuse reflection surface 22a is inclined with respect to an emission surface ES of the light source 20 (for example, a semiconductor laser). Note that, since a semiconductor laser such as an LD and a VCSEL emits light from the emission surface perpendicularly to the emission surface, the emission surface is also inclined with respect to the diffuse reflection surface in the case where the emission direction is inclined with respect to the diffuse reflection surface.

An inclination angle θ of the diffuse reflection surface 22a with respect to the emission direction ED of the light source 20 is favorably 30° to 60°, and more favorably 40° to 50°, in order to obtain a necessary and sufficient irradiation angle range for the object.

Therefore, in the present embodiment, as an example, the inclination angle θ of the diffuse reflection surface 22a with respect to the emission direction ED of the light source 20 is set to approximately 45°.

Moreover, the angle formed by the emission direction ED of the light source 20 with respect to the mounting surface 26a is favorably 0° to 45°, more favorably 0° to 30°, and even more favorably 0° to 15° from the viewpoint of suppressing the height of the peripheral wall 28 and reducing the thickness of the light source unit 12. The emission direction of the light source 20 may be shifted (inclined) toward the transmissive member 30 side or may be shifted (inclined) toward the substrate 26 side from the direction parallel to the mounting surface 26a.

Therefore, in the present embodiment, as an example, the light source 20 is mounted on the mounting surface 26a such that the angle formed by the emission direction ED with respect to the mounting surface 26a becomes approximately 0°, that is, the emission direction ED goes along (approximately parallel to) the mounting surface 26a.

In this case, since the inclination angle θ of the diffuse reflection surface 22a with respect to the emission direction ED of the light source 20 is approximately 45° as described above, the diffuse reflection surface 22a is also inclined at approximately 45° with respect to the mounting surface 26a.

The emission surface ES of the light source 20 and the diffuse reflection surface 22a face each other. That is, the emission direction ED of the light source 20 faces the diffuse reflection surface 22a side.

The emission surface ES of the light source 20 does not face the transmissive member 30. That is, the emission direction ED of the light source 20 does not face the transmissive member 30 side.

The diffuse reflection surface 22a faces the transmissive member 30 in addition to the emission surface ES.

No other optical members (lenses, mirrors, and the like) are interposed between the light source 20 and the diffuse reflection surface 22a. In this case, the light emitted from the light source 20 (emitted light EL) directly enters the diffuse reflection surface 22a. Therefore, the distance between the light source 20 and the diffuse reflection surface 22a can be shortened, and the light source unit 12 can be downsized. Note that other optical members (lenses, mirrors, and the like) may be interposed on the optical path between the light source 20 and the diffuse reflection surface 22a.

When other optical members (lenses, mirrors, and the like) are interposed between the light source 20 and the diffuse reflection surface 22a, the emission surface ES of the light source 20 does not necessarily have to face the diffuse reflection surface 22a.

As an example, the diffuse reflection member 22 is formed using a triangular prism-shaped member having a right-angled triangular cross section with the diffuse reflection surface 22a as an inclined surface. The diffuse reflection member 22 is manufactured by forming (coating), for example, Spectralon (a material for the diffuse reflection surface 22a) on the inclined surface of a triangular prism-shaped base material having a right-angled triangular cross section formed using a transparent or translucent material (a material having a light transmissive property) such as glass or resin. The diffuse reflection member 22 has a similar diffuse reflection property to a general-purpose standard diffuse reflector. That is, the diffuse reflection surface 22a substantially uniformly reflects the incident light (Lambertian reflection) toward the entire region of a predetermined range.

Note that the shape of the diffuse reflection member 22 is not limited to the above shape and can be changed as appropriate.

The diffuse reflection member 22 does not necessarily have a similar function to the standard diffuse reflector.

For example, the diffuse reflection surface 22a may be formed by performing fine unevenness processing (roughing) for the inclined surface of the base material.

For example, as the diffuse reflection member 22, a member having convex mirrors or concave mirrors may be used. Specifically, as the diffuse reflection member 22, a member in which convex mirrors or concave mirrors are two-dimensionally arranged may be used.

In the present embodiment, the diffuse reflection surface 22a is one surface of the diffuse reflection member 22 provided on the substrate 26. That is, the diffuse reflection surface 22a is provided on the substrate 26.

As described above, the diffuse reflection surface 22a is one surface of the diffuse reflection member 22 that is a separate body from the substrate 26. However, for example, a protrusion corresponding to the base material of the diffuse reflection member may be formed on the substrate, and the diffuse reflection surface may be formed on one surface of the protrusion. That is, the diffuse reflection surface may be a part of the substrate. In this case, although it takes some time to manufacture the substrate, the number of parts can be reduced and the diffuse reflection surface can be prevented from coming off the substrate, as compared with the case where the diffuse reflection member is provided on the substrate.

The diffuse reflection surface 22a favorably reflects and diffuses 60% or more of the light from the light source 20, more favorably 75% or more, and even more favorably 90% or more.

Therefore, in the present embodiment, as an example, the reflectance or transmittance of the diffuse reflection surface 22a is set so as to reflect and diffuse 99% or more of the light from the light source 20.

Note that the diffuse reflection surface 22a may reflect and diffuse less than 60% of the light from the light source 20.

In the light source unit 12 configured as described above, the light (emitted light EL) emitted from the light source 20 directly enters the diffuse reflection surface 22a, and at least part (for example, 99%) of the incident light is reflected and diffused by the diffuse reflection surface 22a. The light (diffused reflected light DRL) reflected and diffused by the diffuse reflection surface 22a enters the transmissive member 30, and at least part (for example, 99%) of the light is transmitted through the transmissive member 30. The light having been reflected and diffused by the diffuse reflection surface 22a and having transmitted through the transmissive member 30 is the irradiation light IL to be radiated to the object.

Here, since the emission direction ED of the light source 20 does not face the transmissive member 30 side, the light (emitted light EL) emitted from the light source 20 does not directly go to the transmissive member 30 even if an abnormal situation occurs, for example, a strong impact is applied to the light source unit 12, and the diffuse reflection member 22 is damaged or falls off the package 31. Therefore, the light emitted from the light source 20 (emitted light EL) is not directly radiated to the object (via only the transmissive member 30).

However, there is a possibility that the light emitted from the light source 20 enters a surface other than the diffuse reflection surface 22a of the diffuse reflection member 22 in the case where the abnormal situation occurs. At this time, in the case where the surface other than the diffuse reflection surface 22a is a mirror, for example, there is a possibility that the light emitted from the light source 20 and reflected by the mirror is transmitted through the transmissive member 30 and radiated to the object.

Therefore, in the present embodiment, at least one surface of the diffuse reflection member 22 other than the diffuse reflection surface 22a is provided with a light attenuation function. This light attenuation function is implemented by providing fine irregularities (the surface is roughened), forming an antireflection film, or applying black coating.

Furthermore, the diffuse reflection surface 22a is located between the light source 20 and a part of the peripheral wall 28. Therefore, in the case where an abnormal situation occurs, there is a possibility that the emitted light EL of the light source 20 is transmitted through the peripheral wall 28 without through the diffuse reflection surface 22a and leaks to the outside.

Therefore, in the present embodiment, a light-shielding function of the peripheral wall 28 is enhanced to prevent the emitted light EL of the light source 20 from leaking to the outside when the abnormal situation occurs.

Specifically, the height of the peripheral wall 28 is set such that all the emitted light EL of the light source 20 enters the peripheral wall 28 even if the abnormal situation occurs and the diffuse reflection surface 22a ceases to lie between the light source 20 and a part of the peripheral wall 28.

Furthermore, to suppress the light emitted from the light source 20 and having entered the peripheral wall 28 from being transmitted through the peripheral wall 28, a material having a relatively high light-shielding property is used for the material of the peripheral wall 28 (the material of the package 31).

In the case where the material of the peripheral wall 28 (the material of the package 31) is a material capable of sufficiently blocking the emitted light EL of the light source 20, the thickness of the peripheral wall 28 may be arbitrary. In the case where the material of the peripheral wall 28 is not the material capable of sufficiently blocking the emitted light EL of the light source, the thickness of the peripheral wall 28 is favorably set to a thickness that can sufficiently attenuate the emitted light EL of the light source 20 (a thickness that can sufficiently attenuate the intensity of the light transmitted through the peripheral wall 28).

Furthermore, the light emitted from the light source 20 and reflected by a part of the peripheral wall 28 may be directly radiated to the object or may be further reflected by another part of the peripheral wall 28 and transmitted through the transmissive member 30 and radiated to the object.

Therefore, in the present embodiment, at least a part of an inner peripheral surface of the peripheral wall 28 is provided with a light attenuation function. This light attenuation function is implemented by providing fine irregularities (the surface is roughened), forming an antireflection film, or applying black coating.

With the light attenuation function, even if the above abnormal situation occurs and the diffuse reflection member 22 ceases to lie between the light source 20 and a part of the peripheral wall 28, the intensity of the light emitted from the light source 20 and reflected by the peripheral wall 28 is sufficiently attenuated. Therefore, even if the light is transmitted through the transmissive member 30 and radiated to the object, the safety is not impaired.

Note that, in the holder 24, the recess 24a and the window 30 are not essential. That is, in the holder 24, the peripheral wall 28 and the transmissive member 30 are not essential. The holder 24 may be configured by only the substrate 26. The holder 24 may be configured by only the substrate 26 and the peripheral wall 28, that is, only the package 31. In the holder 24, the substrate 26 is used as the base member on which the light source 20 is mounted, but a member other than the substrate (for example, a non-plate-shaped member) may be used.

(2) Configuration of Light Receiving Unit

The light receiving unit 14 of the first embodiment includes the lens unit 32, a lens holder 34, the bandpass filter 36, and an image sensor 38, as illustrated in FIGS. 1A and 1B.

The image sensor 38 is provided on a sensor board 38a (semiconductor board) mounted on the circuit board 18, and includes a plurality of two-dimensionally arrayed pixels. The image sensor 38 is also called area image sensor.

Each pixel of the image sensor 38 includes a light receiving element (for example, a photodiode: PD), and the pixels are electrically connected to a circuit on the circuit board 18 by wire bonding.

The lens holder 34 is fixed to the circuit board 18 so as to surround the image sensor 38.

The lens unit 32 includes at least one lens element and is held in the lens holder 34 so as to be focused on the image sensor 38.

The bandpass filter 36 fixed to the lens holder 34 is arranged between the image sensor 38 and the lens unit 32. Thereby, only the light having a wavelength near the wavelength of the emitted light EL of the light source 20 (the light in a predetermined frequency band, for example, infrared light), of the light reflected by the object and passing through the lens unit 32, is transmitted through the bandpass filter 36 and enters the image sensor 38.

Furthermore, a field of illumination (field of illumination: FOI in FIG. 1B) of the light source unit 12 is desirably set to be equal to or larger than a field of view range (field of view: FOV in FIG. 1B) of the light receiving unit 14. The field of view range of the light receiving unit 14 is also referred to as a “light receiving range”.

Note that the configuration of the light receiving unit 14 is not limited to the above configuration and can be changed as appropriate. For example, the image sensor 38 may be a linear sensor in which a plurality of pixels is one-dimensionally arranged.

(3) Configuration of Control Unit

The control unit 16 of the first embodiment includes an arithmetic circuit that controls the light source 20 and the image sensor 38 and calculates a distance to an object (subject). The control unit 16 is provided in a region different from the image sensor 38 (pixel arrangement region) on the sensor board 38a. The control unit 16 transmits a light emission control signal (pulse signal) to the light source drive circuit 21 to cause the light source 20 to intermittently emit light, calculates, for each pixel, the distance to the object on the basis of an output of each pixel of the image sensor 38, and generates a distance image.

The calculation method of the control unit 16 may be a method of calculating the distance to the object on the basis of the light emission control signal and an output signal (light receiving signal) of each pixel of the image sensor 38 (direct TOF method) or may be a method of calculating the distance to the object on the basis of a difference or a ratio of charge amounts of signal charges alternately distributed to two charge storage units of each pixel when the image sensor 38 receives light (indirect TOF method).

The arithmetic circuit of the control unit 16 is implemented by, for example, a central processing unit (CPU), a field-programmable gate array (FPGA), or the like.

2. Operation of Distance Measuring Device According to First Embodiment of Present Technology

In the distance measuring device 10 of the first embodiment, the light source unit 12 emits light to the object, the light receiving unit 14 receives the light reflected by the object, and the control unit 16 calculates the distance to the object and generates a distance image.

(1) Operation of Light Source Unit

In the light source unit 12 of the first embodiment, the light source 20 is driven by the light source drive circuit 21, and the light is emitted from the light source 20. The light emitted from the light source 20 enters the diffuse reflection surface 22a of the diffuse reflection member 22, and at least part of the light is reflected and diffused by the diffuse reflection surface 22a toward the transmissive member 30. At least part of the light reflected and diffused by the diffuse reflection surface 22a is transmitted through the transmissive member 30 and radiates the object (subject).

(2) Operation of Light Receiving Unit

In the light receiving unit 14 of the first embodiment, light OL (hereinafter also referred to as “object light OL”) radiated from the light source unit 12 to the object and reflected by the object enters the lens unit 32 and is condensed by the lens unit 32. The object light OL passing through the lens unit 32 enters the bandpass filter 36. Only light in a predetermined wavelength band (for example, infrared light), of the object light OL having entered the bandpass filter 36, passes through the bandpass filter 36. The object light OL having passed through the bandpass filter 36 enters the image sensor 38. At this time, the image sensor 38 performs photoelectric conversion at each pixel.

(3) Operation of Control Unit

The control unit 16 of the first embodiment drives the light source 20 via the light source drive circuit 21, calculates, for each pixel, the distance to the object (subject) on the basis of the output of each pixel of the image sensor 38, and generate the distance image.

3. Effect of Distance Measuring Device According to First Embodiment of Present Technology

(1) Effect of Light Source Unit

In the light source unit 12 of the first embodiment, the holder 24 has the diffuse reflection surface 22a that reflects and diffuses at least part of the light from the light source 20 toward an object.

In the light source unit 12 according to the first embodiment, at least part of the light from the light source 20 is reflected and diffused by the diffuse reflection surface 22a (is changed in the traveling direction) and heads toward the object. In this case, even if the diffuse reflection surface 22a is damaged or falls off, at least part of the light from the light source 20 is not diffused by the diffuse reflection surface 22a and goes in a direction different from the direction toward the object.

According to the light source unit 12 of the first embodiment, safety can be enhanced.

The holder 24 has the recess 24a in which the light source 20 is housed, and the diffuse reflection surface 22a is located in the recess 24a and reflects and diffuses at least part of the light from the light source 20 toward the opening 24a1 of the recess 24a. Thereby, leakage of the light from the light source 20 to the outside without diffusion can be suppressed even if the diffuse reflection surface 22a is damaged or falls off.

Since the holder 24 has the window 30 that covers the opening 24a1 of the recess 24a, adhesion of foreign substances (including moisture) to the light source 20 and the diffuse reflection surface 22a can be suppressed. Thereby, deterioration in performance of the light source unit 12 can be suppressed.

Since the diffuse reflection surface 22a is inclined with respect to the emission direction of the light source 20, the light from the light source 20 can be reflected and diffused in a desired direction.

Since the inclination angle of the diffuse reflection surface 22a with respect to the emission direction of the light source 20 is 30° to 60°, the necessary irradiation angle range for the object can be obtained.

Since the emission surface of the light source 20 and the diffuse reflection surface 22a face each other, the light emitted from the light source 20 can be guided to the diffuse reflection surface 22a side.

Since the light emitted from the light source 20 directly enters the diffuse reflection surface 22a, the light source unit 12 can be downsized (particularly in a width direction).

Since at least part of the light from the light source 20 (the light reflected by the diffuse reflection surface 22a) is 60% or more of the light from the light source 20, the amount of the irradiation light IL radiating the object can be sufficiently secured.

Since the light source 20 is provided on the bottom surface of the recess 24a and the angle formed by the emission direction ED of the light source 20 with respect to the bottom surface is 0° to 45°, the light source unit 12 can be made thinner.

Since the diffuse reflection surface 22a is located between the light source 20 and a part of the peripheral wall 28 of the recess 24a, at least part of the light from the light source 20 can be blocked by the peripheral wall 28 even if the diffuse reflection surface 22a is damaged or falls off.

Since the diffuse reflection surface 22a is provided on the bottom surface of the recess 24a, the light source 20 and the diffuse reflection surface 22a can be easily positioned.

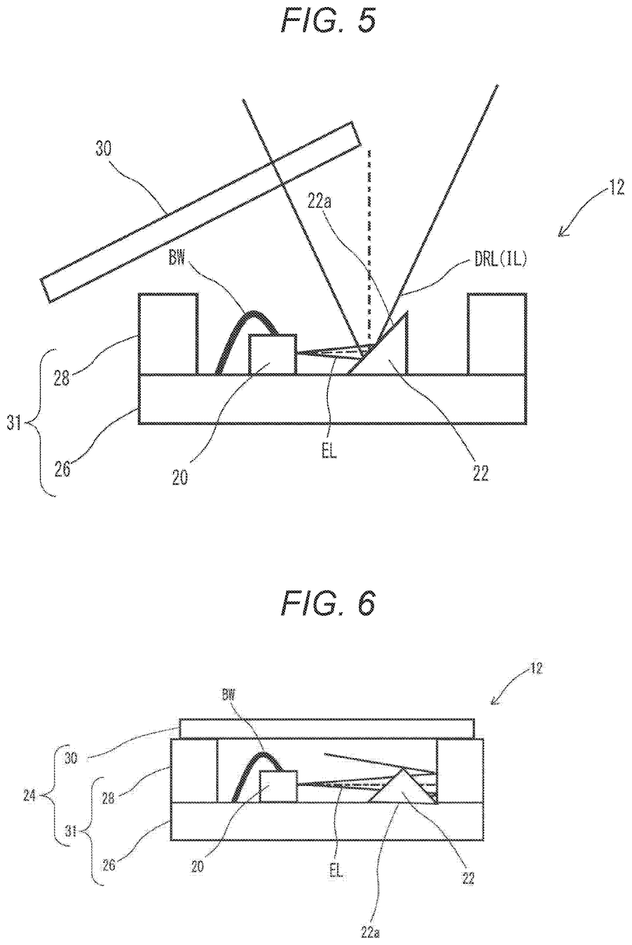

Since in the light source unit 12 of the first embodiment, the diffuse reflection member 22 having the diffuse reflection surface 22a is provided separately from the transmissive member 30, the diffuse reflection member 22 can reflect and diffuse the emitted light EL of the light source 20 toward the object even if the transmissive member 30 falls off the package 31, for example, as illustrated in FIG. 5. As a result, irradiation of the object with the undiffused light can be suppressed.

Since in the light source unit 12 of the first embodiment, the peripheral wall 28 surrounding the diffuse reflection member 22 having the diffuse reflection surface 22a and the light source 20 is provided on the substrate 26, the emitted light EL of the light source 20 enters the peripheral wall 28 even if the diffuse reflection member 22 is detached from the substrate 26 and displaced, for example, as illustrated in FIG. 6. As a result, leakage of the undiffused light to the outside can be suppressed.

(2) Effect of Distance Measuring Device

The distance measuring device 10 of the first embodiment includes the light source unit 12, the light receiving unit 14 that receives the light emitted from the light source unit 12 and reflected by an object, and the control unit 16 that calculates the distance to the object on the basis of at least an output of the light receiving unit 14. As a result, the distance measuring device 10 having excellent safety can be implemented.

Since the light source unit 12, the light receiving unit 14, and the control unit 16 are integrally provided, the distance measuring device 10 can be easily mounted on an object (for example, a moving body, an electronic device, or the like).

According to the object system including the distance measuring device 10 and the object (for example, a moving body, an electronic device, or the like) on which the distance measuring device 10 is mounted, a superior object system for safety can be implemented.

4. Light Source Unit According to Second Embodiment of Present Technology

(1) Configuration of Light Source Unit

A light source unit 122 according to a second embodiment of the present technology has a similar configuration to the light source unit 12 according to the first embodiment, except that arrangement of a diffuse reflection member is different.

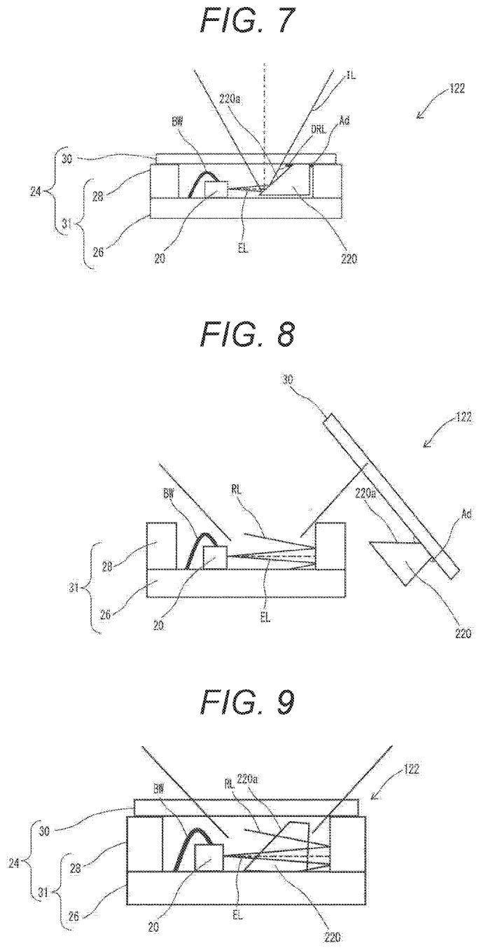

In the light source unit 122 according to the second embodiment, a diffuse reflection member 220 is fixed to an inner surface of a transmissive member 30, as illustrated in FIG. 7. That is, a diffuse reflection surface 220a of the diffuse reflection member 220 is provided on the transmissive member 30.

The diffuse reflection member 220 is formed using a member having a trapezoidal cross section with the diffuse reflection surface 220a as an inclined surface inclined at, for example, 45° with respect to a substrate 26. A surface (upper bottom portion) of the diffuse reflection member 220 on the transmissive member 30 side is fixed to the inner surface of the transmissive member 30 with, for example, an adhesive Ad. There is a certain amount of clearance between a surface (lower bottom portion) of the diffuse reflection member 220 on the substrate 26 side and the substrate 26.

Here, the diffuse reflection surface 220a is one surface of the diffuse reflection member 220 that is a separate body from the transmissive member 30. However, for example, a protrusion corresponding to a base material of the diffuse reflection member 220 may be formed on the transmissive member, and the diffuse reflection surface may be formed on one surface of the protrusion. That is, the diffuse reflection surface may be a part of the transmissive member. In this case, although it takes some time to manufacture the transmissive member, the number of parts can be reduced and the diffuse reflection surface can be prevented from coming off the transmissive member, as compared with the case where the diffuse reflection member is provided on the transmissive member.

Since the operation of the light source unit 122 of the second embodiment is similar to the operation of the light source unit 12 of the first embodiment, description thereof will be omitted.

(2) Effect of Light Source Unit

In the light source unit 122 of the second embodiment, the diffuse reflection member 220 is attached to the transmissive member 30, as illustrated in FIG. 7. Therefore, when the transmissive member 30 comes off a package 31, the transmissive member 30 and the diffuse reflection member 220 come off together, as illustrated in FIG. 8. At this time, since the emitted light from the light source 20 enters the peripheral wall 28, leakage of the undiffused light to the outside can be suppressed.

In the light source unit 122 of the second embodiment, as illustrated in FIG. 9, even if the diffuse reflection member 220 is detached from the transmissive member 30, the emitted light EL of the light source 20 enters the peripheral wall 28. Therefore, leakage of undiffused light to the outside can be suppressed.

5. Light Source Unit According to Third Embodiment of Present Technology

(1) Configuration of Light Source Unit

A light source unit 123 according to a third embodiment of the present technology has a similar configuration to the light source unit 12 according to the first embodiment, except that arrangement of a diffuse reflection member is different.

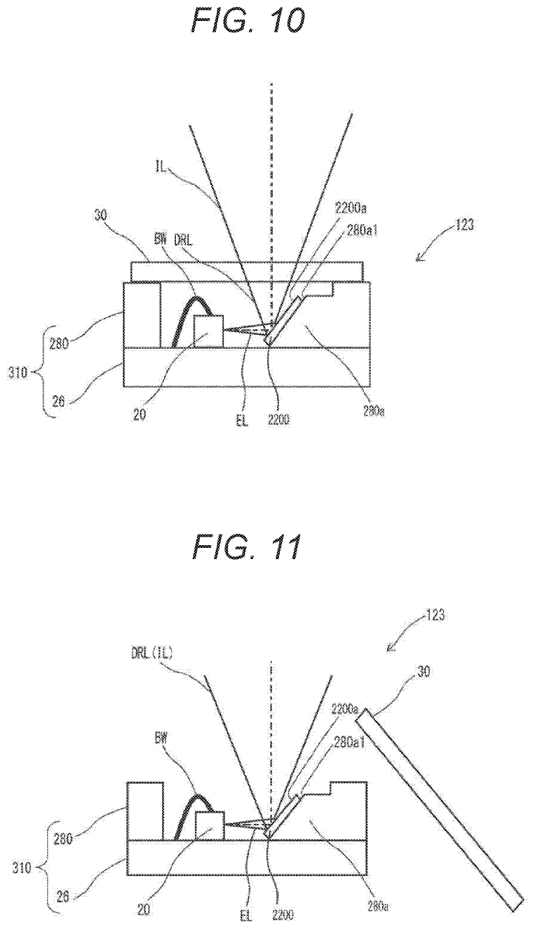

In the light source unit 123 according to the third embodiment, as illustrated in FIG. 10, a peripheral wall 280 of a package 310 has a protruding portion 280a protruding inward, and an inner surface of the protruding portion 280a serves as an inclined surface 280a1 (for example, an inclined surface inclined by 45° with respect to a substrate 26). A plate-shaped diffuse reflection member 2200 (diffuse reflector) is fixed to the inclined surface 280a1 with, for example, an adhesive.

Since the operation of the light source unit 123 of the third embodiment is similar to the operation of the light source unit 12, description thereof will be omitted.

(2) Effect of Light Source Unit

In the light source unit 123 of the third embodiment, the light from the light source 20 is reflected and diffused by the diffuse reflection surface 2200a of the diffuse reflection member 2200 toward the object. Therefore, as illustrated in FIG. 11, even if the transmissive member 30 is detached from the package 310, leakage of undiffused light to the outside can be suppressed.

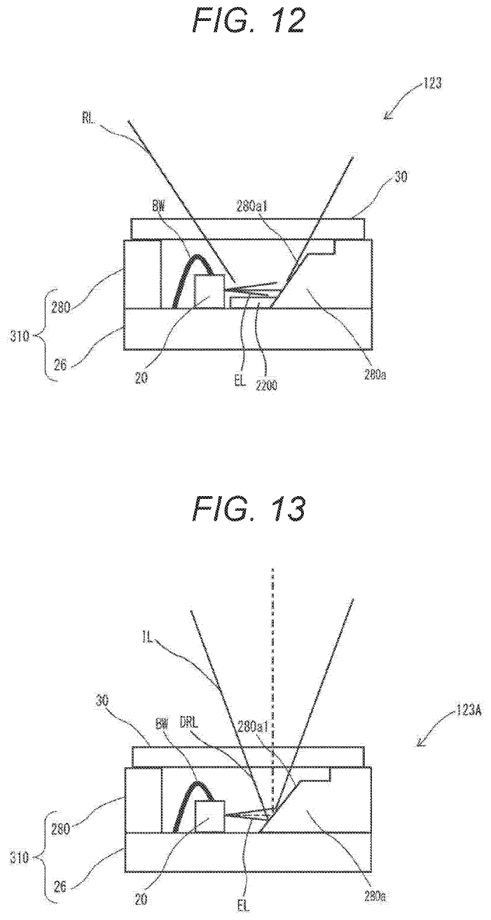

In the light source unit 123 of the third embodiment, as illustrated in FIG. 12, even if the diffuse reflection member 2200 is detached from the peripheral wall 280, emitted light EL of a light source 20 enters the peripheral wall 280. Therefore, leakage of undiffused light to the outside can be suppressed.

6. Light Source Unit According to Modification of Third Embodiment of Present Technology

(1) Configuration of Light Source Unit

As illustrated in FIG. 13, a light source unit 123A according to a modification of the third embodiment of the present technology is different from the light source unit 123 of the third embodiment in that the inclined surface 280a1 of the protruding portion 280a of the peripheral wall 280 serves as a diffuse reflection surface. That is, in the light source unit 123A, the peripheral wall 280 has the diffuse reflection surface. In the light source unit 123A, the diffuse reflection surface is generated by forming a film of a material having a diffuse reflection property on the inclined surface 280a1 or performing fine unevenness processing on the inclined surface 280a1.

(2) Effect of Light Source Unit

Since, in the light source unit 123A of the modification of the third embodiment, the peripheral wall 280 has the diffuse reflection surface, it takes some time to form the diffuse reflection surface but the number of parts can be reduced and the diffuse reflection surface can be prevented from falling off the peripheral wall, as compared with the case where the diffuse reflection member is attached to the peripheral wall.

7. Light Source Unit According to Fourth Embodiment of Present Technology

(1) Configuration of Light Source Unit

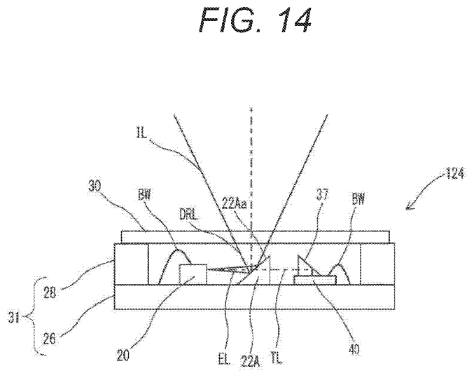

In a light source unit 124 according to a fourth embodiment of the present technology, a light receiving element 40 (for example, a photodiode (PD)) for light detection is mounted at a position on a substrate 26 on an opposite side of a light source 20 with respect to a diffuse reflection member 22A, as illustrated in FIG. 14. The light receiving element 40 is mounted on the substrate 26 by die bonding, and is electrically connected to wiring on the substrate 26 by a bonding wire BW. Moreover, in the light source unit 124, a configuration is adopted in which the diffuse reflection member 22A slightly has a light transmissive property (for example, the transmittance of 1%), and a small amount of light (transmitted light TL) transmitted through the diffuse reflection member 22A is brought to enter the light receiving element 40 using a mirror 37 inclined by, for example, 45° with respect to the substrate 26. An inclination direction of the mirror 37 is opposite to an inclination direction of a diffuse reflection surface 22Aa of the diffuse reflection member 22A. Since the base material of the diffuse reflection member 22A includes glass or resin having a light transmissive property, the overall transmittance is set to 1% by balancing the transmittance of the diffuse reflection surface 22Aa and the transmittance of the base material.

Note that, in the fourth embodiment, the diffuse reflection member 22A is provided on the substrate 26 as in the first embodiment, but the diffuse reflection member 22A may be provided on the transmissive member 30 as in the second embodiment, or the diffuse reflection member 22A may be provided on the peripheral wall as in the third embodiment. For example, in the case where the diffuse reflection member 22A is provided on a protruding portion of the peripheral wall, a space may be formed in the protruding portion, and the mirror 37 and the light receiving element 40 may be arranged in the space.

(2) Effect of Light Source Unit

In the light source unit 124 of the fourth embodiment, a small amount of light emitted from the light source 20 and transmitted through the diffuse reflection member 22A is brought to enter the light receiving element 40.

According to the light source unit 124 of the fourth embodiment, if the diffuse reflection member 22A is damaged or falls off a package 31, and light (emitted light EL) emitted from the light source 20 enters the light receiving element 40 through the mirror 37 without being transmitted through the diffuse reflection member 22A, an output of the light receiving element 40 becomes abnormally high. Conversely, if the output of the light receiving element 40 becomes abnormally high, damage or falling off of the diffuse reflection member 22A can be suspected.

According to the light source unit 124 of the fourth embodiment, if the mirror 37 is damaged or falls off the package 31, and the light emitted from the light source 20 and transmitted through the diffuse reflection member 22 stops entering the light receiving element 40, the output of the light receiving element 40 becomes abnormally low (nearly zero). Conversely, when the output of the light receiving element 40 is abnormally low even though the light source 20 is emitting light, damage or falling off of the mirror 37 can be suspected.

8. Light Source Unit According to Fifth Embodiment of Present Technology

(1) Configuration of Light Source Unit

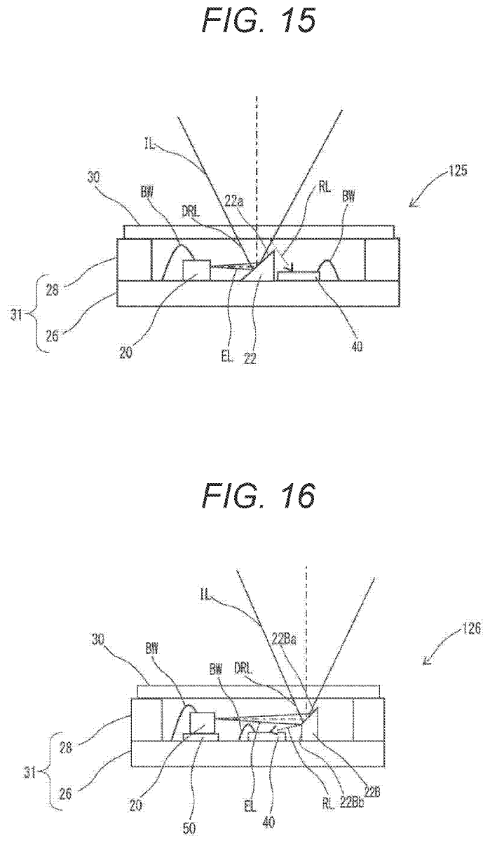

In a light source unit 125 according to a fifth embodiment of the present technology, a light receiving element 40 (for example, a photodiode (PD)) for light detection is mounted at a position on a substrate 26 on an opposite side of a light source 20 with respect to a diffuse reflection member 22, as illustrated in FIG. 15. Moreover, in the light source unit 125, a configuration in which a small amount of light reflected and diffused by the diffuse reflection member 22 and reflected by a transmissive member 30 is brought to enter the light receiving element 40 is adopted.

Note that, in the fifth embodiment, the diffuse reflection member 22 is provided on the substrate 26 as in the first embodiment, but the diffuse reflection member 22 may be provided on the transmissive member 30 as in the second embodiment, or the diffuse reflection member 22 may be provided on the peripheral wall as in the third embodiment. For example, in the case where the diffuse reflection member 22 is provided on a protruding portion of a peripheral wall, a space may be formed in the protruding portion, and the light receiving element 40 is arranged in the space, and an opening opening upward may be formed in the protruding portion of the peripheral wall. In this case, the light reflected by the diffuse reflection member 22 and further reflected by the transmissive member 30 can enter the light receiving element 40 through the opening.

(2) Effect of Light Source Unit

In the light source unit 125 of the fifth embodiment, a small amount of light reflected by the transmissive member 30, of the light emitted from the light source 20 and reflected and diffused by the diffuse reflection member 22, is brought to enter the light receiving element 40. According to the light source unit 125 of the fifth embodiment, if the diffuse reflection member 22 or the transmissive member 30 is damaged or falls off a package 31, and the light emitted from the light source 20 stops entering the light receiving element 40, the output of the light receiving element 40 becomes abnormally low (nearly zero). Conversely, when the output of the light receiving element 40 is abnormally low even though the light source 20 is emitting light, damage or falling off of the diffuse reflection member 22 or the transmissive member 30 can be suspected.

9. Light Source Unit According to Sixth Embodiment of Present Technology

(1) Configuration of Light Source Unit

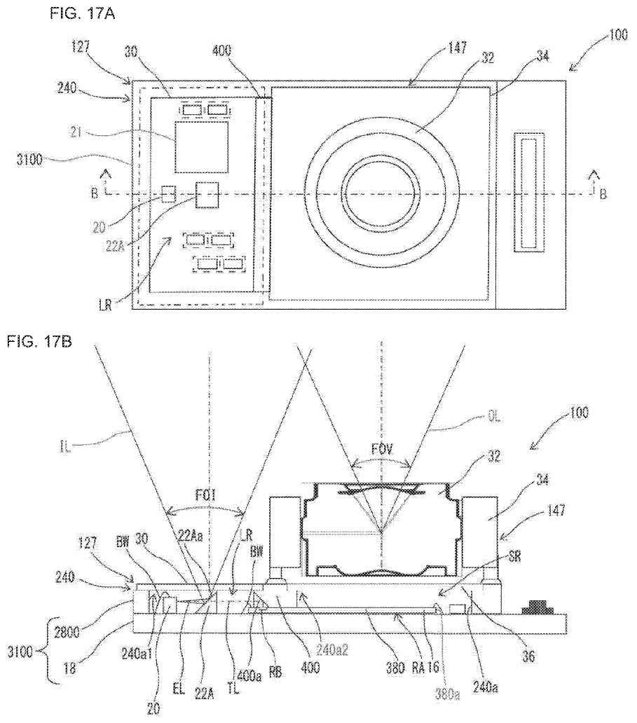

In a light source unit 126 according to a sixth embodiment of the present technology, a light receiving element 40 (for example, a photodiode (PD)) for light detection is mounted at a position on a substrate 26 between a light source 20 and a diffuse reflection member 22B, as illustrated in FIG. 16. Moreover, in the light source unit 126, a configuration in which a small amount of light rejected by the diffuse reflection member 22B is brought to enter the light receiving element 40 is adopted.

More specifically, the diffuse reflection member 22B is manufactured by forming a diffuse reflection surface 22Ba on an inclined surface of a quadrangular prism-shaped base material having a trapezoidal cross section.

A spacer 50 is arranged between the light source 20 and the substrate 26 so that light emitted from the light source 20 passes over the light receiving element 40. That is, the light emitted from the light source 20 does not directly enter the light receiving element 40.

The light source 20 and the diffuse reflection surface 22Ba are in a positional relationship in which most of the light emitted from the light source 20 enters the diffuse reflection surface 22Ba, and a remaining small amount of light enters a vertical surface 22Bb adjacent to the diffuse reflection surface 22Ba on the light receiving element 40 side and perpendicular to the substrate 26.

Note that, in the sixth embodiment, the diffuse reflection member 22B is provided on the substrate 26 as in the first embodiment, but the diffuse reflection member 22B may be provided on the transmissive member 30 as in the second embodiment, or the diffuse reflection member 22B may be provided on the peripheral wall as in the third embodiment.

(2) Effect of Light Source Unit

In the light source unit 126 of the sixth embodiment, a small amount of light emitted from the light source 20 and rejected by the diffuse reflection member 22B is brought to enter the light receiving element 40.

According to the light source unit 126 of the sixth embodiment, if the diffuse reflection member 22B is damaged or falls off a package 31, and the light emitted from the light source 20 stops entering the light receiving element 40, the output of the light receiving element 40 becomes abnormally low (nearly zero) even though the light source 20 is emitting light. Conversely, when the output of the light receiving element 40 is abnormally low even though the light source 20 is emitting light, damage or falling off of the diffuse reflection member 22B is suspected.

10. Effect Common to Light Source Units According to Fourth to Sixth Embodiments of Present Technology

The light source units 124, 125, and 126 of the fourth to sixth embodiments of the present technology include the light receiving element 40 that receives at least part of the light emitted from the light source 20 and via the diffuse reflection member.

In this case, since a certain percentage of the amount of emitted light from the light source 20 can be detected by the light received by the light receiving element 40, control (auto power control: APC) to keep the amount of emitted light from the light source 20 constant can be performed even if an ambient temperature changes by feeding back the output signal of the light receiving element 40 to the light source drive circuit 21, or control to determine abnormality and stop light emission for safety can be performed by detecting a sudden change in the amount of emitted light asynchronous with the light emission control signal.

Furthermore, light emission timing of the light source 20 can be detected by the output of the light receiving element 40. Thereby, the distance to the object can be calculated on the basis of the actual light emission timing of the light source 20 instead of the light emission control signal for causing the light source 20 to emit light.

As described above, according to the light source units 124, 125, and 126 of the fourth to sixth embodiments, the light from the light source 20 can be detected by the light receiving element 40, and damage or falling off of the diffuse reflection member can be detected from an abnormal change in the output of the light receiving element 40.

Parts of the configurations of the light source units of the first to sixth embodiments can be applied to one another within the technical consistency.

11. Distance Measuring Device According to Seventh Embodiment of Present Technology

(1) Configuration of Distance Measuring Device

In a distance measuring device 100 according to a seventh embodiment, as illustrated in FIGS. 17A and 17B, a configuration is adopted in which a light source 20 and a diffuse reflection member 22A having a slight light transmissive property (for example, the transmittance of 1%) of a light source unit 127, an image sensor 380 of a light receiving unit 147, and a control unit 16 are directly mounted on a circuit board 18. Moreover, a peripheral wall 2800 is provided on the circuit board 18 so as to surround the light source 20, the diffuse reflection member 22A, the image sensor 380, and the control unit 16.

That is, in the distance measuring device 100 of the seventh embodiment, a holder 240 includes a package 3100 including the circuit board 18 and the peripheral wall 2800, and holds the light source 20, the diffuse reflection member 22A, the image sensor 380, and the control unit 16. That is, in the distance measuring device 100, the light source 20, the diffuse reflection member 22A, the image sensor 380, and the control unit 16 are held by the common holder 240. More specifically, the light source 20, the diffuse reflection member 22A, the image sensor 380, and the control unit 16 are arranged in a recess 240a of the holder 240, that is, in a region inside the peripheral wall 2800 on the circuit board 18. The image sensor 380 and the control unit 16 are provided on the same sensor board 380a (semiconductor board). An object system is configured by including the distance measuring device 100 and the object (for example, a moving body, an electronic device, or the like) on which the distance measuring device 100 is mounted. Again, a field of illumination FOI is set to be the same as or slightly larger than a field of view FOV.

A light-shielding block 400 extending in a direction orthogonal to the paper surface of FIG. 17B is bridged over the recess 240a (a region inside the peripheral wall 2800) of the holder 240. That is, the recess 240a of the holder 240 is divided by the light-shielding block 400 into a light source region LR in which the light source 20 and the diffuse reflection member 22A are arranged and a sensor region SR in which most of the image sensor 380 is arranged. An opening 240a1 of the light source region LR of the recess 240a is covered with a transmissive member 30. An opening 240a2 of the sensor region SR of the recess 240a is covered with a bandpass filter 36.

In the sensor region SR of the recess 240a, a first light receiving region RA (pixel arrangement region) including a pixel group for distance measurement of the image sensor 380 is arranged. In this case, even if the diffuse reflection member 22A is damaged or falls off, at least part of the light emitted from the light source 20 is blocked by the light-shielding block 400. Therefore, the light does not enter the first light receiving region RA.

As illustrated in FIG. 17A, a light source drive circuit 21 is mounted on a bottom surface of a region adjacent to the light source 20 and the diffuse reflection member 22A in the light source region LR (a region on the depth side of the paper surface of the light source 20 and the diffuse reflection member 22A in FIG. 17B).

The image sensor 380 has a second light receiving region RB for light detection (for example, a region where a PD is formed) in the light source region LR in addition to the first light receiving region RA including the pixel group for distance measurement. The light-shielding block 400 has a mirror surface 400a on an optical path of light (transmitted light TL) emitted from the light source 20 and transmitted through the diffuse reflection member 22A. The mirror surface 400a is arranged so as to be inclined (for example, by 45°) with respect to the circuit board 18 to face the diffuse reflection member 22A and the second light receiving region RB. Conversely, the second light receiving region RB is arranged on the optical path of the light transmitted through the diffuse reflection member 22A and reflected by the mirror surface 400a.

(2) Operation of Distance Measuring Device

In the distance measuring device 100, the light source 20 is driven by the light source drive circuit 21, and the light source 20 emits light. Part (most) of the light emitted from the light source 20 is reflected and diffused by the diffuse reflection member 22A, transmitted through the transmissive member 30, and radiated to an object as irradiation light IL. The light through the lens unit 32 and the bandpass filter 36, of the light (object light OL) radiated to and reflected by the object is condensed on the first light receiving region RA of the image sensor 380. The first light receiving region RA sends an output (a photoelectrically converted electric signal) for each pixel to the control unit 16. The control unit 16 generates a distance image on the basis of the output of each pixel of the first light receiving region RA.

On the other hand, another part (a small amount) of the light emitted from the light source 20 is transmitted through the diffuse reflection member 22A, reflected by the mirror surface 400a, and condensed on the second light receiving region RB. The second light receiving region RB sends an output (a photoelectrically converted electric signal) to the control unit 16. The control unit 16 performs various controls (for example, control of the amount of emitted light of the light source 20, distance calculation based on detected emission timing, and the like) on the basis of the output of the second light receiving region RB.

(3) Effect of Distance Measuring Device and Object System

The distance measuring device 100 of the seventh embodiment includes the light source unit 127, the light receiving unit 147 that receives the light emitted from the light source unit 127 and reflected by an object, and the control unit 16 that calculates the distance to the object on the basis of at least an output of the light receiving unit 147. As a result, the distance measuring device 100 having excellent safety can be implemented.

Since the light source unit 127, the light receiving unit 147, and the control unit 16 are integrally provided, the distance measuring device 100 can be easily mounted on an object (for example, a moving body, an electronic device, or the like).

According to the object system including the distance measuring device 100 and the object (for example, a moving body, an electronic device, or the like) on which the distance measuring device 100 is mounted, a superior object system for safety can be implemented.

In the distance measuring device 100, the light receiving unit 147 includes the image sensor 380 having the first light receiving region RA for receiving the light emitted from the light source unit 127 and reflected by the object and the second light receiving region RB for receiving the light emitted from the light source 20 and via the diffuse reflection surface 22Aa. Thereby, the number of parts can be reduced and the distance measuring device 100 can be downsized.

Note that, in the holder 240, the recess 240a and the window 30 are not essential. That is, in the holder 240, the peripheral wall 2800 and the transmissive member 30 are not essential. The holder 240 may be configured by only the circuit board 18. The holder 240 may be configured by only the circuit board 18 and the peripheral wall 2800, that is, only the package 3100. In the holder 240, the circuit board 18 is used as the base member on which the light source 20 is mounted, but a member other than the circuit board (for example, a non-plate-shaped member) may be used.

12. Configuration of Distance Measuring Device According to Eighth Embodiment of Present Technology

(1) Overall Configuration of Distance Measuring Device

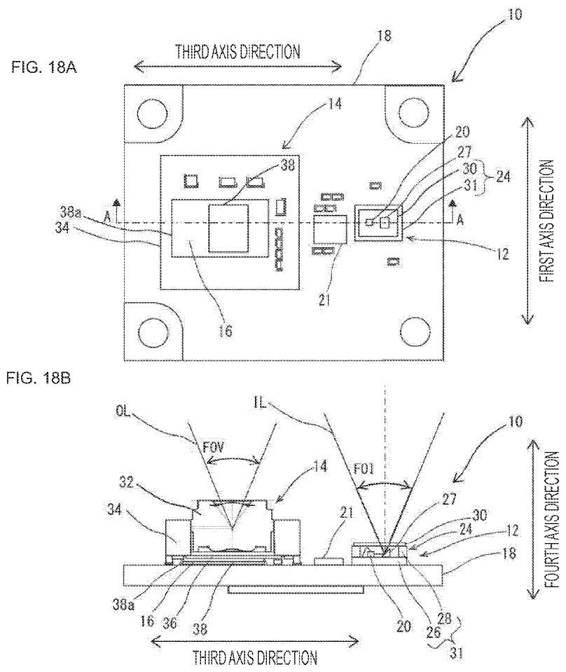

FIG. 18A is a plan view of a distance measuring device 10 according to an eighth embodiment of the present technology. FIG. 18B is a sectional view taken along line A-A of FIG. 18A. The distance measuring device 10 is used to, for example, measure a distance to an object, a shape of the object, and the like. Note that, in FIG. 18A, illustration of some members (lens unit 32, bandpass filter 36, and the like) illustrated in FIG. 18B is omitted from the viewpoint of avoiding complexity of the drawings.

The distance measuring device 10 is mounted on an object. Examples of the object on which the distance measuring device is mounted include moving bodies such as vehicles, aircrafts (including drones), ship, and robots, and electronic devices such as smartphones and tablets. An object system is configured by including the distance measuring device 10 and the object (for example, a moving body, an electronic device, or the like) on which the distance measuring device 10 is mounted.

As illustrated in FIGS. 18A and 18B, the distance measuring device 10 includes a light source device 12 that irradiates an object with light, a light receiving device 14 that receives reflected light from the object, and a control device 16 that controls the light source device 12 and the light receiving device 14. That is, the distance measuring device 10 is a distance measuring device using the principle of time of flight (TOF) having light emitting/receiving and calculating functions. The light source device 12, the light receiving device 14, and the control device 16 are mounted on the same circuit board 18. Moreover, a multi-pin connector for supplying power and exchanging data with an outside is mounted on the circuit board 18. Note that at least two of the light source device 12, the light receiving device 14, and the control device 16 do not have to be mounted on the same circuit board. The “light source device” described below may include the “light source unit” of each of the above embodiments.

(2) Overall Configuration of Light Source Device

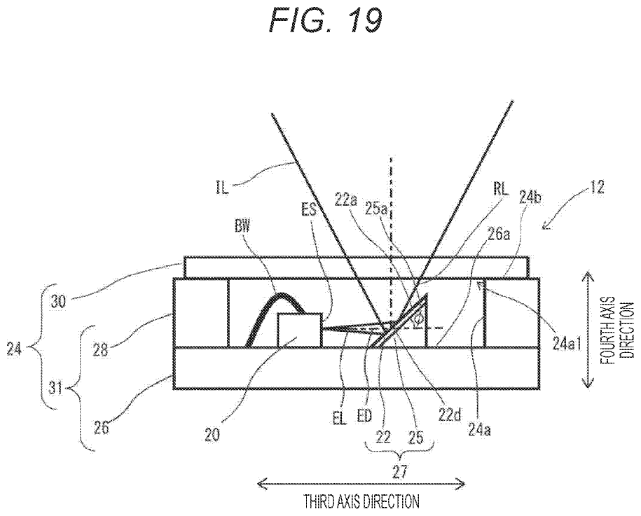

As illustrated in FIG. 19, the light source device 12 includes a light source 20 and a holder 24 that holds the light source 20.

As the light source 20, for example, a laser light source such as an end face emitting-type semiconductor laser (laser diode: LD) or a surface emitting-type semiconductor laser (surface emitting laser: VCSEL) is used. The light source 20 is mounted on a substrate 26 by die bonding, and is electrically connected to wiring on the substrate 26 by a bonding wire BW. Here, for example, infrared light is used as emitted light EL of the light source 20, but light in another wavelength band may be used. The light source 20 is driven by a light source drive circuit 21 (driver circuit). Here, as illustrated in FIGS. 18A and 18B, the light source drive circuit 21 is arranged at a position on the circuit board 18 between the light source device 12 and the light receiving device 14.

Note that the light source 20 may be a light source other than the laser light source (for example, a light emitting diode: LED) but the light source 20 is favorably a light source that emits high-power light such as a laser light source.

Returning to FIG. 19, the holder 24 has a reflection surface 22a that reflects while diffusing at least part of the light from the light source 20 toward an object.

That is, the light source device 12 irradiates the object with at least part of the light (reflected light RL) emitted from the light source 20 and reflected while being diffused by a reflection surface 22a as irradiation light IL.

More specifically, the holder 24 has a recess 24a in which the light source 20 is housed. The reflection surface 22a is located in the recess 24a and reflects and diffuses at least part of the light from the light source 20 toward an opening 24a1 of the recess 24a.

Moreover, the holder 24 has a window 30 that covers the opening 24a1 of the recess 24a. At least part of the light (reflected light RL) emitted from the light source 20 and reflected while being diffused by the diffuse reflection surface 22a toward the opening 24a is transmitted through the window 30. The light transmitted through the window 30, of the reflected light RL, is the irradiation light IL.

More specifically, the holder 24 is provided on the circuit board 18 (see FIGS. 18A and 18B), and includes a package 31 having the recess 24a, a reflector 27 including a diffuse reflection member 22 having the reflection surface 22a, and a transmissive member as the window 30 (hereinafter also called “transmissive member 30”).

The package 31 is an open box-shaped member, and has the substrate 26 having a bottom surface of the recess 24a as one surface, and a peripheral wall 28 having an inner peripheral surface of the recess 24a as an inner peripheral surface. The substrate 26 and the peripheral wall 28 are integrally formed using a material such as ceramic. Note that, in the package 31, the substrate 26 and the peripheral wall 28 may be separate bodies.

The light source 20 and the reflector 27 are mounted on one surface (substrate surface) of the substrate 26. Hereinafter, the one surface (substrate surface) of the substrate 26 on which the light source 20 and the reflector 27 are mounted is also referred to as a “mounting surface 26a”.

The peripheral wall 28 is provided on the mounting surface 26a so as to surround the light source 20 and the reflector 27.

The transmissive member 30 is a glass-made or resin-made plate-shaped member having a light transmissive property, and is attached using an adhesive or the like to an opening end surface 24b (an end surface of the peripheral wall 28 on the opposite side of an end surface on the substrate 26 side) of the holder 24 so as to cover the opening 24a1. The transmittance of the transmissive member 30 is set so as to transmit most (for example, 99% or more) of the light in a wavelength band (for example, an infrared region) of the emitted light EL of the light source 20.

Therefore, since approximately all of the reflected light RL from the reflection member 22 is transmitted through the transmissive member 30, the irradiation light IL can be substantially identified with the reflected light RL.

The light source 20 and the reflector 27 are sealed in the package 31 by the transmissive member 30. Thereby, invasion of foreign substances (for example, grit and dust, and moisture) into the package 31 can be suppressed and the parts (the light source 20, the reflection member 22, and the like) in the package 31 can be protected (for example, adhesion of foreign substances to the light source 20 or the reflection member 22 can be suppressed, and occurrence of problems such as short-circuit of wiring due to the invaded foreign substances can be suppressed).

The reflector 27 includes a support member 25 that supports the reflection member 22 in addition to the reflection member 22.

Here, the reflection member 22 is formed using an approximately plate-shaped member, and is supported by the support member 25 such that the reflection surface 22a is located on an optical path of the light (emitted light EL) from the light source 20.

As an example, the support member 25 is formed using a glass-made or resin-made triangular prism-shaped member (triangular prism-shaped member having a height direction in a direction perpendicular to the paper surface of FIG. 19) having a right-angled triangular cross section and having a light transmissive property. The approximately plate-shaped reflection member 22 is bonded to an inclined surface 25a of the support member 25 with, for example, an adhesive. Note that the support member 25 does not necessarily have to have a light transmissive property.

As an example, the reflectance or transmittance of the reflection surface 22a is set so as to reflect while diffusing 90% or more (favorably, 99% or more) of the light from the light source 20.

Note that, here, the reflection member 22 is an approximately plate-shaped member supported by the support member 25, but may be, for example, a member having the reflection surface 22a formed on an inclined surface of a base material corresponding to the support member 25. That is, the reflector 27 may be configured by a single reflection member in which the reflection member 22 and the support member 25 are integrally molded.

Here, a surface of the reflection member 22 on an opposite side of the reflection surface 22a (the bonding surface with the inclined surface 25a) is a plane parallel to the inclined surface 25a. Hereinafter, this plane is also referred to as “reference plane 22d”.

Note that, here, as an example, the surface of the reflection member 22 on an opposite side of the reflection surface 22a (the bonding surface with the inclined surface 25a) is set as the reference plane 22d. However, the inclined surface 25a of the support member 25 may be set as the reference plane, an arbitrary cross section parallel to the reflection member 22 or the inclined surface 25a of the support member 25 may be set as the reference plane, or a virtual plane parallel to the inclined surface 25a may be set as the reference plane.

The reference plane 22d is inclined with respect to an emission direction ED of the light source 20. That is, the reference plane 22d is inclined with respect to an emission surface ES of the light source 20 (for example, a semiconductor laser). Note that, since a semiconductor laser such as an LD and a VCSEL emits light from the emission surface ES perpendicularly to the emission surface ES, the emission surface ES is also inclined with respect to the reference plane 22d in the case where the emission direction ED is inclined with respect to the reference plane 22d.

An inclination angle φ of the reference plane 22d with respect to the emission direction ED of the light source 20 is favorably 30° to 60°, and more favorably 40° to 50°, in order to obtain the necessary and sufficient irradiation angle range for the object.

Therefore, in the present embodiment, as an example, the inclination angle φ of the reference plane 22d with respect to the emission direction ED of the light source 20 is set to approximately 45°.

Moreover, the angle formed by the emission direction ED of the light source 20 with respect to the mounting surface 26a is favorably 0° to 45°, more favorably 0° to 30°, and even more favorably 0° to 15° from the viewpoint of suppressing the height of the peripheral wall 28 and reducing the thickness of the light source device 12. The emission direction ED of the light source 20 may be shifted (inclined) toward the transmissive member 30 side or may be shifted (inclined) toward the substrate 26 side from the direction parallel to the mounting surface 26a.

Therefore, in the present embodiment, as an example, the light source 20 is mounted on the mounting surface 26a such that the angle formed by the emission direction ED with respect to the mounting surface 26a becomes approximately 0°, that is, the emission direction ED goes along (approximately parallel to) the mounting surface 26a.

In this case, since the inclination angle cp of the reference plane 22d with respect to the emission direction ED of the light source 20 is approximately 45° as described above, the reference plane 22d and the inclined surface 25a are also inclined at approximately 45° with respect to the mounting surface 26a.

The emission surface ES of the light source 20 and the reflection surface 22a face each other. That is, the emission direction ED of the light source 20 faces the reflection surface 22a side.

The emission surface ES of the light source 20 does not face the transmissive member 30. That is, the emission direction ED of the light source 20 does not face the transmissive member 30 side.

The reflection surface 22a also faces the transmissive member 30.

No other optical members (lenses, mirrors, and the like) are interposed between the light source 20 and the reflection surface 22a. In this case, the light emitted from the light source 20 (emitted light EL) directly enters the reflection surface 22a. Therefore, the distance between the light source 20 and the reflection surface 22a can be shortened, and the device can be downsized. Other optical members (lenses, mirrors, and the like) may be interposed on the optical path between the light source 20 and the reflection surface 22a.

When other optical members (lenses, mirrors, and the like) are interposed between the light source 20 and the reflection surface 22a, the emission surface ES of the light source 20 does not necessarily have to face the reflection surface 22a.

Note that, in the holder 24, the recess 24a and the window 30 are not essential. That is, in the holder 24, the peripheral wall 28 and the transmissive member 30 are not essential. The holder 24 may be configured by only the substrate 26. The holder 24 may be configured by only the substrate 26 and the peripheral wall 28, that is, only the package 31. In the holder 24, the substrate 26 is used as the base member on which the light source 20 is mounted, but a member other than the substrate (for example, a non-plate-shaped member) may be used.

(3) Configuration of Light Receiving Device

The light receiving device 14 of the eighth embodiment includes the lens unit 32, a lens holder 34, the bandpass filter 36, and an image sensor 38, as illustrated in FIGS. 18A and 18B.

The image sensor 38 is provided on a sensor board 38a (semiconductor board) mounted on the circuit board 18, and includes a plurality of two-dimensionally arrayed pixels. The image sensor 38 is also called area image sensor.

The shape of a pixel arrangement region, which is a region in which the plurality of pixels of the image sensor 38 is arranged, is, for example, a rectangle. Here, the pixel arrangement region occupies approximately the entire region of the image sensor 38. That is, the shape of the image sensor 38 approximately matches the shape of the pixel arrangement region.

Note that the shape of the image sensor 38 may be a shape other than a rectangle (for example, a square, a circle, an ellipse, or a polygon other than a square and a rectangle).

Each pixel of the image sensor 38 includes a light receiving element (for example, a photodiode: PD), and the pixels are electrically connected to a circuit on the circuit board 18 by wire bonding.

The lens holder 34 is fixed to the circuit board 18 so as to surround the image sensor 38.

The lens unit 32 includes at least one lens element and is held in the lens holder 34 so as to be focused on the image sensor 38.

The bandpass filter 36 fixed to the lens holder 34 is arranged between the image sensor 38 and the lens unit 32. Thereby, only the light having a wavelength near the wavelength of the emitted light EL of the light source 20 (the light in a predetermined wavelength band, for example, infrared light), of the light reflected by the object and passing through the lens unit 32, is transmitted through the bandpass filter 36 and enters the image sensor 38.

Furthermore, a field of illumination (field of illumination: FOI in FIG. 18B) of the light source device 12 is desirably set to be equal to or larger than a field of view range (field of view: FOV in FIG. 18B) of the light receiving device 14. The field of view range of the light receiving device 14 is also referred to as a “light receiving range”.

Note that the configuration of the light receiving device 14 is not limited to the above configuration. For example, the image sensor 38 may be a linear sensor (line sensor) in which a plurality of pixels is one-dimensionally arranged.

(4) Configuration of Control Device

The control device 16 of the eighth embodiment includes an arithmetic circuit that controls the light source 20 and the image sensor 38 and calculates a distance to an object (subject). As illustrated in FIGS. 18A and 18B, the control device 16 is arranged in a region different from the image sensor 38 (pixel arrangement region) on the sensor board 38a. The control device 16 transmits a light emission control signal (pulse signal) to the light source drive circuit 21 to cause the light source 20 to intermittently emit light, calculates, for each pixel, the distance to the object on the basis of an output of each pixel of the image sensor 38, and generates a distance image.

The calculation method of the control device 16 may be a method of calculating the distance to the object on the basis of the light emission control signal and an output signal (light receiving signal) of each pixel of the image sensor 38 (direct TOF method) or may be a method of calculating the distance to the object on the basis of a difference or a ratio of charge amounts of signal charges alternately distributed to two charge storage units of each pixel when the image sensor 38 receives light (indirect TOF method).

The arithmetic circuit of the control device 16 is implemented by, for example, a central processing unit (CPU), a field-programmable gate array (FPGA), or the like.

(5) Configuration of Reflection Member

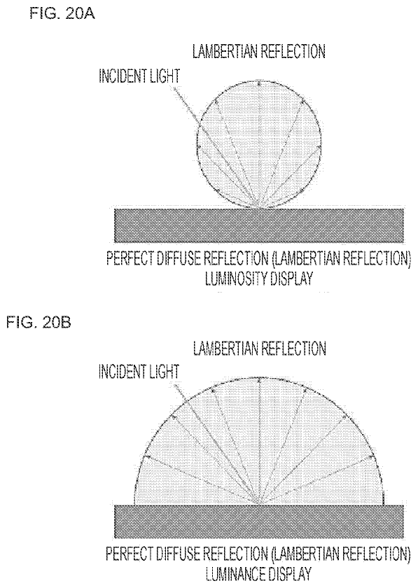

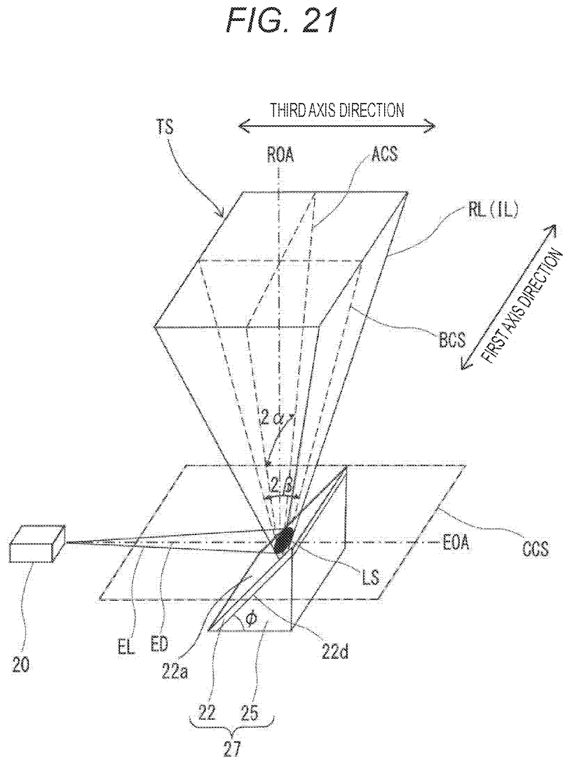

By the way, a commercially available diffuse reflector is designed to perform so-called Lambertian reflection (perfect diffuse reflection) as illustrated in FIGS. 20A and 20B, that is, a perfect diffuse reflector. If such a perfect diffuse reflector is used as the diffuse reflection member 22 of the distance measuring device 10, a field of illumination FOI of the light source device 12 becomes too wide with respect to the field of view FOV of the light receiving device 14. Therefore, the irradiation light IL from the light source device 12 has a large portion (wasted portion) that is not radiated to the object and not received by the light receiving device 14, and sufficient illuminance cannot be obtained within the field of view FOV.

Therefore, in the present embodiment, as illustrated in FIG. 18B, the field of illumination FOI of the light source device 12 is set to be the same as the field of view FOV of the light receiving device 14 or slightly wider in consideration of variation by designing the reflection member 22.

Furthermore, the light emitted from the light source device 12 and reflected by the object is collected by the lens unit 32 of the light receiving device 14 on the image sensor 38. At this time, the shape of the cross section perpendicular to the optical axis of the reflected light OL from the object (hereinafter also referred to as “object light OL”) approximates to the shape of the image sensor 38 as the shape of the cross section (hereinafter simply referred to as a “cross section of the irradiation light IL” or a “cross section of the reflected light RL”) perpendicular to the optical axis of the irradiation light IL (the reflected light RL from the reflection member 22) further approximates to the shape (for example, a rectangle) of the image sensor 38 of the light receiving device 14. In this case, the object light OL can be condensed on the image sensor 38 without waste. That is, the irradiation light IL can be efficiently used.

Therefore, in the present embodiment, a target shape TS (see FIG. 21) that is a targeted shape of the cross section of the irradiation light IL is set to be the same as the shape (here, a rectangle) of the image sensor 38 (see FIG. 18A), and the reflection member 22 is designed to be able to generate the reflected light RL (irradiation light IL) having a cross-sectional shape of the target shape TS (see FIG. 21). Note that FIG. 21 illustrates only the light source 20 and the reflector 27 in the light source device 12 for convenience. The reflected light RL (irradiation light IL) illustrated in FIG. 21 has a quadrangular pyramid shape in which shapes of arbitrary cross sections perpendicular to the optical axis are rectangular similar to each other. Hereinafter, the reflected light RL having a cross-sectional shape of the target shape TS is also referred to as “desired reflected light RL”. The irradiation light IL having a cross-sectional shape of the target shape TS is also referred to as “desired irradiation light IL”.

Hereinafter, a design concept of the reflection member 22 will be described in detail.

The field of illumination FOI of the light source device 12, that is, the range in which the irradiation light IL exists, depends on a diffusion direction of the light by the reflection member 22 and a diffusion angle for each diffusion direction.

Here, as illustrated in FIG. 21, an optical axis (central axis) of the emitted light EL of the light source 20 is EOA, an optical axis (central axis) of the reflected light RL is ROA, a cross section including EOA and ROA of the reflected light RL is B cross section BCS, a cross section perpendicular to the B cross section BCS of the reflected light RL and including ROA is A cross section ACS, a cross section perpendicular to the B cross section BCS of the reflected light RL and including EOA is C cross section CCS, and an angle formed by the optical axis EOA of the emitted light EL and the reference plane 22d of the reflection member 22 is φ.

At this time, the diffusion angle of the desired reflected light RL (desired irradiation light IL) is defined as follows.

The diffusion angle in the A cross section ACS: an angle 2α (α≥0) with ROA as the axis of symmetry

The diffusion angle in the B cross section BCS: an angle 2β (β≥0) with ROA as the axis of symmetry

For example, in the case of φ≈45°, the angle formed by ROA and EOA is approximately 90°.

Note that the emitted light EL from the light source 20 usually has a spread angle to a greater or lesser extent, but here, the angle is assumed to be small enough to ignore and the emitted light EL is assumed to be parallel light for convenience of description. The case where the angle cannot be ignored (the case where the emitted light EL is not parallel light) will be described below.

Here, the diffusion angle of the desired reflected light RL in the A cross section ACS is defined as 2α, and the diffusion angle in the B cross section BCS is defined as 2β. However, in the desired reflected light RL, the diffusion angle in an arbitrary cross section parallel to the A cross section ACS is 2α, and the diffusion angle in an arbitrary cross section parallel to the B cross section BCS is 2β.

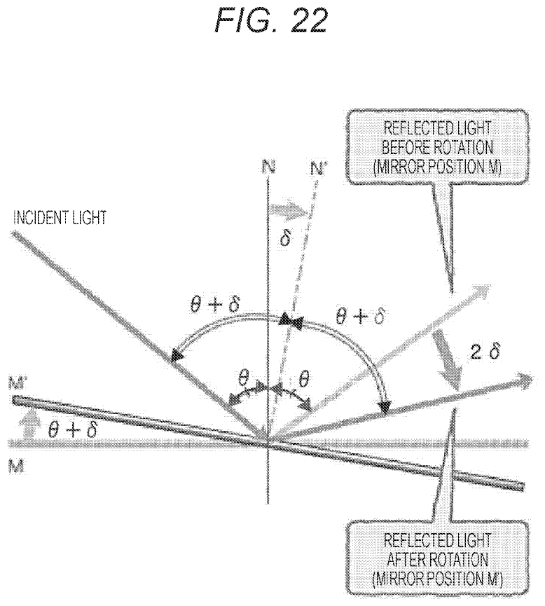

Here, as illustrated in FIG. 22, generally, in a case where light enters a plane mirror at an incident angle θ and reflected at a reflection angle θ, if the plane mirror is rotated by an angle δ to set the incident angle to θ+δ, the reflection angle also becomes θ+δ. Therefore, the reflected light after rotation of the plane mirror rotates twice (2δ) the rotation angle of the plane mirror with respect to the reflected light before rotation of the plane mirror.

Furthermore, when parallel light is applied to a curved mirror having curvatures in two axis directions orthogonal to each other, reflected light diffused in the two axis directions can be obtained.

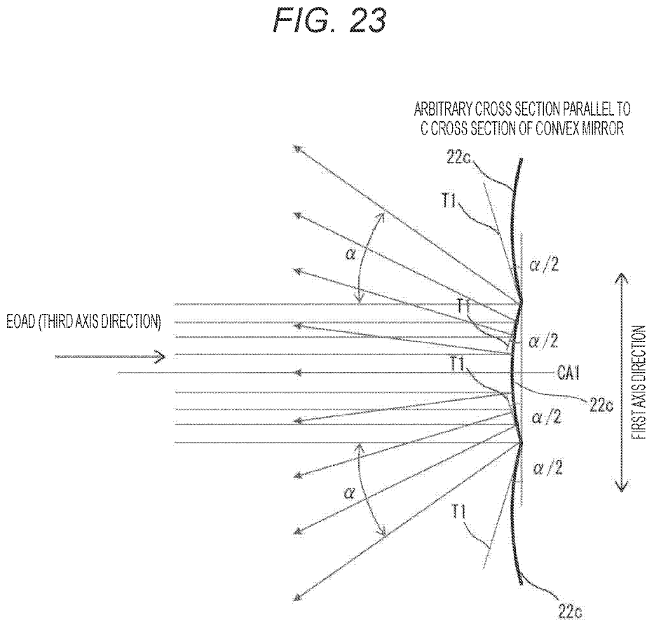

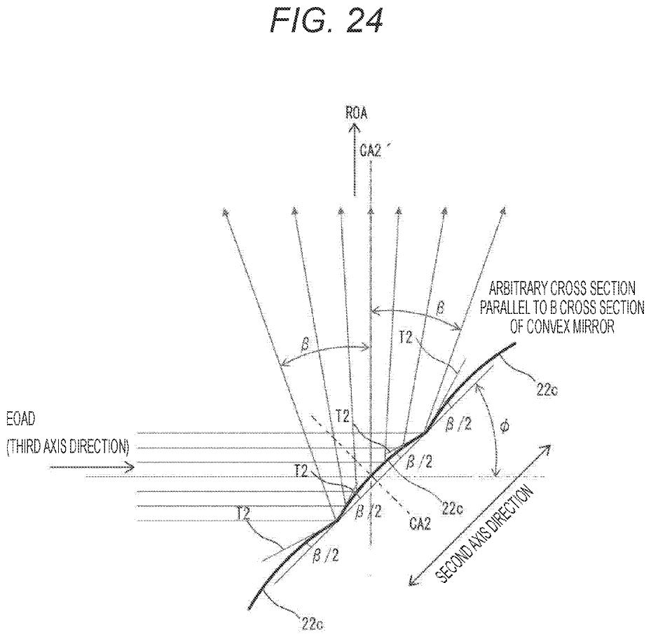

Therefore, as illustrated in FIGS. 23 and 24, the inventor has configured the reflection member 22 including a convex mirror 22c (an example of a curved mirror) having curvatures in two axis directions orthogonal to each other, and has applied the above principle to the convex mirror 22c.

FIG. 23 illustrates an arbitrary cross section parallel to the C cross section CCS of the convex mirror 22c. FIG. 24 illustrates an arbitrary cross section parallel to the B cross section BCS of the convex mirror 22c.

As illustrated in FIGS. 23 and 24, the convex mirror 22c has curvatures in a first axis direction and a second axis direction orthogonal to each other in the reference plane 22d.

The first axis direction is orthogonal to the B cross section BCS and parallel to the C cross section CCS. The second axis direction is orthogonal to the first axis direction and parallel to the B cross section BCS.

That is, in the convex mirror 22c, an arbitrary cross section parallel to the C cross section CCS has a curvature, and an arbitrary cross section parallel to the B cross section BCS has a curvature.

Specifically, as illustrated in FIG. 23, the convex mirror 22c is designed such that an arbitrary cross section parallel to the C cross section CCS has an arc shape (an example of a convex curve shape), and an angle formed by a tangent line T1 of an arc (an example of a convex curve) drawn by the cross section with respect to the first axis direction continuously changes from −α/2 to +α/2. When parallel light is brought to enter the cross section, the parallel light can be reflected at the diffusion angle of 2α within the A cross section ACS or in a cross section parallel to the A cross section ACS.

Furthermore, as illustrated in FIG. 24, the convex mirror 22c is designed such that an arbitrary cross section parallel to the B cross section BCS has an arc shape (an example of a convex curve shape), and an angle formed by a tangent line T2 of an arc (an example of a convex curve) drawn by the cross section with respect to the second axis direction continuously changes from −β/2 to +β/2. When parallel light is brought to enter the cross section, the parallel light can be reflected at the diffusion angle of 2β within the B cross section BCS or in a cross section parallel to the B cross section BCS.

As a result, by causing the parallel light to enter the convex mirror 22c, reflected light (irradiation light) having the diffusion angle of 2α in the A cross section ACS and in the arbitrary cross section parallel to the A cross section ACS, and having the diffusion angle of 2β, in the B cross section BCS and in the arbitrary cross section parallel to the B cross section BCS can be obtained.

Here, the reflection member 22 is designed such that an arbitrary cross section parallel to the C cross section CCS and an arbitrary cross section parallel to the B cross section BCS of each convex mirror 22c have a convex arc shape (an example of a convex curve shape). However, another convex curve shape may be adopted as long as the curvature continuously changes in the same direction.

Specifically, at least one of the arbitrary cross section parallel to the C cross section CCS or the arbitrary cross section parallel to the B cross section BCS of each convex mirror 22c may have a convex curve shape such as an ellipse, a parabola, a hyperbola, a sine curve, or a cycloidal curve.

The arbitrary cross section parallel to the C cross section CCS and the arbitrary cross section parallel to the B cross section BCS of each convex mirror 22c may have different convex curve shapes from each other.

Here, to generate the reflected light RL having the cross-sectional shape of the target shape TS, it is desirable to set the shape of the convex mirror 22c of the reflection member 22 viewed from an optical axis direction EOAD (hereinafter also referred to as “third axis direction”) of the emitted light EL of the light source 20, that is, from the emission direction ED of the light source 20, to be a shape (for example, a rectangle or a square) according to the target shape TS (for example, a rectangle) of the reflected light RL, favorably, a shape (for example, a rectangle or a square with an approximated aspect ratio) approximating to the target shape TS (for example, a rectangle), and to cause the emitted light of the light source 20 to enter the entire convex mirror 22c. When the shape of the convex mirror 22c (the shape viewed from the third axis direction), the shape facing the emission surface ES of the light source 20, is the shape according to the target shape TS, the emitted light EL of the light source 20 is reflected while being diffused by the convex mirror 22c to the shape according to the target shape TS. Note that the third axis direction is inclined with respect to the reference plane 22d and is orthogonal to the first axis direction.

Examples of the above “shape according to the target shape TS” includes, in the case where the target shape TS is a rectangle, a rectangle (including a rectangle having a similarity ratio of 1) similar to the target shape TS, a quadrangle (for example, a rectangle, a square, or a trapezoid) approximating to the target shape TS, an ellipse (for example, an ellipse inscribed in the target shape TS or an ellipse circumscribed around the target shape TS) approximating to the target shape TS.

In the above description, it has been described that the target shape TS is set to be the same as the shape of the image sensor 38. More specifically, as illustrated in FIG. 18, the shape of the image sensor 38 is a rectangle having the first axis direction as a longitudinal direction (long side direction) and the third axis direction as a short direction (short side direction). As illustrated in FIG. 21, the target shape TS is also a rectangle having the first axis direction as a longitudinal direction (long side direction) and the third axis direction as a short direction (short side direction). Then, the target shape TS and the shape of the image sensor 38 are similar to each other.

Here, if the configuration to reflect the emitted light EL of the light source 20 by a single convex mirror having the shape viewed from the third axis direction being the shape according to the target shape TS (the same shape as the target shape TS, for example) is adopted, the shape of the cross section of the irradiation light IL deviates from the target shape TS if the emitted light EL of the light source 20 slightly deviates from the convex mirror. That is, the positioning of the light source 20 and the convex mirror becomes very severe, which is not realistic (practical). Meanwhile, if the single convex mirror is made too small with respect to the diameter of the emitted light EL of the light source 20 in order to facilitate the positioning of the light source 20 and the convex mirror, loss of the emitted light EL becomes large.

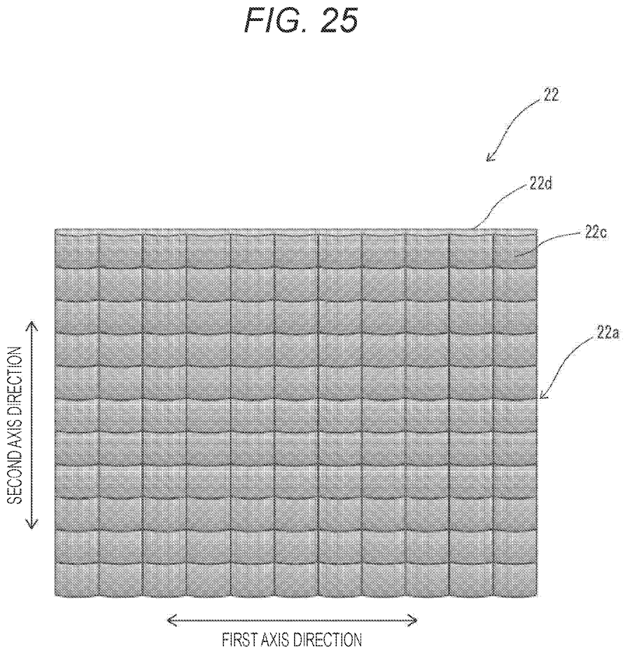

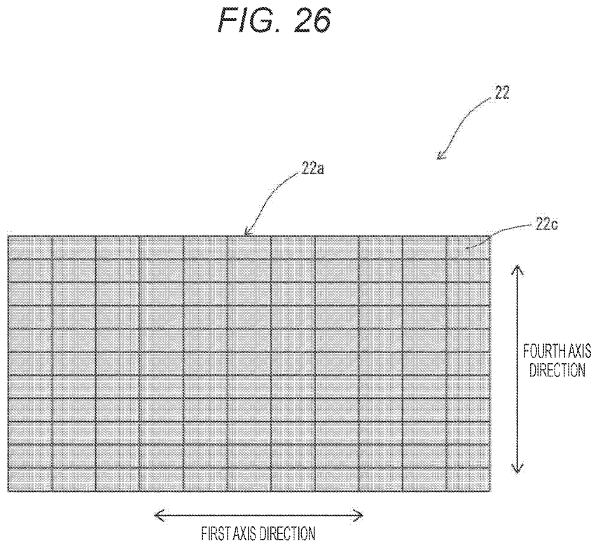

Therefore, as illustrated in FIGS. 25 and 26, the inventor has configured the reflection member 22 including a plurality of minute convex mirrors 22c, and causes the emitted light EL of the light source 20 to enter the plurality of minute convex mirrors 22c (causes the plurality of convex mirrors 22c to be included in a light spot LS (see FIG. 21) on the reflection member 22 of the emitted light EL). That is, the reflection surface 22a of the reflection member 22 is configured by the convex surfaces of the plurality of convex mirrors 22c.

Moreover, in the present embodiment, the shape and size, and the relative position of the reflection surface 22a with respect to the light source 20 are set such that the entire light spot LS (see FIG. 21) formed on the reflection surface 22a is contained within the reflection surface 22a when the emitted light EL of the light source 20 enters the reflection surface 22a.

FIG. 25 is a view of the reflection surface 22a viewed from a direction perpendicular to the reference plane 22d. In FIG. 25, the reflection surface 22a is viewed in such a manner that the convex mirrors 22c having a slightly distorted rectangular shape are arranged in a grid manner. FIG. 26 is a view of the reflection surface 22a viewed from the third axis direction. In FIG. 26, the reflection surface 22a is viewed in such a manner that the rectangular convex mirrors 22c are arranged in a grid manner.

That is, as illustrated in FIGS. 25 and 26, the plurality of convex mirrors 22c is regularly arranged along the reference plane 22d.

More specifically, as illustrated in FIG. 26, the plurality of convex mirrors 22c includes at least three convex mirrors and is arranged in a two-dimensional grid manner as viewed from the third axis direction.

Here, the direction orthogonal to both the first axis direction and the third axis direction (the direction perpendicular to the C cross section CCS) is defined as a fourth axis direction.

More specifically, the plurality of convex mirrors 22c includes at least four convex mirrors, and is arranged in a two-dimensional grid manner in the first axis direction that is a direction corresponding to the horizontal direction (first axis direction) of the target shape TS and in the fourth axis direction that is a direction corresponding to the vertical direction (third axis direction) of the target shape TS as viewed from the third axis direction. Note that, here, the horizontal direction of the target shape TS is described as the first axis direction and the vertical direction is described as the third axis direction, but the horizontal direction of the target shape TS may be set as the third axis direction and the vertical direction may be set as the first axis direction.

That is, the plurality of convex mirrors 22c is arranged at equal pitches in each of the first axis direction and the fourth axis direction as viewed from the third axis direction.

In this way, the plurality of convex mirrors 22c is regularly arranged with each other according to the target shape TS.

In each convex mirror 22c, the shape viewed from the third axis direction is the shape (here, a rectangle) according to the target shape TS (here, a rectangle). Each convex mirror 22c is arranged such that the long side direction of the rectangle that is the shape viewed from the third axis direction coincides with the first axis direction that is the direction corresponding to the long side direction (first axis direction) of the target shape TS, and the short side direction of the rectangle coincides with the fourth axis direction that is the direction corresponding to the short side direction (third axis direction) of the target shape TS.

In this way, each convex mirrors 22c is regularly arranged according to the target shape TS.

As described above, the plurality of convex mirrors 22c is regularly arranged according to the target shape TS.

In summary, as illustrated in FIGS. 25 and 26, in the reflection member 22, the plurality of minute convex mirrors 22c having the shape (here, the rectangle) according to the target shape TS of the cross section of the reflected light RL viewed from the third axis direction is aligned in a grid manner in the first axis direction and the second axis direction and bedded without gaps on the reference plane 22d inclined with respect to the third axis direction. Note that there may be a slight gap between two adjacent convex mirrors 22c.

Here, as illustrated in FIG. 26, the overall shape of the reflection surface 22a viewed from the third axis direction is rectangular, but a shape other than the rectangle may be adopted as long as the entire light spot LS (see FIG. 21) formed on the reflection surface 22a is contained in the reflection surface 22a when the emitted light EL of the light source 20 enters the reflection surface 22a.

Here, the diffusion angle 2α in an arbitrary cross section parallel to the A cross section ACS of the light by each convex mirror 22c is determined according to the curvature in the first axis direction of the convex mirror 22c (the curvature of the convex curve drawn by an arbitrary cross section parallel to the C cross section CCS). The diffusion angle 2β in an arbitrary cross section parallel to the B cross section BCS of the light by each convex mirror 22c is determined according to the curvature in the second axis direction of the convex mirror 22c (the curvature of the convex curve drawn by an arbitrary cross section parallel to the B cross section BCS).

As illustrated in FIG. 23, an arbitrary cross section parallel to the C cross section CCS of each convex mirror 22c is an arc shape (an example of a convex curve shape), and an angle formed by a chord (line segment) connecting both ends of an arc (an example of a convex curve) drawn by the cross section and the tangent line T1 (in a plane parallel to the C cross section) at each end of the arc is set to α/2. At this time, an incident angle of light on the arbitrary cross section parallel to the C cross section CCS of each convex mirror 22c continuously changes from −α/2 to +α/2 symmetrically with respect to a central axis CA1 passing through the center in the first axis direction of the cross section and extending in the third axis direction.

Therefore, the reflected light from each convex mirror 22c continuously spreads at the angle of 2α symmetrically with respect to an axis corresponding to the central axis CA1 of the convex mirror 22c in the A cross section ACS or in a plane parallel to the A cross section ACS.

Here, the above-described “axis corresponding to the central axis CA1 of the convex mirror 22c” is an axis parallel to ROA intersecting with the central axis CA1 in the B cross section BCS including the central axis CA1 of the convex mirror 22c or in the plane parallel to the B cross section BCS.

However, when α is increased, the reflected light from each convex mirror 22c interferes with an adjacent convex mirror 22c, and eclipse occurs.

Therefore, to suppress the eclipse, 0°<α and α+(α/2)≤90°, that is, 0°<α≤60° is desirable.

Note that it is desirable that all the convex mirrors 22c satisfy 0°<α≤60° but only some of the convex mirrors 22c may satisfy 0°<α≤60°.

FIG. 23 illustrates, for convenience, a state in which light enters one convex mirror 22c and is reflected while diffused. In reality, light similarly enters other convex mirrors 22c and is reflected while diffused.

As illustrated in FIG. 24, the arbitrary cross section parallel to the B cross section BCS of each convex mirror 22c is an arc shape (an example of a convex curve shape), and the angle formed by a chord (line segment) connecting both ends of an arc (convex curve) drawn by the cross section and the tangent line (in a plane parallel to the B cross section) at each end of the arc is set to β/2. At this time, an incident angle of light on the arbitrary cross section parallel to the B cross section BCS of each convex mirror 22c continuously changes from (90°−φ)−β/2 to (90°−φ)+β/2 symmetrically with respect to a central axis CA2 passing through the center in the second axis direction of the cross section and orthogonal to both the first axis direction and the second axis direction (orthogonal to the reference plane 22d).

Therefore, the reflected light from each convex mirror 22c continuously spreads at the angle of 2β symmetrically with respect to an axis CA2′ corresponding to the central axis CA2 of the convex mirror 22c in the B cross section BCS or in a plane parallel to the B cross section BCS.

Here, the above-described “axis CA2′ corresponding to the central axis CA2 of the convex mirror 22c” is an axis parallel to ROA intersecting with the central axis CA2 in the B cross section BCS including the central axis CA2 of the convex mirror 22c or in the plane parallel to the B cross section BCS.

However, when β is increased, the reflected light from each convex mirror 22c interferes with an adjacent convex mirror 22c, and eclipse occurs.

Therefore, to suppress the eclipse, 0°<β and β+(β/2)+φ≤90°, that is, 0°<β≤60°−(⅔)φ is desirable.

Note that it is desirable that all the convex mirrors 22c satisfy 0°<β≤60°−(⅔)φ but only some of the convex mirrors 22c may satisfy 0°<β≤60°−(⅔)φ.

FIG. 24 illustrates, for convenience, a state in which light enters one convex mirror 22c and is reflected while diffused. In reality, light similarly enters other convex mirrors 22c and is reflected while diffused.

Note that, even if the ranges of α and β are limited to 0° <α≤60° and 0°<β≤60°−(⅔)φ in order to suppress the eclipse, as described above, the diffusion angle of the reflected light RL can be set in the ranges of 0°≤2α≤120° and 0°≤2β≤60° in the case where the incident angle 90°−φ on the reflection member 22 is set to 45° (φ=45°), which is the most practical. Therefore, the angle can be practically sufficiently large.

When parallel light is brought to enter the plurality of convex mirrors 22c of the reflection member 22 as described above, the light reflected while being diffused by each convex mirror 22c becomes quadrangular pyramid-shaped reflected light diffused at the diffusion angle 2α in the A cross section ACS or in the plane parallel to the A cross section ACS, and diffused at the diffusion angle 2β in the B cross section BCS or in the plane parallel to the B cross section BCS. At this time, the reflected light from an adjacent convex mirror 22c has an overlapping portion, but the reflected light RL, which is an aggregate of the reflected light from all the convex mirrors 22c, also becomes quadrangular pyramid-shaped reflected light diffused at the diffusion angle 2α in the A cross section ACS or in the plane parallel to the A cross section ACS, and diffused at the diffusion angle 2β in the B cross section BCS or in the plane parallel to the B cross section BCS.

That is, by causing the emitted light EL of the light source 20 to be reflected by the reflection member 22, the quadrangular pyramid-shaped reflected light RL (irradiation light IL) having the diffusion angle 2α in the A cross section ACS and in the arbitrary cross section parallel to the A cross section ACS, and the diffusion angle 2β in the B cross section BCS and in the arbitrary cross section parallel to the B cross section BCS can be generated.

Here, in each of the plurality of convex mirrors 22c, a length in the first axis direction of the shape viewed from the third axis direction, a length in the fourth axis direction of the shape viewed from the third axis direction, a curvature in the first axis direction, and a curvature in the second axis direction are set according to a ratio of a length in a direction (for example, the first axis direction) corresponding to the first axis direction and a length in a direction (for example, the third axis direction) corresponding to the fourth axis direction in the target shape TS.

Note that this setting is not essential.

Specifically, it is favorable to make the curvature in the first axis direction and the curvature in the second axis direction of each convex mirror 22c equal to each other in the case of making the ratio of the length in the fourth axis direction to the length in the first axis direction in the shape viewed from the third axis direction, of each of the plurality of convex mirrors 22c, equal to the ratio of the length in the direction (third axis direction) corresponding to the fourth axis direction to the length in the direction (the first axis direction, for example) corresponding to the first axis direction in the target shape TS.

For example, in the case where the shape of each convex mirror 22c viewed from the third axis direction and the target shape TS are similar rectangles (rectangles having the same aspect ratio), if the curvature in the first axis direction and the curvature in the second axis direction of each convex mirror 22c are made equal to each other, the shape of the cross section perpendicular to the optical axis of light reflected while being diffused by each convex mirror 22c can be expanded while being kept to the rectangle similar to the target shape TS, and uniformity of illuminance of the irradiation light IL can be improved.

Specifically, it is favorable to make the curvature in the first axis direction and the curvature in the second axis direction of the convex mirror 22c different from each other to make the cross sectional shape of the light reflected while being diffused by the convex mirror 22c close to the target shape TS in the case of making the ratio of the length in the fourth axis direction to the length in the first axis direction in the shape viewed from the third axis direction, of each of the plurality of convex mirrors 22c, different from the ratio of the length in the direction (for example, the third axis direction) corresponding to the fourth axis direction to the length in the direction (the first axis direction, for example) corresponding to the first axis direction in the target shape TS.

For example, it is favorable to make the curvature in the first axis direction sufficiently larger than the curvature in the second axis direction of the convex mirror 22c to make the cross sectional shape of the light reflected while being diffused by the convex mirror 22c be a horizontally long rectangle (close to the target shape TS) in the case where the shape of each convex mirror 22c viewed from the third axis direction is a vertically long (the length in the fourth axis direction is longer than the length in the first axis direction) rectangle, and the target shape TS is a horizontally long (the length in the first axis direction is longer than the length in the third axis direction) rectangle.

For example, it is favorable to make the curvature in the second axis direction sufficiently larger than the curvature in the first axis direction of the convex mirror 22c to make the cross sectional shape of the light reflected while being diffused by the convex mirror 22c be a vertically long rectangle (close to the target shape TS) in the case where the shape of each convex mirror 22c viewed from the third axis direction is a horizontally long (the length in the first axis direction is longer than the length in the fourth axis direction) rectangle, and the target shape TS is a vertically long (the length in the third axis direction is longer than the length in the first axis direction) rectangle.

For example, it is favorable to make the curvature in the first axis direction larger than the curvature in the second axis direction of the convex mirror 22c to make the degree of being horizontally long of the cross sectional shape of the light reflected while being diffused by the convex mirror 22c larger (close to the target shape TS) in the case where the shape of each convex mirror 22c viewed from the third axis direction is a horizontally long (the length in the first axis direction is longer than the length in the fourth axis direction) rectangle, the target shape TS is a horizontally long (the length in the first axis direction is longer than the length in the third axis direction) rectangle, and the latter rectangle is horizontally longer than the former rectangle.

For example, it is favorable to make the curvature in the second axis direction smaller than the curvature in the first axis direction of the convex mirror 22c to make the degree of being vertically long of the cross sectional shape of the light reflected while being diffused by the convex mirror 22c smaller (close to the target shape TS) in the case where the shape of each convex mirror 22c viewed from the third axis direction is a vertically long (the length in the fourth axis direction is longer than the length in the first axis direction) rectangle, the target shape TS is a vertically long (the length in the third axis direction is longer than the length in the first axis direction) rectangle, and the former rectangle is vertically longer than the latter rectangle.

For example, it is favorable to make the curvature in the second axis direction larger than the curvature in the first axis direction of the convex mirror 22c to make the degree of being vertically long of the cross sectional shape of the light reflected while being diffused by the convex mirror 22c larger (close to the target shape TS) in the case where the shape of each convex mirror 22c viewed from the third axis direction is a vertically long (the length in the fourth axis direction is longer than the length in the first axis direction) rectangle, the target shape TS is a vertically long (the length in the third axis direction is longer than the length in the first axis direction) rectangle, and the latter rectangle is vertically longer than the former rectangle.

Furthermore, it is desirable that the size of the convex mirror 22c is sufficiently smaller than the light spot LS (see FIG. 21) of the emitted light EL formed on the reflection surface 22a, and as many convex mirrors 22c as possible are contained in the light spot LS.

Reasons will be described below. Since the light shines on only a part of the convex mirrors 22c located around the light spot LS, the reflected light can also shine on only a part of the field of illumination FOV, which becomes a factor to reduce the uniformity of illuminance. Meanwhile, the ratio of the convex mirrors 22c that the light shines on only a part thereof decreases as the size of the convex mirror 22c is smaller than the light spot LS, which is advantageous to increase the uniformity of illuminance.

Here, the plurality of convex mirrors 22c is set to have curvatures in the first axis direction that are equal to each other and have curvatures in the second axis direction that are equal to each other.

Note that at least two of the plurality of convex mirrors 22c may be set such that at least one of the curvatures in the first axis direction or the curvatures in the second axis direction are different from each other.

Furthermore, in the plurality of convex mirrors 22c, the ratios of the length in the fourth axis direction to the length in the first axis direction in the shape viewed from the third axis direction are set to be equal to each other.

Note that, in at least two of the plurality of convex mirrors 22c, the ratios of the length in the fourth axis direction to the length in the first axis direction in the shape viewed from the third axis direction may be set to be different from each other.

Moreover, in the plurality of convex mirrors 22c, the lengths in the first axis direction are set to be equal to each other and the lengths in the fourth axis direction are set to be equal to each other in the shape viewed from the third axis direction.

Note that, in the plurality of convex mirrors 22c, at least one of the lengths in the first axis direction or the lengths in the fourth axis direction in the shape viewed from the third axis direction may be set to be different from each other.

Note that, in the above description, the third axis direction is the optical axis direction EOAD of the emitted light EL of the light source 20, but the embodiment is not limited to the case. For example, in a case of arranging optical members such as a lens and a mirror between the light source 20 and the reflection member 22, the third axis direction is only required to substantially coincide with the optical axis direction of the light emitted from the light source 20 and passing through the optical members.

That is, it is favorable that the third axis direction substantially coincides with the optical axis direction (incident axis direction) of the incident light emitted from the light source 20 and entering the reflection member 22. Note that the third axis direction may be slightly inclined with respect to the incident axis direction.

(6) Method of Manufacturing Reflection Member

As a method of producing the reflection member 22, an etching method similar to Japanese Patent Application Laid-Open No. 10-148704 “Method of forming a microlens array and method of manufacturing solid-state image sensor” can be used. Note that, since the incident axis of light (the optical axis of the incident light) of the convex mirror 22c according to the present technology is tilted with respect to the reference plane 22d, the direction of etching on the masked substrate surface needs to be tilted to match the direction of the incident axis.

Hereinafter, an outline of processes of manufacturing the reflection member 22 will be described.

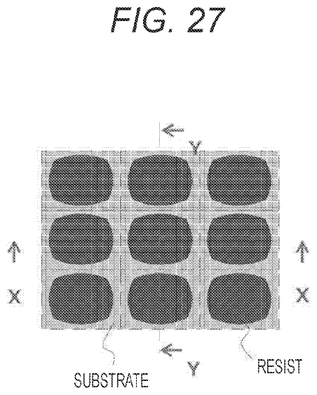

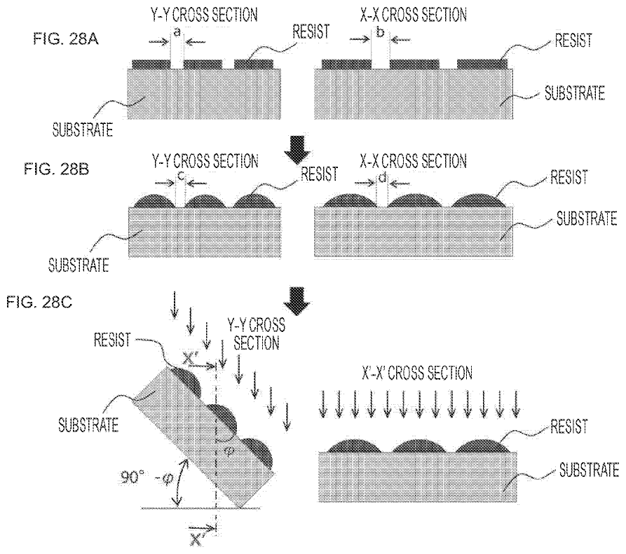

First, as illustrated in FIG. 27, a resist to server as a mask is applied to one surface of a substrate (base material) that is a material for the reflection member 22 such as glass, metal, or resin according to the shape and pitch of the convex mirror 22c to be formed. FIG. 27 illustrates only nine resists formed in a 3×3 grid pattern on one substrate, for convenience of description, but in reality, a large number of minute resists is formed on one substrate in a grid manner.

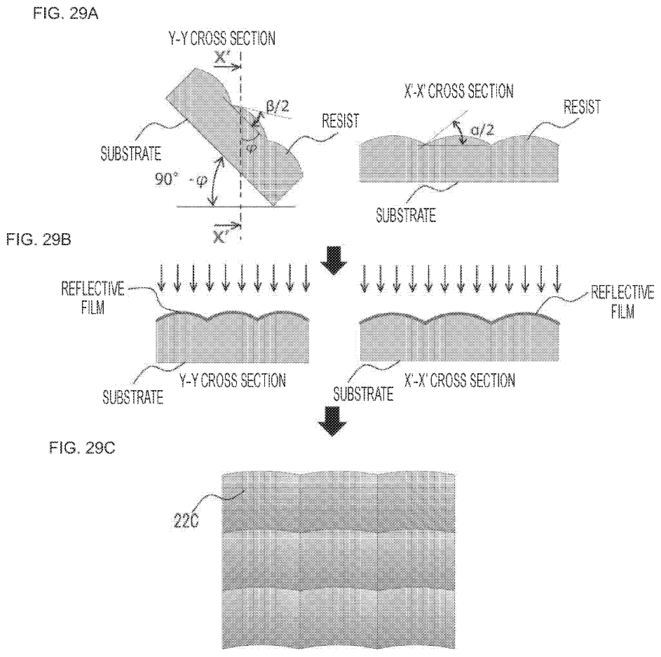

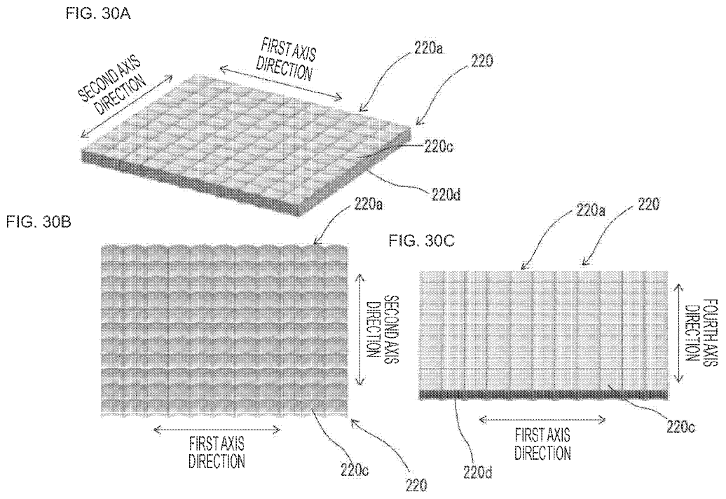

FIG. 28A illustrates Y-Y cross sections and X-X cross sections of FIG. 27. From the state where the resist is applied on the substrate as illustrated in FIG. 28A, the resist is melted by reflow and deformed into a dome shape by surface tension as illustrated in FIG. 28B.

At this time, as can be seen from FIGS. 28A and 28B, a gap between the resists adjacent in the Y-Y axis direction (the direction corresponding to the second axis direction) changes from a to c (<a), and a gap between the resists adjacent in the X-X axis direction (the direction corresponding to the first axis direction) changes from b to d (<b)

Next, in an etching device such as a parallel plate-type RIE device, dry etching (etching gas: oxygen+CF4) is performed while keeping the substrate tilted by φ (for example, 45°) around the X-X axis with respect to the direction corresponding to the third axis direction so that the etching gas containing ions and radicals is emitted from the same direction (corresponding to the third axis direction) as an assumed light incident direction as illustrated in FIG. 28C. At this time, the etching is performed under a condition that a planar pattern transferred from the resist to the substrate gradually becomes larger than a planar pattern of the resist (a positive conversion difference occurs). Here, the resist thickness, the gaps between adjacent resists, the CF4 concentration of the etching gas, and the like are controlled so that a convex surface formed as a result becomes the convex surface having the shape illustrated in FIG. 29A. Here, as can be seen from FIGS. 28C and 29A, the X′-X′ cross section is a cross section parallel to both the direction corresponding to the first axis direction and the direction corresponding to the third axis direction.

Next, as illustrated in FIG. 29B, a reflective film is formed on the surface of the formed convex surface by a method such as sputtering using a film-forming material such as aluminum, gold, or silver having high reflectance for near-infrared light to form a mirror surface. As a result, the reflection member 22 including the plurality of convex mirrors 22c is generated (see FIG. 29C).

Note that, to prevent oxidation of the reflective film and improve durability, it is desirable to form a protective film including silicon monoxide or the like on the reflective film as needed.

13. Operation of Distance Measuring Device According to Eighth Embodiment of Present Technology

(1) Overall Operation of Distance Measuring Device

In the distance measuring device 10 of the eighth embodiment, the light source device 12 emits light to the object, the light receiving device 14 receives the light reflected by the object, and the control device 16 calculates the distance to the object and generates a distance image.

(2) Operation of Light Source Device

In the light source device 12 of the eighth embodiment, the light source 20 is driven by the light source drive circuit 21, and the light is emitted from the light source 20. The light (emitted light EL) emitted from the light source 20 directly enters the reflection surface 22a of the reflection member 22, and at least part (for example, 99%) of the incident light is reflected by the reflection surface 22a while being diffused toward the transmissive member 30. At least part (99%, for example) of the light (reflected light RL) reflected while being diffused by the reflection surface 22a is transmitted through the transmissive member 30 and radiates the object (subject) as the irradiation light IL.

(3) Operation of Light Receiving Device

In the light receiving device 14 of the eighth embodiment, the light (object light OL) radiated from the light source device 12 to the object and reflected by the object enters the lens unit 32 and is condensed by the lens unit 32. The object light OL passing through the lens unit 32 enters the bandpass filter 36. Only light in a predetermined wavelength band (for example, infrared light), of the object light OL having entered the bandpass filter 36, passes through the bandpass filter 36. The object light OL having passed through the bandpass filter 36 enters the image sensor 38. At this time, the image sensor 38 performs photoelectric conversion at each pixel.

(4) Operation of Control Device

The control device 16 of the eighth embodiment drives the light source 20 via the light source drive circuit 21, calculates, for each pixel, the distance to the object (subject) on the basis of the output of each pixel of the image sensor 38, and generates the distance image.

14. Effect of Distance Measuring Device According to Eighth Embodiment of Present Technology

(1) Effect of Light Source Device

In the light source device 12, the reflection member 22 includes the plurality of convex mirrors 22c (curved mirrors) regularly arranged along the reference plane 22d that the light from the light source 20 enters, and each convex mirror 22c has curvatures in the first axis direction and the second axis direction that are orthogonal to each other within the reference plane 22d.

In the light source device 12, the light from the light source 20 enters the plurality of convex mirrors 22c regularly arranged along the reference plane 22d. The light having entered each convex mirror 22c is reflected while being diffused in the direction (for example, the first axis direction) corresponding to the first axis direction and the direction (for example, the third axis direction) corresponding to the second axis direction while maintaining regularity with each other.

According to the light source device 12, the reflected light RL (reflected light RL having a desired cross-sectional shape) in which the cross-sectional shape perpendicular to the optical axis ROA is the desired shape (target shape TS) can be easily generated.

In contrast, in the case where a plurality of convex mirrors is randomly (irregularly) arranged as in Patent Document 1, for example, the light having entered each convex mirror is reflected while being diffused randomly with each other. Therefore, in Patent Document 1, the reflected light in which the cross-sectional shape perpendicular to the optical axis ROA is the desired shape is less easily generated.

Since the plurality of convex mirrors 22c is regularly arranged according to the target shape TS of the cross section perpendicular to the optical axis ROA of the reflected light RL, the desired reflected light RL can be more easily generated.

Since each of the plurality of convex mirrors 22c is inclined with respect to the reference plane 22d and the shape viewed from the third axis direction orthogonal to the first axis direction is the shape corresponding to the target shape TS, the desired reflected light RL can be even more easily generated.

Since the third axis direction substantially coincides with the optical axis direction (EOAD) of the emitted light EL of the light source 20, the desired reflected light RL can be more reliably generated.

In each of the plurality of convex mirrors 22c, a length in the first axis direction of the shape viewed from the third axis direction, a length in the fourth axis direction of the shape viewed from the third axis direction, a curvature in the first axis direction, and a curvature in the second axis direction are set according to a ratio of a length in a direction corresponding to the first axis direction and a length in a direction corresponding to the fourth axis direction in the target shape TS. Thereby, the shape of the cross section perpendicular to the optical axis ROA of the reflected light RL can be made into a desired shape, and the illuminance within the cross section can be made uniform.

In each of the plurality of convex mirrors 22c, the shape of the cross section perpendicular to the optical axis ROA of the reflected light RL can be made into a desired shape, and the illuminance within the cross section can be made uniform, in the case where the ratio of the length in the fourth axis direction to the length in the first axis direction in the shape viewed from the third axis direction is equal to the ratio of the length in the direction corresponding to the fourth axis direction to the length in the direction corresponding to the first axis direction in the target shape TS, and the curvature in the first axis direction and the curvature in the second axis direction are set to be equal to each other.

Since the plurality of convex mirrors 22c includes at least three convex mirrors 22c and is two-dimensionally arranged as viewed from the third axis direction, the reflected light RL can be spread to a wider range.

Since the plurality of convex mirrors 22c includes at least four convex mirrors 22c and is arranged in a two-dimensional grid manner in the first axis direction and the second axis direction as viewed from the third axis direction, the reflected light RL having a desired cross-sectional shape can be generated with high accuracy, and the illuminance in the cross section perpendicular to the optical axis ROA of the reflected light RL can be made more uniform.

In the case where 0°<α≤60° is satisfied when the angle formed by the tangent line at each end of a convex curve drawn by a cut end obtained by cutting each of the plurality of convex mirrors 22c in the plane orthogonal to the fourth axis direction and the line segment connecting both ends of the convex curve is α/2, the eclipse of the reflected light from each convex mirror 22c by the convex mirror 22c adjacent in the first axis direction to the each convex mirror 22c can be suppressed.

In the case where 0°<β≤60°−(⅔)φ is satisfied when the angle formed by the tangent line at each end of a convex curve drawn by a cut end obtained by cutting each of the plurality of convex mirrors 22c in the plane orthogonal to the first axis direction and the line segment connecting both ends of the convex curve is β/2, and the angle formed by the fourth axis direction with respect to the reference plane as viewed from the first axis direction is 90°−φ, the eclipse of the reflected light from each convex mirror 22c by the convex mirror 22c adjacent in the second axis direction to the each convex mirror 22c can be suppressed.

Since the cut end of each convex mirror 22c is an arc shape, the design of the convex mirror 22c is easy.

Since the plurality of convex mirrors 22c is set to have curvatures in the first axis direction that are equal to each other and have curvatures in the second axis direction that are equal to each other, the desired reflected light can be more easily generated.

Since, in the plurality of convex mirrors 22c, the ratios of the length in the fourth axis direction to the length in the first axis direction in the shape viewed from the third axis direction are equal to each other, the reflected light having a desired cross-sectional shape can be more easily generated.

Since, in the plurality of convex mirrors 22c, the lengths in the first axis direction are equal to each other, and the lengths in the fourth axis direction are equal to each other, in the shape viewed from the third axis direction, the desired reflected light can be even more easily generated.

Since the light source 20 is a laser light source, the light source 20 can generate high-luminance reflected light.

(2) Effect of Distance Measuring Device and Object System

The distance measuring device 10 of the eighth embodiment includes the light source device 12, the light receiving device 14 that receives the light emitted from the light source device 12 and reflected by an object, and the control device 16 that calculates the distance to the object on the basis of at least an output of the light receiving device 14.

According to the distance measuring device 10, the field of illumination FOI by the light source device 12 can be set to a desired range. Therefore, the light is not emitted to a useless range, which is effective in reducing power consumption and increasing the illuminance in a required range.

Since the light source device 12, the light receiving device 14, and the control device 16 are integrally provided, the distance measuring device 10 can be easily mounted on an object (for example, a moving body, an electronic device, or the like).

According to the object system including the distance measuring device 10 and the object (for example, a moving body, an electronic device, or the like) on which the distance measuring device 10 is mounted, a superior object system for safety can be implemented.

The light receiving device 14 includes the image sensor 38, and the target shape TS approximately coincides with the shape of the pixel arrangement region of the image sensor 38. Thereby, the light emitted from the light source device 12 and reflected by the object can be brought to enter the image sensor 38 without waste.

15. Reflection Member According to Ninth Embodiment of Present Technology

FIG. 30A is a perspective view of a reflection member 220. FIG. 30B is a view of the reflection member 220 viewed from a direction perpendicular to a reference plane 220d. FIG. 30C is a view of the reflection member 220 viewed from an optical axis direction EOAD (a third axis direction orthogonal to both a first axis direction and a fourth axis direction) of emitted light EL of a light source 20.

The reflection member 220 according to a ninth embodiment is different from the reflection member 22 according to the eighth embodiment in including a plurality of concave mirrors 220c (an example of a curved mirror) as illustrated in FIGS. 30A to 30C.

That is, the reflection surface 220a of a reflection member 22 is configured by concave surfaces of the plurality of concave mirrors 220c.

Each concave mirror 220c also has curvatures in a first axis direction and a second axis direction.

As illustrated in FIGS. 30A to 30C, the plurality of concave mirrors 220c is arranged in a two-dimensional grid manner along the reference plane 220d.

That is, the plurality of concave mirrors 220c is regularly arranged.

As illustrated in FIG. 30B, each concave mirror 220c has a distorted rectangular shape as viewed from a direction perpendicular to the reference plane 220d.

As illustrated in FIG. 30C, the shape viewed from the third axis direction of each concave mirror 220c is a rectangle that is a shape according to a target shape TS.

As illustrated in FIG. 30C, the plurality of concave mirror 220c is arranged in a two-dimensional grid manner in the first axis direction (a direction corresponding to the first axis direction that is a long side direction of the target shape TS) and in the fourth axis direction (a direction corresponding to the third axis direction that is a short side direction of the target shape TS) as viewed from the third axis direction.

That is, the plurality of concave mirrors 220c is regularly arranged with each other according to the target shape TS.

As illustrated in FIG. 30C, the long side direction of the rectangle, which is the shape viewed from the third axis direction of each concave mirror 220c, is the first axis direction (the direction corresponding to the long side direction of the target shape TS), and the short side direction of the rectangle is the fourth axis direction (the direction corresponding to the short side direction of the target shape TS).

That is, each concave mirror 220c is arranged in an orientation corresponding to the target shape TS.

As described above, the plurality of concave mirrors 220c is regularly arranged according to the target shape TS.

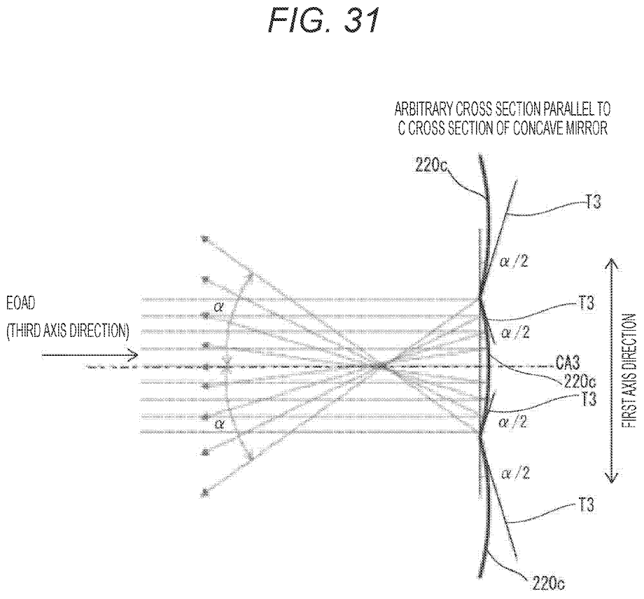

As illustrated in FIG. 31, each concave mirror 220c is designed such that an arbitrary cross section parallel to a C cross section CCS has an arc shape (an example of a concave curve shape), and an angle formed by a tangent line T3 of an arc (an example of a concave curve) drawn by the cross section with respect to the first axis direction continuously changes from −α/2 to +α/2.

That is, an angle formed by a chord (line segment) connecting both ends of an arc (an example of a concave curve) drawn by an arbitrary cross section parallel to the C cross section CCS of each concave mirror 220c and the tangent line T3 (located in an arbitrary plane parallel to the C cross section CCS) at each end of the arc is set to α/2. That is, in each concave mirror 220c, a cut end cut in a plane orthogonal to the fourth axis direction is an arc shape (an example of a concave curve shape), and the angle formed by the tangent line T3 at each end of an arc (an example of a concave curve) drawn by the cut end and the chord (line segment) connecting both ends of the arc is set to α/2.

In this time, an incident angle of light on the arbitrary cross section parallel to the C cross section CCS of each concave mirror 220c continuously changes from −α/2 to +α/2 symmetrically with respect to a central axis CA3 passing through the center in the first axis direction of the cross section and extending in the third axis direction.

Therefore, the reflected light from each concave mirror 220c continuously spreads at the angle of 2α symmetrically with respect to an axis corresponding to the central axis CA3 of the concave mirror 220c in an A cross section ACS or in a plane parallel to the A cross section ACS.

Here, the “axis corresponding to the central axis CA3 of the concave mirror 220c” is an axis parallel to ROA intersecting with the central axis CA3 in a B cross section BCS including the central axis CA3 of the concave mirror 220c or in a plane parallel to the B cross section BCS.

Therefore, when the parallel light is brought to enter each concave mirror 220c, reflected light (irradiation light) having the diffusion angle of 2α within the A cross section ACS and in the arbitrary cross section parallel to the A cross section ACS can be obtained.

Here, if α is increased in the arbitrary cross section parallel to the C cross section, the reflected light from each concave mirror 220c interferes with an adjacent concave mirror 220c, and eclipse occurs. That is, the light reflected by each concave mirror 220c is eclipsed by the concave mirror 220c adjacent in the first axis direction to the each concave mirror 220c.

Therefore, to suppress the eclipse, 0°<α≤90° is desirable.

Note that it is desirable that all the concave mirrors 220c satisfy 0°<α≤90° but only some of the concave mirrors 220c may satisfy 0°<α≤90°.

FIG. 31 illustrates, for convenience, a state in which light enters one concave mirror 220c and is reflected while diffused. In reality, light similarly enters other concave mirrors 220c and is reflected while diffused.

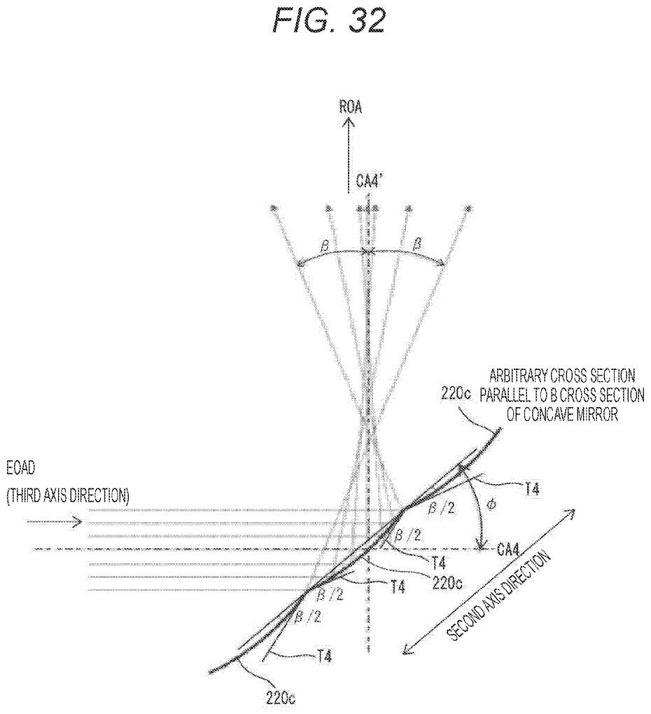

Furthermore, as illustrated in FIG. 32, each concave mirror 220c is designed such that an arbitrary cross section parallel to the B cross section BCS has an arc shape (an example of a concave curve shape), and an angle formed by a tangent line T4 of an arc (an example of a concave curve) drawn by the cross section with respect to the second axis direction continuously changes from −β/2 to +β/2.

That is, an angle formed by a chord (line segment) connecting both ends of an arc (an example of a concave curve) drawn by an arbitrary cross section parallel to the B cross section BCS of each concave mirror 220c and the tangent line T4 (located in an arbitrary plane parallel to the B cross section) at each end of the arc is set to β/2. That is, in each concave mirror 220c, a cut end cut in a plane orthogonal to the first axis direction is an arc shape (an example of a concave curve shape), and the angle formed by the tangent line T4 at each end of an arc (an example of a concave curve) drawn by the cut end and the chord (line segment) connecting both ends of the arc is set to β/2.

In this case, the incident angle of light on each concave mirror 220c continuously changes from (90°−φ)−β/2 to (90°−φ)+β/2.

Therefore, the reflected light from each concave mirror 220c continuously spreads at the angle of 2β symmetrically with respect to an axis CA4′ corresponding to a central axis CA4 of the concave mirror 220c in the B cross section BCS or in the plane parallel to the B cross section BCS.

Here, the above-described “axis CA4′ corresponding to a central axis CA4” is an axis parallel to ROA intersecting with the central axis CA4 in the B cross section BCS including the central axis CA4 of the concave mirror 220c or in the plane parallel to the B cross section BCS.

Therefore, when the parallel light is brought to enter the concave mirror 220c, reflected light (irradiation light) having the diffusion angle of 2β, in the B cross section BCS and in the arbitrary cross section parallel to the B cross section BCS can be obtained.

Here, if β is increased in the arbitrary cross section parallel to the B cross section, the reflected light from each concave mirror 220c interferes with the concave mirror 220c adjacent to the each concave mirror 220c, and eclipse occurs. That is, the light reflected by each concave mirror 220c is eclipsed by the concave mirror 220c adjacent in the second axis direction to the each concave mirror 220c.

Therefore, to suppress the eclipse, 0°<β≤90°−φ is desirable.

Note that it is desirable that all the concave mirrors 220c satisfy 0°<β≤90°−φ but only some of the concave mirrors 220c may satisfy 0°<β≤90°−φ.

FIG. 32 illustrates, for convenience, a state in which light enters one concave mirror 220c and is reflected while diffused. In reality, light similarly enters other concave mirrors 220c and is reflected while diffused.

As a result, by causing the parallel light to enter the concave mirror 220c, reflected light RL (irradiation light IL) having the diffusion angle of 2α in the A cross section ACS and in the arbitrary cross section parallel to the A cross section ACS, and having the diffusion angle of 2β in the B cross section BCS and in the arbitrary cross section parallel to the B cross section BCS can be obtained. That is, the reflected light RL (irradiation light IL) having a desired cross-sectional shape can be generated.

The reflection member 220 of the ninth embodiment also has substantially similar functions and effects to the reflection member 22 of the eighth embodiment.

The reflection member 220 of the ninth embodiment can also be manufactured by a manufacturing method substantially similar to the manufacturing method of the reflection member 22 of the eighth embodiment.

In the ninth embodiment, the reflection member 220 is designed such that an arbitrary cross section parallel to the C cross section CCS and an arbitrary cross section parallel to the B cross section BCS of each concave mirror 220c have an arc shape. However, another concave curve shape may be adopted as long as the curvature continuously changes in the same direction.

Specifically, at least one of the arbitrary cross section parallel to the C cross section CCS or the arbitrary cross section parallel to the B cross section BCS of each concave mirror 220c may have a concave curve shape such as an ellipse, a parabola, a hyperbola, a sine curve, or a cycloidal curve.

The arbitrary cross section parallel to the C cross section CCS and the arbitrary cross section parallel to the B cross section BCS of each concave mirror 220c may have different concave curve shapes from each other.

16. Reflection Member According to Tenth Embodiment of Present Technology

A reflection member of a tenth embodiment is different from the reflection member 22 of the eighth embodiment in that curvatures in a first axis direction and in a second axis direction of each of a plurality of curved mirrors are one of a total of four combinations of curvatures of two positive properties and two negative properties (specifically, the curvatures in the first axis direction and in the second axis direction are both positive, the curvatures in the first axis direction and in the second axis direction are both negative, the curvature in the first axis direction is positive and the curvature in the second axis direction is negative, the curvature in the first axis direction is negative and the curvature in the second axis direction is positive).

Note that when a level difference occurs in a boundary between adjacent curved mirrors, an eclipse occurs. Therefore, to avoid the occurrence of a level difference in the boundary, it is favorable that the positive and negative properties of the curvatures in the second axis direction of a plurality of curved mirrors of a plurality of curved mirror groups each including a plurality of curved mirrors arranged in the first axis direction, and the groups arranged in the second direction, are equal to each other, and the positive and negative properties of the curvatures in the first axis direction of a plurality of curved mirrors of a plurality of curved mirror groups each including a plurality of curved mirrors arranged in the second axis direction, and the groups arranged in the first axis direction, are equal to each other.

Therefore, in the tenth embodiment, examples in which a level difference does not occur at the boundary between adjacent curved mirrors are described as Example 1 and Example 2.

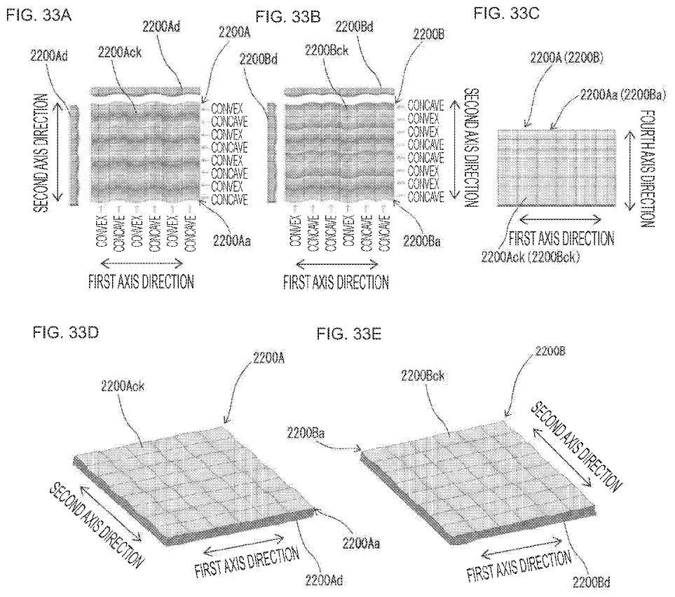

FIG. 33A illustrates a view of a reflection member 2200A of Example 1 of the tenth embodiment viewed from a direction perpendicular to a reference plane 2200Ad (the largest view), a view of the reflection member 2200A viewed from the first axis direction (the narrow view on the left side), and a view of the reflection member 2200A viewed from the second axis direction (the narrow view on the upper side).

FIG. 33B illustrates a view of a reflection member 2200B of Example 2 of the tenth embodiment viewed from a direction perpendicular to a reference plane 2200Bd (the largest view), a view of the reflection member 2200B viewed from the first axis direction (the narrow view on the left side), and a view of the reflection member 2200B viewed from the second axis direction (the narrow view on the upper side).

FIG. 33C is a view of the reflection member 2200A or 2200B of Example 1 or 2 of the tenth embodiment viewed from a third axis direction.

FIG. 33D is a perspective view of the reflection member 2200A of the Example 1 of the tenth embodiment.

FIG. 33E is a perspective view of the reflection member 2200B of Example 2 of the tenth embodiment.

In the reflection members 2200A and 2200B of Examples 1 and 2 of the tenth embodiment, an arbitrary cross section parallel to a C cross section CCS and an arbitrary cross section parallel to a B cross section BCS of each curved mirror have an arc shape. However, the embodiment is not limited to the cases. For example, the arbitrary cross sections may have a curved shape such as an ellipse, a parabola, a hyperbola, a sine curve, or a cycloid curve.

The arbitrary cross section parallel to the C cross section CCS and the arbitrary cross section parallel to the B cross section BCS of each curved mirror may have different curve shapes from each other.

(1) Reflection Member of Example 1

As illustrated in FIGS. 33A and 33D, in the reflection member 2200A of Example 1, a reflection surface 2200Aa is configured by curved surfaces (surfaces) of a plurality of (N) curved mirrors 2200Ack (k=1 to N).

The plurality of curved mirrors 2200Ack is arranged in a two-dimensional grid manner along the reference plane 2200Ad.

That is, the plurality of curved mirrors 2200Ack is regularly arranged.

More specifically, in the reflection member 2200A, the plurality of curved mirrors 2200Ack is arranged in a two-dimensional grid manner in the first axis direction and in the fourth axis direction as viewed from the third axis direction, as illustrated in FIG. 33C.

That is, the plurality of curved mirrors 2200Ack is regularly arranged with each other according to a target shape TS.

Each curved mirror 2200Ack has a distorted rectangular shape, as illustrated in FIG. 33A.

As illustrated in FIG. 33C, the shape viewed from the third axis direction of each curved mirror 2200Ack is a rectangle that is a shape according to the target shape TS.

A long side direction of the shape viewed from the third axis direction of each curved mirror 2200Ack is the first axis direction (a direction corresponding to the long side direction of the target shape TS), and a short side direction is the fourth axis direction (a direction corresponding to the short side direction of the target shape TS).

That is, each curved mirror 2200Ack is arranged in an orientation corresponding to the target shape TS.

In this way, the plurality of curved mirrors 2200Ack is regularly arranged according to the target shape TS.

Furthermore, in the reflection member 2200A, as illustrated in FIGS. 33A and 33C, the positive and negative properties in the first axis direction of the curvatures of the plurality of curved mirrors 2200Ack arranged in the second axis direction (arranged in the fourth axis direction) are set to be equal to each other, and the positive and negative properties in the second axis direction of the curvatures of the plurality of curved mirrors 2200Ack arranged in the first axis direction are set to be equal to each other.

Thereby, formation of a level difference between the curved mirrors 2200Ack adjacent in the first axis direction and between the curved mirrors 2200Ack adjacent in the second axis direction can be prevented.

That is, the curved mirrors 2200Ack adjacent in the first axis direction can be smoothly connected to each other, and the curved mirrors 2200Ack adjacent in the second axis direction can be smoothly connected to each other.

Moreover, in the reflection member 2200A, as illustrated in FIGS. 33A and 33C, the positive and negative properties of the curvatures in the first axis direction are set to be opposite to each other between adjacent curved mirror groups, of a plurality of curved mirror groups each including the plurality of curved mirrors 2200Ack arranged in the second axis direction (arranged in the fourth axis direction) and the groups arranged in the first axis direction. The positive and negative properties of the curvatures in the second axis direction are set to be opposite to each other between adjacent curved mirror groups, of a plurality of curved mirror groups each including the plurality of curved mirrors 2200Ack arranged in the first axis direction and the groups arranged in the second axis direction (arranged in the fourth axis direction).

That is, as illustrated in FIGS. 33A and 33D, the reflection member 2200A has a shape in which concave and convex shapes are alternately arranged as viewed from both the first axis direction and the second axis direction.

Note that the convex display on the lower side of the largest view of FIG. 33A (the figure illustrating the reflection member 2200A) indicates that the curvatures in the first axis direction of all the curved mirrors arranged in the second axis direction above the convex display are convex (positive). The concave display on the lower side of the largest view of FIG. 33A (the figure illustrating the reflection member 2200A) indicates that the curvatures in the first axis direction of all the curved mirrors arranged in the second axis direction above the concave display are concave (negative). The convex display on the right side of the largest view of FIG. 33A (the figure illustrating the reflection member 2200A) indicates that the curvatures in the second axis direction of all the curved mirrors arranged in the first axis direction on the left side of the convex display are convex (positive). The concave display on the right side of the largest view of FIG. 33A (the figure illustrating the reflection member 2200A) indicates that the curvatures in the second axis direction of all the curved mirrors arranged in the first axis direction on the left side of the concave display are concave (negative).

(2) Reflection Member of Example 2

As illustrated in FIGS. 33B and 33E, in the reflection member 2200B of Example 2, a reflection surface 2200Ba is configured by curved surfaces (surfaces) of a plurality of (N) curved mirrors 2200Bck (k=1 to N).

The plurality of curved mirrors 2200Bck is arranged in a two-dimensional grid manner (regularly) along the reference plane 2200Bd.

That is, the plurality of curved mirrors 2200Bck is regularly arranged.

More specifically, as illustrated in FIG. 33C, in the reflection member 2200B, the plurality of curved mirrors 2200Bck is arranged in a two-dimensional grid manner in the first axis direction (the direction corresponding to the long side direction of the target shape TS) and in the fourth axis direction (the direction corresponding to the short side direction of the target shape TS) as viewed from the third axis direction.

That is, the plurality of curved mirrors 2200Bck is regularly arranged with each other according to a target shape TS.

Each curved mirror 2200Bck has a distorted rectangular shape, as illustrated in FIG. 33B.

As illustrated in FIG. 33C, the shape viewed from the third axis direction of each curved mirror 2200Bck is a rectangle that is a shape according to the target shape TS.

As illustrated in FIG. 33C, the long side direction of the shape viewed from the third axis direction of each curved mirror 2200Bck is the first axis direction (the direction corresponding to the long side direction of the target shape TS), and the short side direction is the fourth axis direction (the direction corresponding to the short side direction of the target shape TS).

That is, each curved mirror 2200Bck is arranged in an orientation corresponding to the target shape TS.

In this way, the plurality of curved mirrors 2200Bck is regularly arranged according to the target shape TS.

Furthermore, in the reflection member 2200B, as illustrated in FIGS. 33B and 33C, the positive and negative properties in the first axis direction of the curvatures of the plurality of curved mirrors 2200Bck arranged in the second axis direction (arranged in the fourth axis direction) are set to be equal to each other, and the positive and negative properties in the second axis direction of the curvatures of the plurality of curved mirrors 2200Bck arranged in the first axis direction are set to be equal to each other.

Thereby, formation of a level difference between the curved mirrors 2200Bck adjacent in the first axis direction and between the curved mirrors 2200Bck adjacent in the second axis direction can be prevented.

That is, the curved mirrors 2200Bck adjacent in the first axis direction can be smoothly connected to each other, and the curved mirrors 2200Bck adjacent in the second axis direction can be smoothly connected to each other.

Moreover, in the reflection member 2200B, as illustrated in FIGS. 33B and 33C, the positive and negative properties of the curvatures in the first axis direction are set to be opposite to each other among some adjacent curved mirror groups, of a plurality of curved mirror groups each including the plurality of curved mirrors 2200Bck arranged in the second axis direction (arranged in the fourth axis direction) and the groups arranged in the first axis direction, and the positive and negative properties of the curvatures in the first axis direction are set to be equal to each other among other adjacent curved mirror groups. In the reflection member 2200B, as illustrated in FIGS. 33B and 33C, the positive and negative properties of the curvatures in the second axis direction are set to be opposite to each other among some adjacent curved mirror groups, of a plurality of curved mirror groups each including the plurality of curved mirrors 2200Bck arranged in the first axis direction and the groups arranged in the second axis direction (arranged in the fourth axis direction), and the positive and negative properties of the curvatures in the second axis direction are set to be equal to each other among other adjacent curved mirror groups.

That is, as illustrated in FIGS. 33B and 33E, the reflection member 2200B has a shape in which concave and convex shapes are randomly arranged as viewed from both the first axis direction and the second axis direction.

Note that the convex display on the lower side of the largest view of FIG. 33B (the figure illustrating the reflection member 2200B) indicates that the curvatures in the first axis direction of all the curved mirrors arranged in the second axis direction above the convex display are convex (positive). The concave display on the lower side of the largest view of FIG. 33B (the figure illustrating the reflection member 2200B) indicates that the curvatures in the first axis direction of all the curved mirrors arranged in the second axis direction above the concave display are concave (negative). The convex display on the right side of the largest view of FIG. 33B (the figure illustrating the reflection member 2200B) indicates that the curvatures in the second axis direction of all the curved mirrors arranged in the first axis direction on the left side of the convex display are convex (positive). The concave display on the right side of the largest view of FIG. 33B (the figure illustrating the reflection member 2200B) indicates that the curvatures in the second axis direction of all the curved mirrors arranged in the first axis direction on the left side of the concave display are concave (negative).

Since the reflection member of each example of the tenth embodiment also has the curvatures in the first axis direction and in the second axis direction as in the reflection members 22 and 220 of the eighth and ninth embodiments, the reflection member can reflect while diffusing the incident light in the direction corresponding to the first axis direction (for example, the first axis direction) and in the direction corresponding to the second axis direction (for example, the third axis direction).

The reflection member of each example of the tenth embodiment also has substantially similar functions and effects to the reflection member 22 of the eighth embodiment.

Manufacturing of the reflection member of each example of the tenth embodiment is a little complicated because the shape of each curved mirror is not uniform as compared with the reflection member 22 of the eighth embodiment, but the reflection member of the tenth embodiment can be manufactured by a method based on the method of manufacturing the reflection member 22 of the eighth embodiment.

In the case where at least one curved mirror of the reflection members of the examples of the tenth embodiment has a convex curve shape in a cut end cut in the plane orthogonal to the fourth axis direction, similarly to the eighth embodiment, it is favorable to satisfy 0°<α≤60° where an angle formed by a tangent line at each end of a convex curve drawn by the cut end and a line segment connecting both ends of the convex curve is α/2.

In the case where at least one curved mirror of the reflection members of the examples of the tenth embodiment has a convex curve shape in a cut end cut in a plane orthogonal to the first axis direction, similarly to the eighth embodiment, it is favorable to satisfy 0°<β≤60°−(⅔)φ where an angle formed by a tangent line at each end of a convex curve drawn by the cut end and a line segment connecting both ends of the convex curve is β/2, and an angle formed by the fourth axis direction with respect to the reference plane as viewed from the first axis direction is 90°−φ.

In the case where at least one curved mirror of the reflection members of the examples of the tenth embodiment has a concave curve shape in a cut end cut in the plane orthogonal to the fourth axis direction, similarly to the ninth embodiment, it is favorable to satisfy 0°<α≤90° where an angle formed by a tangent line at each end of a concave curve drawn by the cut end and a line segment connecting both ends of the concave curve is α/2.

In the case where at least one curved mirror of the reflection members of the examples of the tenth embodiment has a concave curve shape in a cut end cut in a plane orthogonal to the first axis direction, similarly to the ninth embodiment, it is favorable to satisfy 0°<β≤90°−φ where an angle formed by a tangent line at each end of a concave curve drawn by the cut end and a line segment connecting both ends of the concave curve is β/2, and an angle formed by the fourth axis direction with respect to the reference plane as viewed from the first axis direction is 90°−φ.

As can be seen from the first to tenth embodiments, the reflection members of the present technology have a very high degree of freedom in setting the curvatures in the first and second axis directions orthogonal to each other in the reference plane.

Note that some of the configurations of the reflection members of the first to tenth embodiments can be applied to each other within the technical consistency.

17. Light Source Device According to Modification of Present Technology

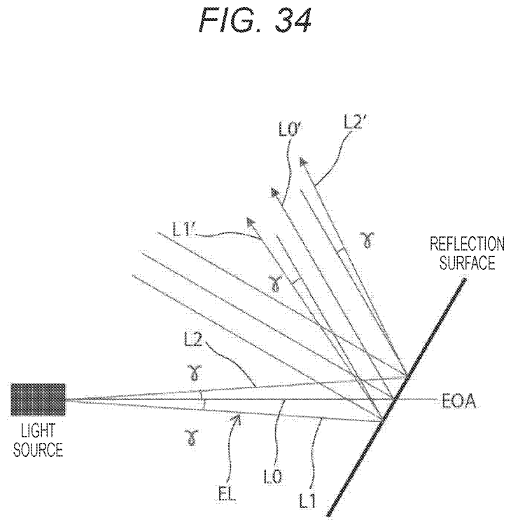

The description given so far is based on the assumption that the laser light entering the reflection member 22 can be regarded as parallel light. However, as illustrated in FIG. 34, since the emitted light EL from the light source 20 usually has a spread angle of 2γ (γ on one side) to a greater or lesser extent, the field of illumination FOI by the reflected light RL becomes wider than the fields of illumination FOI of the diffusion angles 2α and 2β described so far by the spread angle 2γ of the emitted light EL.

That is, in FIG. 34, reflected light L0′ from the reflection surface (here, a plane mirror is used for convenience of description) of a light ray L0 passing on an optical axis EOA of the emitted light EL is not affected at all in the reflection direction by the spread angle γ. In contrast, reflected light L1′ and L2′ from the reflection surface of rays L1 and L2 having the spread angle γ with respect to the optical axis of the emitted light EL are shifted outward in the reflecting direction by the spread angle γ.

In this case, the influence of the spread angle 2γ is negligible for the curved mirror near the center of a light spot LS (see FIG. 21), whereas the influence of the spread angle 2γ is larger for the curved mirror closer to a periphery of the light spot LS. Therefore, there is a concern that variation in illuminance in the field of illumination FOI of the reflected light RL becomes large.

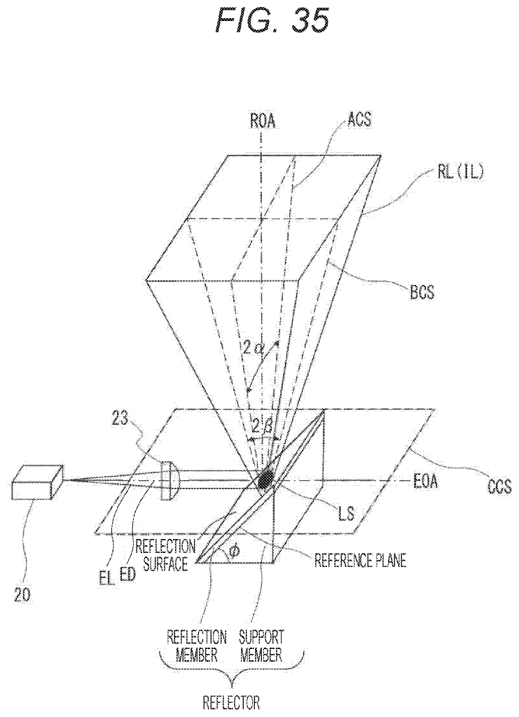

As a countermeasure, a collimator lens 23 is arranged on the optical path between the light source 20 and the reflection member as illustrated in FIG. 35 (favorably, the optical axis of the collimator lens 23 is arranged so as to match EOA), so that the laser light with the spread angle 2γ can be corrected to parallel light. Therefore, the influence of the spread angle 2γ can be eliminated or reduced. Note that FIG. 35 illustrates only the light source 20 in the light source device, the collimator lens 23, and the reflector, for convenience.

Note that the influence of the spread angle 2γ can be corrected without arranging the collimator lens 23 between the light source 20 and the reflection member. That is, since the distance between the light source 20 and the reflection member can be shortened, the influence of the spread angle 2γ can be corrected while suppressing the increase in size of the package 31. As illustrated in FIG. 34, in general, when the emitted light EL having the spread angle of 2γ (γ on one side) is brought to enter a plane mirror, the spread angle of the reflected light is also 2γ. From the above fact, the angle of the tangent line of a convex curve or a concave curve drawn by the cross section of the curved mirror may be corrected in a range of −γ/2 to +γ/2 according to an increase or a decrease in the incident angle on the curved mirror due to the spread angle for each ray included in the emitted light EL with reference to the optical axis EOA of the emitted light EL. The reflected light from each curved mirror can be made into parallel light, and the influence of the spread angle can be eliminated or reduced.

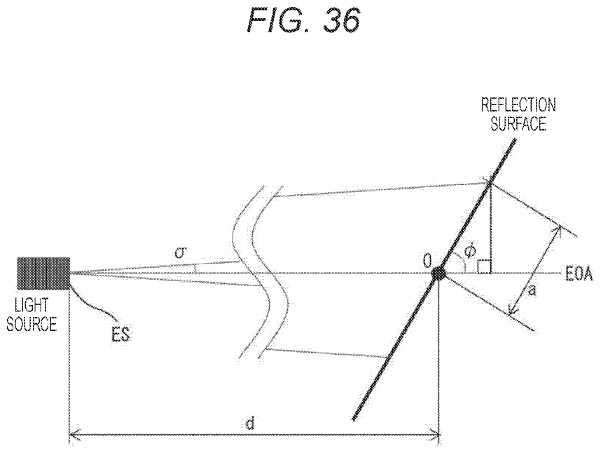

Here, parameters d, φ, σ, and a illustrated in FIG. 36 are defined as follows.

d: the distance from a light emitting point (emission surface ES) of the light source 20 to an intersection O of EOA and the reflection surface (illustrated as a plane mirror in FIG. 36 for convenience)

φ: the angle φ formed by EOA and the reflection surface (0°<φ≤90°)

σ: the spread angle σ on one side of each ray included in the emitted light EL of the light source 20 (0°≤|σ|≤γ<45°)

a: the distance from the intersection O to an intersection of a ray with the spread angle σ and the reflection surface

At this time, (d+a×cos φ) tan σ=a×sin φ is established.

When the equation is transformed, a=d/(sin φ/tan σ−cos φ) . . . (*)

If φ=45°, a=√2×d/(1/tan σ−1)

If φ=90°, a=d×tan σ

Correction is performed with a correction angle σ/2 in a direction in which the field of illumination FOI (diffusion angle) by the reflected light RL is narrowed to the reflection surface with a radius a obtained from the above equation (*) when σ is changed from −γ to γ. Note that, when σ is negative, a is also negative (in the opposite direction).

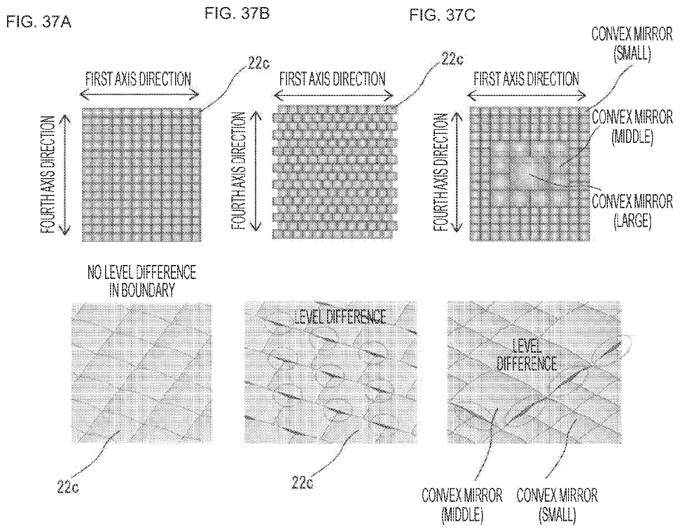

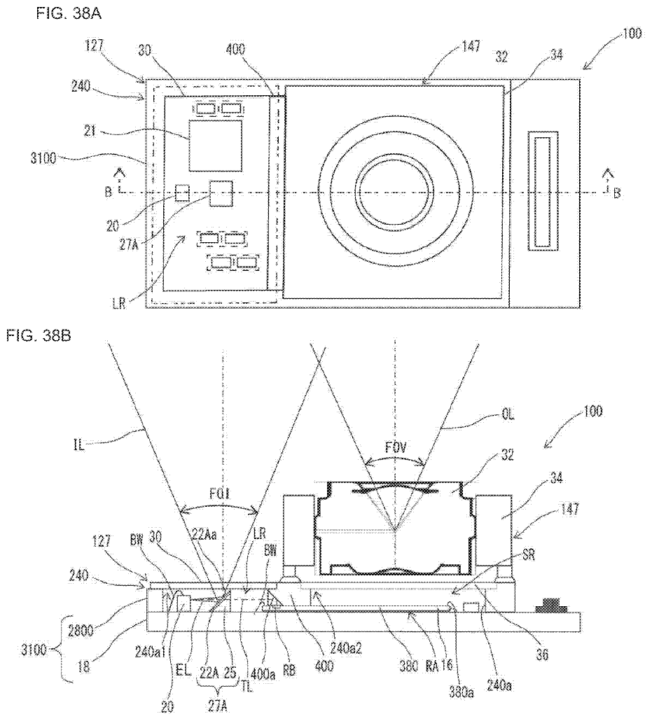

Furthermore, the arrangement of the plurality of curved mirrors of the reflection member according to the present technology as viewed from the third axis direction is not limited to the grid-like arrangement illustrated in the upper figure in FIG. 37A, and may be a staggered arrangement illustrated in the upper figure in FIG. 37B or may be a combination arrangement in which different sizes are combined illustrated in the upper figure in FIG. 37C.

As can be seen from the lower figure in FIG. 37A (the perspective view of the grid-like arrangement), the level difference between the adjacent convex mirrors 22c can be eliminated in the grid-like arrangement.

In contrast, as can be seen from the lower figure in FIG. 37B (the perspective view of the staggered arrangement) or the lower figure in FIG. 37C (the perspective view of the combination arrangement), the level difference occurs between adjacent convex mirrors 22c in the staggered arrangement or the combination arrangement.

Therefore, the grid-like arrangement is the most favorable as the arrangement of the plurality of curved mirrors of the reflection member according to the present technology as viewed from the third axis direction.

Note that, here, as illustrated in FIGS. 37A to 37C, the description has been given using the convex mirror as an example among curved mirrors, but a similar argument holds for the concave mirror.

18. Distance Measuring Device According to Eleventh Embodiment of Present Technology

(1) Configuration of Distance Measuring Device

In a distance measuring device 100 according to an eleventh embodiment, as illustrated in FIG. 38, a configuration is adopted in which a light source 20 of a light source device 127, a reflector 27A including a reflection member 22A having a slight light transmissive property (for example, the transmittance of 1%) and a support member 25, an image sensor 380 of a light receiving device 147, and a control device 16 are directly mounted on a circuit board 18. Moreover, a peripheral wall 2800 is provided on the circuit board 18 so as to surround the light source 20, the reflection member 22A, the image sensor 380, and the control device 16. The reflection member 22A has configurations and functions similar to the reflection member according to any one of the eighth to tenth embodiments, except having a light transmissive property.

That is, in the distance measuring device 100 of the eleventh embodiment, a holder 240 is configured, which includes a package 3100 including the circuit board 18 and a peripheral wall 2800, and holds the light source 20, the reflector 27A, the image sensor 380, and the control device 16. That is, in the distance measuring device 100, the light source 20, the reflector 27A, the image sensor 380, and the control device 16 are held by the common holder 240. More specifically, the light source 20, the reflector 27A, the image sensor 380, and the control device 16 are arranged in a recess 240a of the holder 240, that is, in a region inside the peripheral wall 2800 on the circuit board 18. The image sensor 380 and the control device 16 are provided on the same sensor board 380a (semiconductor board). An object system is configured by including the distance measuring device 100 and the object (for example, a moving body, an electronic device, or the like) on which the distance measuring device 100 is mounted. Again, a field of illumination FOI is set to be the same as or slightly larger than a field of view FOV.

A light-shielding block 400 extending in a direction orthogonal to the paper surface of FIG. 38 is bridged over the recess 240a (a region inside the peripheral wall 2800) of the holder 240. That is, the recess 240a of the holder 240 is divided by the light-shielding block 400 into a light source region LR in which the light source 20 and the reflector 27A are arranged and a sensor region SR in which most of the image sensor 380 is arranged. An opening 240a1 of the light source region LR of the recess 240a is covered with a transmissive member 30. An opening 240a2 of the sensor region SR of the recess 240a is covered with a bandpass filter 36.

In the sensor region SR of the recess 240a, a first light receiving region RA including a pixel group for distance measurement of the image sensor 380 is arranged. The first light receiving region RA corresponds to the pixel arrangement region of the image sensor 380 of the eighth embodiment. Here, the shape of the first light receiving region RA is rectangular. A target shape TS has the same shape as the first light receiving region RA (a rectangle with the same aspect ratio).

Even if the reflection member 22A is damaged or falls off, at least part of the light emitted from the light source 20 is blocked by the light-shielding block 400. Therefore, the light does not enter the first light receiving region RA.

As illustrated in FIG. 38A, a light source drive circuit 21 is mounted on a bottom surface of a region adjacent to the light source 20 and the reflector 27A in the light source region LR (a region on the depth side of the paper surface of the light source 20 and the reflector 27A in FIG. 38B).

The image sensor 380 has a second light receiving region RB for light detection (for example, a region where a PD is formed) in the light source region LR in addition to the first light receiving region RA including the pixel group for distance measurement. The light-shielding block 400 has a mirror surface 400a on an optical path of light (transmitted light TL) emitted from the light source 20 and transmitted through the reflector 27A. The mirror surface 400a is arranged so as to be inclined (for example, by 45°) with respect to the circuit board 18 to face the reflection member 22A and the second light receiving region RB. Conversely, the second light receiving region RB is arranged on the optical path of the light transmitted through the reflector 27A and reflected by the mirror surface 400a.

(2) Operation of Distance Measuring Device

In the distance measuring device 100, the light source 20 is driven by the light source drive circuit 21, and the light source 20 emits light. Part (most) of the light emitted from the light source 20 is reflected and diffused by the reflection member 22A, transmitted through the transmissive member 30, and radiated to an object. The light through the lens unit 32 and the bandpass filter 36, of the light (object light OL) radiated to the object and reflected by the object is condensed on the first light receiving region RA of the image sensor 380. The first light receiving region RA sends an output (a photoelectrically converted electric signal) for each pixel to the control device 16. The control device 16 generates a distance image on the basis of the output of each pixel of the first light receiving region RA.

On the other hand, another part (a small amount) of the light emitted from the light source 20 is transmitted through the reflector 27A, reflected by the mirror surface 400a, and condensed on the second light receiving region RB. The second light receiving region RB sends an output (a photoelectrically converted electric signal) to the control device 16. The control device 16 performs various controls (for example, control of the amount of emitted light, distance calculation based on detected emission timing, and the like) on the basis of the output of the second light receiving region RB.

(3) Effect of Distance Measuring Device and Object System

The distance measuring device 100 of the eleventh embodiment includes the light source device 127, the light receiving device 147 that receives the light emitted from the light source device 127 and reflected by an object, and the control device 16 that calculates the distance to the object on the basis of at least an output of the light receiving device 147.

Thereby, the distance measuring device 100 capable of effectively using the irradiation light IL can be implemented.

Since the light source device 127, the light receiving device 147, and the control device 16 are integrally provided, the distance measuring device 100 can be easily mounted on an object (for example, a moving body, an electronic device, or the like).

The light receiving device 147 includes the image sensor 380 having the first light receiving region RA for receiving the light emitted from the light source device 127 and reflected by the object and the second light receiving region RB for receiving the light (transmitted light TL) emitted from the light source 20 and transmitted through the reflector 27A. Thereby, the number of parts can be reduced and the distance measuring device 100 can be downsized.

According to the object system including the distance measuring device 100 and the object (for example, a moving body, an electronic device, or the like) on which the distance measuring device 100 is mounted, a superior object system for use efficiency of the irradiation light IL can be implemented.

Note that, in the holder 240, the recess 240a and the window 30 are not essential. That is, in the holder 240, the peripheral wall 2800 and the transmissive member 30 are not essential. The holder 240 may be configured by only the circuit board 18. The holder 240 may be configured by only the circuit board 18 and the peripheral wall 2800, that is, only the package 3100. In the holder 240, the circuit board 18 is used as the base member on which the light source 20 is mounted, but a member other than the circuit board (for example, a non-plate-shaped member) may be used.

19. Applications to Moving Bodies

The light source unit and the distance measuring device according to the present technology can be applied to various products. For example, the light source unit and the distance measuring device according to the present technology can be mounted on any type of moving bodies including an automobile, an electric automobile, a hybrid electric automobile, a motorcycle, a bicycle, a personal mobility, an airplane, a drone, a ship, a robot, a construction machine, and an agricultural machine (tractor) to implement a moving body system (an example of the object system) For example, the light source unit and the distance measuring device according to the present technology can be applied to a vehicle exterior information detection unit or a vehicle interior information detection unit of a vehicle control system to be described below.

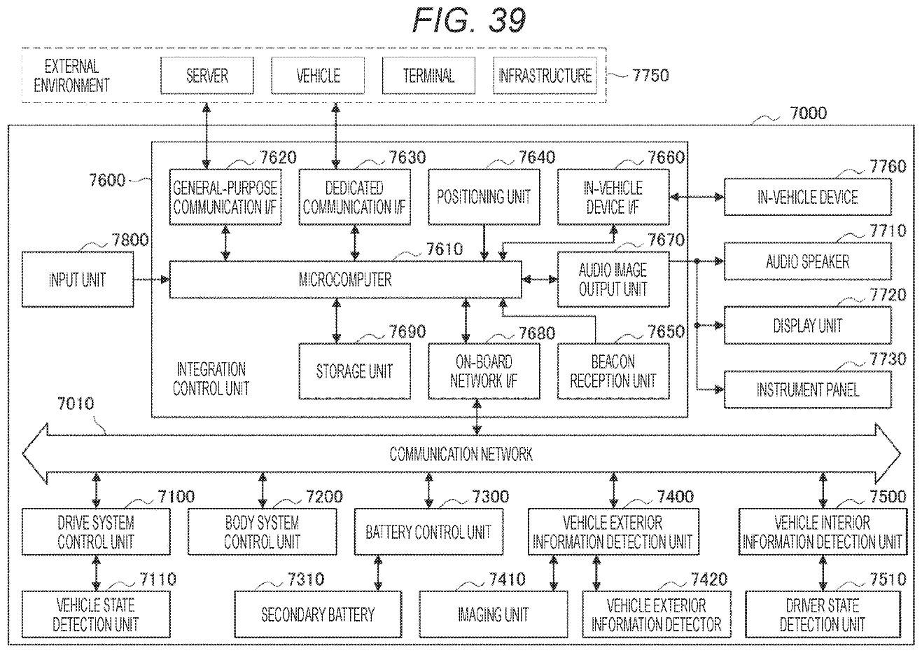

FIG. 39 is a block diagram illustrating a schematic configuration example of a vehicle control system 7000 as an example of a moving body control system to which the technology according to the present disclosure is applicable. A vehicle control system 7000 includes a plurality of electronic control units connected through a communication network 7010. In the example illustrated in FIG. 39, the vehicle control system 7000 includes a drive system control unit 7100, a body system control unit 7200, a battery control unit 7300, a vehicle exterior information detection unit 7400, a vehicle interior information detection unit 7500, and an integration control unit 7600. The communication network 7010 that connects the plurality of control units may be, for example, an on-board communication network conforming to an arbitrary standard such as a controller area network (CAN), a local interconnect network (LIN), a local area network (LAN), or FlexRay (registered trademark).

Each control unit includes a microcomputer that performs arithmetic processing according to various programs, a storage unit that stores programs executed by the microcomputer, parameters used for various calculations, and the like, and a drive circuit that drives various devices to be controlled. Each control unit includes a network I/F for communicating with another control unit via the communication network 7010 and a communication I/F for communicating with a device, a sensor, or the like inside and outside the vehicle by wired communication or wireless communication. FIG. 39 illustrates, as functional configurations of the integration control unit 7600, a microcomputer 7610, a general-purpose communication I/F 7620, a dedicated communication I/F 7630, a positioning unit 7640, a beacon reception unit 7650, an in-vehicle device I/F 7660, an audio image output unit 7670, an on-board network I/F 7680, and a storage unit 7690. Similarly, the other control units include a microcomputer, a communication I/F, a storage unit, and the like.

The drive system control unit 7100 controls operations of devices regarding a drive system of a vehicle according to various programs. For example, the drive system control unit 7100 functions as a control device of a drive force generation device for generating drive force of a vehicle, such as an internal combustion engine or a drive motor, a drive force transmission mechanism for transmitting drive force to wheels, a steering mechanism that adjusts a steering angle of a vehicle, a braking device that generates braking force of a vehicle and the like. The drive system control unit 7100 may have a function as a control device of an antilock brake system (ABS), electronic stability control (ESC), or the like.

The drive system control unit 7100 is connected with a vehicle state detection unit 7110. The vehicle state detection unit 7110 includes, for example, at least one of a gyro sensor for detecting angular velocity of an axial rotational motion of a vehicle body, an acceleration sensor for detecting acceleration of the vehicle, or a sensor for detecting an operation amount of an accelerator pedal, an operation amount of a brake pedal, a steering angle of a steering wheel, an engine speed, rotation speed of a wheel, or the like. The drive system control unit 7100 performs arithmetic processing using a signal input from the vehicle state detection unit 7110 and controls the internal combustion engine, the drive motor, an electric power steering device, a brake device, or the like.

The body system control unit 7200 controls operations of various devices equipped in the vehicle body according to various programs. For example, the body system control unit 7200 functions as a control device of a keyless entry system, a smart key system, an automatic window device, and various lamps such as head lamps, back lamps, brake lamps, turn signals, and fog lamps. In this case, radio waves transmitted from a mobile device substituted for a key or signals of various switches can be input to the body system control unit 7200. The body system control unit 7200 receives an input of the radio waves or the signals, and controls a door lock device, the automatic window device, the lamps, and the like of the vehicle.

The battery control unit 7300 controls a secondary battery 7310 that is a power supply source of the drive motor according to various programs. For example, the battery control unit 7300 receives information such as a battery temperature, a battery output voltage, or a remaining capacity of the battery from a battery device including the secondary battery 7310. The battery control unit 7300 performs arithmetic processing using these signals to control temperature adjustment of the secondary battery 7310, a cooling device provided in the battery device, or the like.

The vehicle exterior information detection unit 7400 detects information outside the vehicle that mounts the vehicle control system 7000. For example, at least one of an imaging unit 7410 or a vehicle exterior information detector 7420 is connected to the vehicle exterior information detection unit 7400. The imaging unit 7410 includes at least one of a time of flight (ToF) camera, a stereo camera, a monocular camera, an infrared camera, or another camera. The vehicle exterior information detector 7420 includes, for example, at least one of an environmental sensor for detecting current weather or atmospheric phenomena or an ambient information detection sensor for detecting other vehicles, obstacles, pedestrians, and the like around the vehicle equipped with the vehicle control system 7000.

The environmental sensor may be, for example, at least one of a raindrop sensor for detecting rainy weather, a fog sensor for detecting fog, a sunshine sensor for detecting the degree of sunshine, or a snow sensor for detecting snowfall. The ambient information detection sensor may be at least one of an ultrasonic sensor, a radar device, or a light detection and ranging or laser imaging detection and ranging (LIDAR) device. The imaging unit 7410 and the vehicle exterior information detector 7420 may be provided as independent sensors or devices, respectively, or may be provided as devices in which a plurality of sensors or devices is integrated.

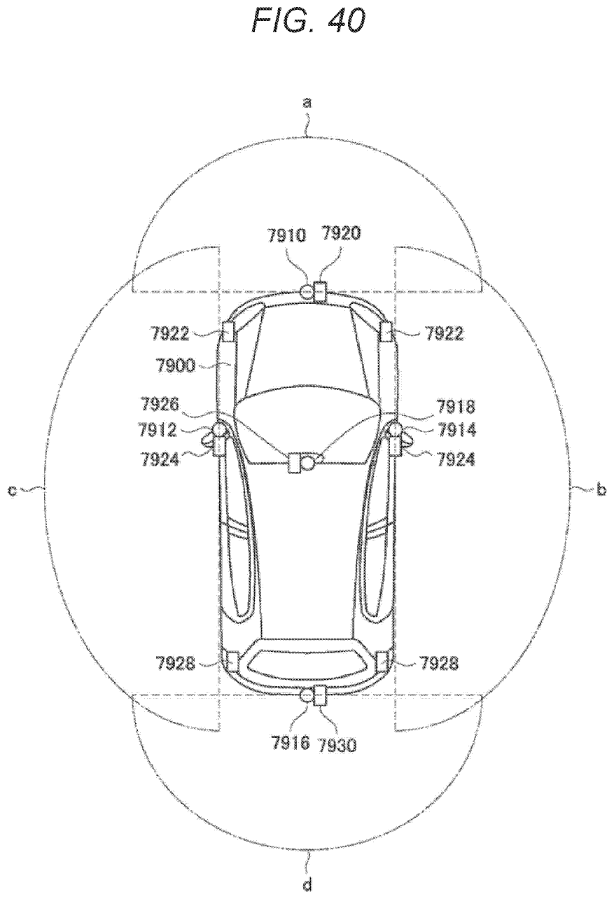

Here, FIG. 40 illustrates an example of installation positions of the imaging unit 7410 and the vehicle exterior information detector 7420. Each of imaging units 7910, 7912, 7914, 7916, and 7918 is provided on at least one position of a front nose, side mirrors, a rear bumper, a back door, or an upper portion of a windshield in an interior of a vehicle 7900, for example. The imaging unit 7910 provided at the front nose and the imaging unit 7918 provided at the upper portion of the windshield in an interior of the vehicle mainly acquire front images of the vehicle 7900. The imaging units 7912 and 7914 provided at the side mirrors mainly acquire side images of the vehicle 7900. The imaging unit 7916 provided at the rear bumper or the back door mainly acquires a rear image of the vehicle 7900. The imaging unit 7918 provided at the upper portion of the windshield in the interior of the vehicle is mainly used for detecting a preceding vehicle, a pedestrian, an obstacle, a traffic signal, a traffic sign, a lane, or the like.

Note that FIG. 40 illustrates an example of capture ranges of the imaging units 7910, 7912, 7914, and 7916. An imaging range a indicates an imaging range of the imaging unit 7910 provided at the front nose, imaging ranges b and c respectively indicate imaging ranges of the imaging units 7912 and 7914 provided at the side mirrors, and an imaging range d indicates an imaging range of the imaging unit 7916 provided at the rear bumper or the back door. For example, a bird's-eye view image of the vehicle 7900 as viewed from above can be obtained by superimposing image data imaged in the imaging units 7910, 7912, 7914, and 7916.

Vehicle exterior information detectors 7920, 7922, 7924, 7926, 7928, and 7930 provided at the front, rear, side, corner, and upper portion of the windshield in the interior of the vehicle 7900 may be ultrasonic sensors or radar devices, for example. Vehicle exterior information detectors 7920, 7926, and 7930 provided at the front nose, the rear bumper, the back door, and the upper portion of the windshield in the interior of the vehicle 7900 may be LIDAR devices, for example. These vehicle exterior information detectors 7920 to 7930 are mainly used for detecting a preceding vehicle, a pedestrian, an obstacle, and the like.

Referring back to FIG. 39, the description will be continued. The vehicle exterior information detection unit 7400 causes the imaging unit 7410 to image an image outside the vehicle, and receives the imaged image data. Furthermore, the vehicle exterior information detection unit 7400 receives detection information from the connected vehicle exterior information detector 7420. In a case where the vehicle exterior information detector 7420 is an ultrasonic sensor, a radar device, or an LIDAR device, the vehicle exterior information detection unit 7400 transmits ultrasonic waves, electromagnetic waves, or the like and receives information of received reflected waves. The vehicle exterior information detection unit 7400 may perform object detection processing or distance detection processing of persons, vehicles, obstacles, signs, letters or the like on a road surface on the basis of the received information. The vehicle exterior information detection unit 7400 may perform environment recognition processing of recognizing rainfall, fog, a road surface condition, or the like on the basis of the received information. The vehicle exterior information detection unit 7400 may calculate the distance to the object outside the vehicle on the basis of the received information.

Furthermore, the vehicle exterior information detection unit 7400 may perform image recognition processing or distance detection processing of recognizing persons, vehicles, obstacles, signs, letters, or the like on a road surface on the basis of the received image data. The vehicle exterior information detection unit 7400 may perform processing such as distortion correction or alignment for the received image data and combine the image data imaged by different imaging units 7410 to generate a bird's-eye view image or a panoramic image. The vehicle exterior information detection unit 7400 may perform viewpoint conversion processing using the image data imaged by the different imaging units 7410.

The vehicle interior information detection unit 7500 detects information inside the vehicle. A driver state detection unit 7510 that detects a state of a driver is connected to the vehicle interior information detection unit 7500, for example. The driver state detection unit 7510 may include a camera for imaging the driver, a biometric sensor for detecting biological information of the driver, a microphone for collecting sounds in the interior of the vehicle, and the like. The biometric sensor is provided, for example, on a seating surface, a steering wheel, or the like, and detects the biological information of an occupant sitting on a seat or the driver holding the steering wheel. The vehicle interior information detection unit 7500 may calculate the degree of fatigue or the degree of concentration of the driver or may determine whether or not the driver falls asleep at the wheel on the basis of detection information input from the driver state detection unit 7510. The vehicle interior information detection unit 7500 may perform processing such as noise canceling processing for collected sound signals.

The integration control unit 7600 controls the overall operation in the vehicle control system 7000 according to various programs. The integration control unit 7600 is connected with an input unit 7800. The input unit 7800 is realized by, a device that can be operated and input by an occupant, such as a touch panel, a button, a microphone, a switch, or a lever, for example. Data obtained by recognizing sounds input by the microphone may be input to the integration control unit 7600. The input unit 7800 may be, for example, a remote control device using an infrared ray or another radio wave, or may be an externally connected device such as a mobile phone or a personal digital assistant (PDA) corresponding to the operation of the vehicle control system 7000. The input unit 7800 may be, for example, a camera, and in this case, the occupant can input information by gesture. Alternatively, data obtained by detecting movement of a wearable device worn by the occupant may be input. Moreover, the input unit 7800 may include, for example, an input control circuit that generates an input signal on the basis of the information input by the occupant or the like using the above input unit 7800 and outputs the input signal to the integration control unit 7600, and the like. The occupant or the like inputs various data to and instructs the vehicle control system 7000 on a processing operation by operating the input unit 7800.

The storage unit 7690 may include a read only memory (ROM) for storing various programs executed by the microcomputer, and a random access memory (RAM) for storing various parameters, calculation results, sensor values, or the like. Furthermore, the storage unit 7690 may be realized by a magnetic storage device such as a hard disc drive (HDD), a semiconductor storage device, an optical storage device, a magneto-optical storage device, or the like.

The general-purpose communication I/F 7620 is a general-purpose communication I/F that mediates communication with various devices existing in an external environment 7750. The general-purpose communication I/F 7620 may include a cellular communication protocol such as global system of mobile communications (GSM) (registered trademark), WiMAX (registered trademark), long term evolution (LTE) (registered trademark), or LTE-advanced (LTE-A), or a wireless communication protocol such as a wireless LAN (also referred to as Wi-Fi (registered trademark)) or Bluetooth (registered trademark). The general-purpose communication I/F 7620 may be connected to a device (for example, an application server or a control server) existing on an external network (for example, the Internet, a cloud network, or a company specific network) via a base station or an access point, for example. Furthermore, the general-purpose communication I/F 7620 may be connected with a terminal (for example, a terminal of a driver, a pedestrian, or a shop, or a machine type communication (MTC) terminal) existing in the vicinity of the vehicle, using a peer to peer (P2P) technology, for example.

The dedicated communication I/F 7630 is a communication I/F supporting a communication protocol formulated for use in the vehicle. For example, the dedicated communication I/F 7630 may include a standard protocol such as a wireless access in vehicle environment (WAVE), which is a combination of a lower layer IEEE 802.11p and an upper layer IEEE 1609, dedicated short range communications (DSRC), or a cellular communication protocol. The dedicated communication I/F 7630 typically performs V2X communication that is a concept including one or more of vehicle to vehicle communication, vehicle to infrastructure communication, vehicle to home communication, and vehicle to pedestrian communication.

The positioning unit 7640 receives a global navigation satellite system (GNSS) signal from a GNSS satellite (for example, a global positioning system (GPS) signal from a GPS satellite) to execute positioning, and generates position information including the latitude, longitude, and altitude of the vehicle, for example. Note that the positioning unit 7640 may specify a current position by exchanging signals with a wireless access point or may acquire the position information from a terminal such as a mobile phone, a PHS, or a smartphone having a positioning function.

The beacon reception unit 7650 receives, for example, a radio wave or an electromagnetic wave transmitted from a wireless station or the like installed on a road, and acquires information such as a current position, congestion, road closure, or required time. Note that the function of the beacon reception unit 7650 may be included in the above-described dedicated communication I/F 7630.

The in-vehicle device I/F 7660 is a communication interface that mediates connection between the microcomputer 7610 and various in-vehicle devices 7760 existing in the vehicle. The in-vehicle device I/F 7660 may establish wireless connection using a wireless communication protocol such as a wireless LAN, Bluetooth (registered trademark), near field communication (NFC), or wireless USB (WUSB). Furthermore, the in-vehicle device I/F 7660 may establish wired connection such as a universal serial bus (USB), a high-definition multimedia interface (HDMI) (registered trademark), mobile high-definition link (MHL), or the like via a connection terminal (not illustrated) (and a cable if necessary). The in-vehicle device 7760 may include, for example, at least one of a mobile device or a wearable device possessed by an occupant or an information device carried in or attached to the vehicle. Furthermore, the in-vehicle device 7760 may include a navigation device that performs a route search to an arbitrary destination. The in-vehicle device I/F 7660 exchanges control signals or data signals with these in-vehicle devices 7760.

The on-board network I/F 7680 is an interface that mediates communication between the microcomputer 7610 and the communication network 7010. The on-board network I/F 7680 transmits and receives signals and the like according to a predetermined protocol supported by the communication network 7010.

The microcomputer 7610 of the integration control unit 7600 controls the vehicle control system 7000 according to various programs on the basis of information acquired via at least one of the general-purpose communication I/F 7620, the dedicated communication I/F 7630, the positioning unit 7640, the beacon reception unit 7650, the in-vehicle device I/F 7660, or the on-board network I/F 7680. For example, the microcomputer 7610 may calculate a control target value of the drive force generation device, the steering mechanism, or the brake device on the basis of the acquired information of the interior and the exterior of the vehicle, and output a control command to the drive system control unit 7100. For example, the microcomputer 7610 may perform cooperative control for the purpose of realization of an advanced driver assistance system (ADAS) function including collision avoidance or shock mitigation of the vehicle, following travel based on an inter-vehicle distance, vehicle speed maintaining travel, collision warning of the vehicle, lane out warning of the vehicle, and the like. Furthermore, the microcomputer 7610 may control the drive force generation device, the steering mechanism, the braking device, or the like on the basis of the acquired information of a vicinity of the vehicle to perform cooperative control for the purpose of automatic driving of autonomous travel without depending on an operation of the driver or the like.

The microcomputer 7610 may create three-dimensional distance information between the vehicle and an object such as a peripheral structure or person and may create local map information including peripheral information of the current position of the vehicle on the basis of information acquired via at least one of the general-purpose communication I/F 7620, the dedicated communication I/F 7630, the positioning unit 7640, the beacon reception unit 7650, the in-vehicle device I/F 7660, or the on-board network I/F 7680. Furthermore, the microcomputer 7610 may predict danger such as a collision of the vehicle, approach of a pedestrian or the like, or entry into a closed road on the basis of the acquired information, and generate a warning signal. The warning signal may be, for example, a signal for generating a warning sound or for lighting a warning lamp.

The audio image output unit 7670 transmits an output signal of at least one of an audio or an image to an output device that can visually and aurally notify the occupant of the vehicle or outside the vehicle of information. In the example in FIG. 39, as the output device, an audio speaker 7710, a display unit 7720, and an instrument panel 7730 are exemplarily illustrated. The display unit 7720 may include, for example, at least one of an on-board display or a head-up display. The display unit 7720 may have an augmented reality (AR) display function. The output device may be a wearable device such as a headphone or a spectacular display worn by an occupant, a projector, a lamp, or the like other than the aforementioned devices. In the case where the output device is a display device, the display device visually displays a result obtained in various types of processing performed by the microcomputer 7610 or information received from another control unit, in various formats such as a text, an image, a table, and a graph. Furthermore, in the case where the output device is an audio output device, the audio output device converts an audio signal including reproduced audio data, acoustic data, or the like into an analog signal, and aurally outputs the analog signal.

Note that, in the example illustrated in FIG. 39, at least two control units connected via the communication network 7010 may be integrated as one control unit. Alternatively, an individual control unit may be configured by a plurality of control units. Moreover, the vehicle control system 7000 may include another control unit (not illustrated). Furthermore, in the above description, some or all of the functions carried out by any one of the control units may be performed by another control unit. That is, predetermined arithmetic processing may be performed by any of the control units as long as information is transmitted and received via the communication network 7010. Similarly, a sensor or a device connected to any of the control units may be connected to another control unit, and a plurality of control units may transmit and receive detection information to each other via the communication network 7010.

20. Applications to Operating Room System

The light source unit and the distance measuring device according to the present technology can be applied to various products related to the medical field. For example, the light source unit according to the present technology may be applied to a light source device used in an operating room system to be described below. For example, the distance measuring device according to the present technology may be applied to a device including the light source device, a lens unit, and an imaging unit used in an operating room system to be described below.

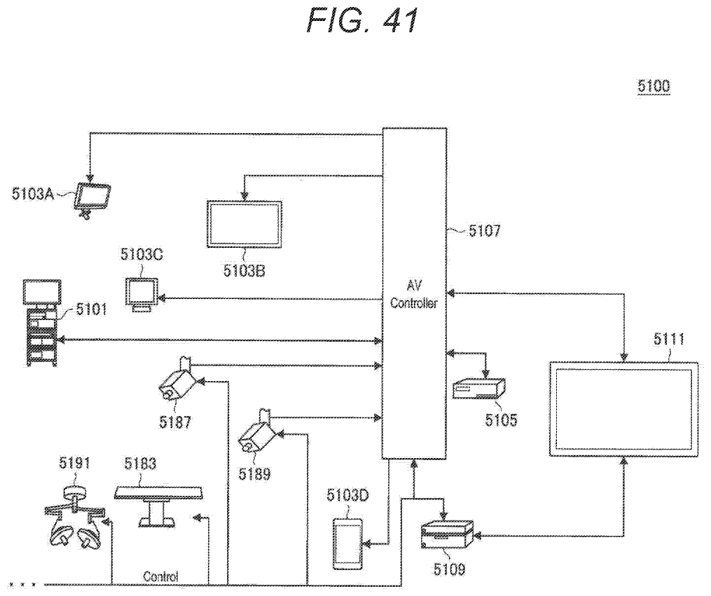

FIG. 41 is a diagram schematically illustrating an overall configuration of an operating room system 5100 to which the technology according to the present disclosure is applicable. Referring to FIG. 41, the operating room system 5100 is configured such that devices installed in an operating room are connected to be able to cooperate with each other via an audiovisual controller (AV controller) 5107 and an operating room control device 5109.

Various devices can be installed in the operating room. FIG. 41 illustrates, as an example, a group of various devices 5101 for endoscopic surgery, a ceiling camera 5187 provided on a ceiling of the operating room and imaging the hand of an operator, a surgical field camera 5189 provided on the ceiling of the operating room and imaging an entire state of the operating room, a plurality of display devices 5103A to 5103D, a recorder 5105, a patient bed 5183, and an illumination 5191.

Here, among these devices, the group of devices 5101 belongs to an endoscopic surgical system 5113 described below and includes an endoscope, a display device that displays an image imaged by the endoscope, and the like. Each device belonging to the endoscopic surgical system 5113 is also referred to as a medical device. Meanwhile, the display devices 5103A to 5103D, the recorder 5105, the patient bed 5183, and the illumination 5191 are devices provided in, for example, the operating room separately from the endoscopic surgical system 5113. Each device not belonging to the endoscopic surgical system 5113 is referred to as a non-medical device. The audiovisual controller 5107 and/or the operating room control device 5109 controls the medical devices and the non-medical devices in cooperation with each other.

The audiovisual controller 5107 centrally controls processing relating to image display in the medical devices and the non-medical devices. Specifically, among the devices included in the operating room system 5100, the group of devices 5101, the ceiling camera 5187, and the surgical field camera 5189 can be devices (hereinafter, also referred to as devices at the transmission source) having a function to transmit information to be displayed during a surgical operation (hereinafter the information is also referred to as display information). Furthermore, the display devices 5103A to 5103D can be devices (hereinafter, also referred to as devices at the output destination) to which the display information is output. Furthermore, the recorder 5105 can be a device corresponding to both the device at the transmission source and the device at the output destination. The audiovisual controller 5107 has functions to control the operation of the devices at the transmission source and the devices at the output destination, acquire the display information from the devices at the transmission source, transmit the display information to the devices at the output destination, and display or record the display information. Note that the display information is various images imaged during the surgical operation, various types of information regarding the surgical operation (for example, physical information of a patient, information of a past examination result, information of an operation method, and the like), and the like.

Specifically, information regarding an image of an operation site in a patient's body cavity imaged by the endoscope can be transmitted from the group of devices 5101 to the audiovisual controller 5107 as the display information. Furthermore, information regarding an image of the operator's hand imaged by the ceiling camera 5187 can be transmitted from the ceiling camera 5187 as the display information. Furthermore, information regarding an image illustrating the state of the entire operating room imaged by the surgical field camera 5189 can be transmitted from the surgical field camera 5189 as the display information. Note that, in a case where another device having an imaging function exists in the operating room system 5100, the audiovisual controller 5107 may acquire information regarding an image imaged by the another device from the another device as the display information.

Alternatively, for example, information regarding these images imaged in the past is recorded in the recorder 5105 by the audiovisual controller 5107. The audiovisual controller 5107 can acquire the information regarding the images imaged in the past from the recorder 5105 as the display information. Note that the recorder 5105 may also record various types of information regarding the surgical operation in advance.

The audiovisual controller 5107 causes at least any of the display devices 5103A to 5103D as the devices at the output destination to display the acquired display information (in other words, the image imaged during the surgical operation and the various types of information regarding the surgical operation). In the illustrated example, the display device 5103A is a display device suspended and installed from the ceiling of the operating room, the display device 5103B is a display device installed on a wall of the operating room, the display device 5103C is a display device installed on a desk in the operating room, and the display device 5103D is a mobile device (for example, a tablet personal computer (PC)) having a display function.

Furthermore, although illustration is omitted in FIG. 41, the operating room system 5100 may include a device outside the operating room. The device outside the operating room can be, for example, a server connected to a network built inside or outside a hospital, a PC used by a medical staff, a projector installed in a conference room of the hospital, or the like. In a case where such an external device is outside the hospital, the audiovisual controller 5107 can also cause a display device of another hospital to display the display information via a video conference system or the like for telemedicine.

The operating room control device 5109 centrally controls processing other than the processing regarding the image display in the non-medical devices. For example, the operating room control device 5109 controls the driving of the patient bed 5183, the ceiling camera 5187, the surgical field camera 5189, and the illumination 5191.

The operating room system 5100 is provided with a centralized operation panel 5111, and the user can give an instruction regarding the image display to the audiovisual controller 5107 and can give an instruction regarding the operation of the non-medical devices to the operating room control device 5109, through the centralized operation panel 5111. The centralized operation panel 5111 is provided with a touch panel on a display surface of the display device.

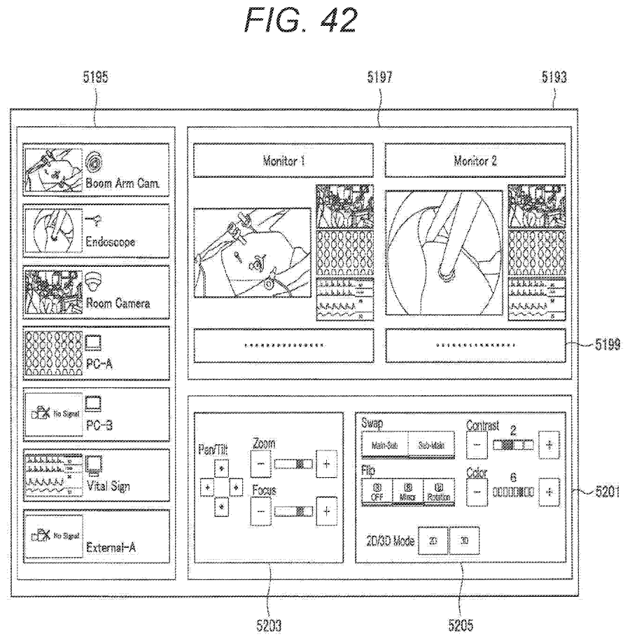

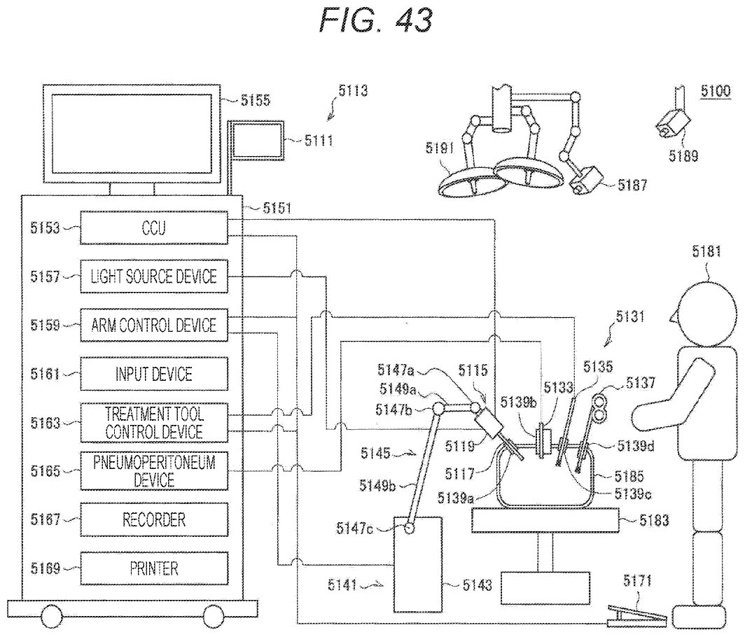

FIG. 42 is a diagram illustrating a display example of an operation screen on the centralized operation panel 5111. FIG. 42 illustrates, as an example, an operation screen corresponding to a case where two display devices are provided in the operating room system 5100 as the devices at the output destination. Referring to FIG. 42, an operation screen 5193 is provided with a transmission source selection area 5195, a preview area 5197, and a control area 5201.

The transmission source selection area 5195 displays a transmission source device provided in the operating room system 5100 and a thumbnail screen representing the display information held by the transmission source device in association with each other. The user can select the display information to be displayed on the display device from any of the transmission source devices displayed in the transmission source selection area 5195.

The preview area 5197 displays a preview of screens displayed on two display devices (Monitor 1 and Monitor 2) that are the devices at the output destination. In the illustrated example, four images are displayed in PinP on one display device. The four images correspond to the display information transmitted from the transmission source device selected in the transmission source selection area 5195. One of the four images is displayed relatively large as a main image, and the remaining three images are displayed relatively small as sub-images. The user can switch the main image and a sub-image by appropriately selecting areas where the four images are displayed. Furthermore, a status display area 5199 is provided below the areas where the four images are displayed, and the status regarding the surgical operation (for example, an elapsed time of the surgical operation, the patient's physical information, and the like) is appropriately displayed in the area.

The control area 5201 is provided with a transmission source operation area 5203 in which a graphical user interface (GUI) component for operating the device at the transmission source is displayed, and an output destination operation area 5205 in which a GUI component for operating the device at the output destination is displayed. In the illustrated example, the transmission source operation area 5203 is provided with GUI components for performing various operations (pan, tilt, and zoom) of the camera in the device at the transmission source having an imaging function. The user can operate the operation of the camera in the device at the transmission source by appropriately selecting these GUI components. Note that, although illustration is omitted, in a case where the device at the transmission source selected in the transmission source selection area 5195 is a recorder (in other words, in a case where the image recorded in the past in the recorder is displayed in the preview area 5197), the transmission source operation area 5203 can be provided with GUI components for performing operations such as reproduction, stop of reproduction, rewind, and fast forward, of the image.

Furthermore, the output destination operation area 5205 is provided with GUI components for performing various operations (swap, flip, color adjustment, contrast adjustment, and switching between 2D display and 3D display) for the display in the display device that is the device at the output destination. The user can operate the display in the display device by appropriately selecting these GUI components.

Note that the operation screen displayed on the centralized operation panel 5111 is not limited to the illustrated example, and the user may be able to perform operation input to devices that can be controlled by the audiovisual controller 5107 and the operating room control device 5109 provided in the operating room system 5100, via the centralized operation panel 5111.

FIG. 43 is a diagram illustrating an example of a state of a surgical operation to which the above-described operating room system is applied. The ceiling camera 5187 and the surgical field camera 5189 are provided on the ceiling of the operating room and can image the hand of an operator (surgeon) 5181 who performs treatment for an affected part of a patient 5185 on the patient bed 5183 and the state of the entire operating room. The ceiling camera 5187 and the surgical field camera 5189 can be provided with a magnification adjustment function, a focal length adjustment function, an imaging direction adjustment function, and the like. The illumination 5191 is provided on the ceiling of the operating room and illuminates at least the hand of the operator 5181. The illumination 5191 may be able to appropriately adjust an irradiation light amount, a wavelength (color) of irradiation light, an irradiation direction of the light, and the like.

The endoscopic surgical system 5113, the patient bed 5183, the ceiling camera 5187, the surgical field camera 5189, and the illumination 5191 are connected in cooperation with each other via the audiovisual controller 5107 and the operating room control device 5109 (not illustrated in FIG. 43), as illustrated in FIG. 41. The centralized operation panel 5111 is provided in the operating room, and as described above, the user can appropriately operate these devices present in the operating room via the centralized operation panel 5111.

Hereinafter, a configuration of the endoscopic surgical system 5113 will be described in detail. As illustrated, the endoscopic surgical system 5113 includes an endoscope 5115, other surgical tools 5131, a support arm device 5141 that supports the endoscope 5115, and a cart 5151 in which various devices for endoscopic surgery are mounted.

In endoscopic surgery, a plurality of cylindrical puncture devices called trocars 5139a to 5139d is punctured into an abdominal wall instead of cutting the abdominal wall to open the abdomen. Then, a lens barrel 5117 of the endoscope 5115 and other surgical tools 5131 are inserted into a body cavity of the patient 5185 through the trocars 5139a to 5139d. In the illustrated example, as the other surgical tools 5131, a pneumoperitoneum tube 5133, an energy treatment tool 5135, and a pair of forceps 5137 are inserted into the body cavity of the patient 5185. Furthermore, the energy treatment tool 5135 is a treatment tool for performing incision and detachment of tissue, sealing of a blood vessel, and the like with a high-frequency current or an ultrasonic vibration. Note that the illustrated surgical tools 5131 are mere examples, and various kinds of surgical tools typically used in the endoscopic surgery such as tweezers, a retractor, and the like may be used as the surgical tools 5131.

An image of an operation site in the body cavity of the patient 5185 imaged by the endoscope 5115 is displayed on a display device 5155. The operator 5181 performs treatment such as removal of an affected part, using the energy treatment tool 5135 and the forceps 5137 while viewing the image of the operation site displayed on the display device 5155 in real time. Note that, although illustration is omitted, the pneumoperitoneum tube 5133, the energy treatment tool 5135, and the forceps 5137 are supported by the operator 5181, an assistant, or the like during the surgical operation.

(Support Arm Device)

The support arm device 5141 includes an arm unit 5145 extending from a base unit 5143. In the illustrated example, the arm unit 5145 includes joint portions 5147a, 5147b, and 5147c, and links 5149a and 5149b, and is driven under the control of an arm control device 5159. The endoscope 5115 is supported by the arm unit 5145, and the position and posture of the endoscope 5115 are controlled. With the control, stable fixation of the position of the endoscope 5115 can be realized.

(Endoscope)

The endoscope 5115 includes the lens barrel 5117 having a region with a predetermined length from a distal end inserted into the body cavity of the patient 5185, and a camera head 5119 connected to a proximal end of the lens barrel 5117. In the illustrated example, the endoscope 5115 configured as a so-called hard endoscope including the hard lens barrel 5117 is illustrated. However, the endoscope 5115 may be configured as a so-called soft endoscope including the soft lens barrel 5117.

The distal end of the lens barrel 5117 is provided with an opening in which an object lens is fit. A light source device 5157 is connected to the endoscope 5115, and light generated by the light source device 5157 is guided to the distal end of the lens barrel 5117 by a light guide extending inside the lens barrel 5117 and an object to be observed in the body cavity of the patient 5185 is irradiated with the light through the object lens. Note that the endoscope 5115 may be a forward-viewing endoscope, may be an oblique-viewing endoscope, or may be a side-viewing endoscope.

An optical system and an imaging element are provided inside the camera head 5119, and reflected light (observation light) from the object to be observed is condensed to the imaging element by the optical system. The observation light is photoelectrically converted by the imaging element, and an electrical signal corresponding to the observation light, that is, an image signal corresponding to an observed image is generated. The image signal is transmitted to a camera control unit (CCU) 5153 as raw data. Note that the camera head 5119 has a function to adjust magnification and a focal length by appropriately driving the optical system.

Note that, for example, to cope with stereoscopic view (3D display) or the like, a plurality of imaging elements may be provided in the camera head 5119. In this case, a plurality of relay optical systems is provided inside the lens barrel 5117 to guide the observation light to each of the plurality of imaging elements.

(Various Devices Mounted in Cart)

The CCU 5153 includes a central processing unit (CPU), a graphics processing unit (GPU), and the like, and centrally controls the operations of the endoscope 5115 and the display device 5155. Specifically, the CCU 5153 applies various types of image processing for displaying an image based on the image signal, such as developing processing (demosaic processing), to the image signal received from the camera head 5119. The CCU 5153 provides the image signal to which the image processing has been applied to the display device 5155. Furthermore, the audiovisual controller 5107 illustrated in FIG. 41 is connected to the CCU 5153. The CCU 5153 also supplies the image signal to which the image processing has been applied to the audiovisual controller 5107. Furthermore, the CCU 5153 transmits a control signal to the camera head 5119 to control its driving. The control signal may include information regarding imaging conditions such as the magnification and focal length. The information regarding imaging conditions may be input via an input device 5161 or may be input via the above-described centralized operation panel 5111.

The display device 5155 displays the image based on the image signal to which the image processing has been applied by the CCU 5153 under the control of the CCU 5153. In a case where the endoscope 5115 supports high-resolution imaging such as 4K (horizontal pixel number 3840×vertical pixel number 2160) or 8K (horizontal pixel number 7680×vertical pixel number 4320), and/or in a case where the endoscope 5115 supports 3D display, for example, the display device 5155, which can perform high-resolution display and/or 3D display, can be used corresponding to each case. In the case where the endoscope 5115 supports the high-resolution imaging such as 4K or 8K, a greater sense of immersion can be obtained by use of the display device 5155 with the size of 55 inches or more. Furthermore, a plurality of display devices 5155 having different resolutions and sizes may be provided depending on the use.

The light source device 5157 includes a light source such as a light emitting diode (LED), for example, and supplies irradiation light to the endoscope 5115 in imaging an operation site.

The arm control device 5159 includes a processor such as a CPU, and operates according to a predetermined program, thereby controlling driving of the arm unit 5145 of the support arm device 5141 according to a predetermined control method.

The input device 5161 is an input interface for the endoscopic surgical system 5113. The user can input various types of information and instructions to the endoscopic surgical system 5113 via the input device 5161. For example, the user inputs various types of information regarding the surgical operation, such as the patient's physical information and the information regarding an operation method of the surgical operation via the input device 5161. Furthermore, for example, the user inputs an instruction to drive the arm unit 5145, an instruction to change the imaging conditions (such as the type of the irradiation light, the magnification, and the focal length) of the endoscope 5115, an instruction to drive the energy treatment tool 5135, or the like via the input device 5161.

The type of the input device 5161 is not limited, and the input device 5161 may be one of various known input devices. For example, a mouse, a keyboard, a touch panel, a switch, a foot switch 5171, a lever, and/or the like can be applied to the input device 5161. In the case where a touch panel is used as the input device 5161, the touch panel may be provided on a display surface of the display device 5155.

Alternatively, the input device 5161 is, for example, a device worn by the user, such as a glass-type wearable device or a head mounted display (HMD), and various inputs are performed according to a gesture or a line-of-sight of the user detected by the device. Furthermore, the input device 5161 includes a camera capable of detecting a movement of the user, and various inputs are performed according to a gesture or a line-of-sight of the user detected from an image imaged by the camera. Moreover, the input device 5161 includes a microphone capable of collecting a voice of the user, and various inputs are performed by a sound through the microphone. The input device 5161 is configured to be able to input various types of information in a non-contact manner, as described above, so that the user (for example, the operator 5181) in particular belonging to a clean area can operate a device belonging to a filthy area in a non-contact manner. Furthermore, since the user can operate the device without releasing his/her hand from the possessed surgical tool, the user's convenience is improved.

A treatment tool control device 5163 controls driving of the energy treatment tool 5135 for cauterization and incision of tissue, sealing of a blood vessel, and the like. A pneumoperitoneum device 5165 sends a gas into the body cavity of the patient 5185 through the pneumoperitoneum tube 5133 to expand the body cavity for the purpose of securing a field of vision by the endoscope 5115 and a work space for the operator. A recorder 5167 is a device that can record various types of information regarding the surgical operation. A printer 5169 is a device that can print the various types of information regarding the surgery in various formats such as a text, an image, or a graph.

Hereinafter, a particularly characteristic configuration in the endoscopic surgical system 5113 will be further described in detail.

(Support Arm Device)

The support arm device 5141 includes the base unit 5143 as a base and the arm unit 5145 extending from the base unit 5143. In the illustrated example, the arm unit 5145 includes the plurality of joint portions 5147a, 5147b, and 5147c, and the plurality of links 5149a and 5149b connected by the joint portion 5147b. However, FIG. 43 illustrates a simplified configuration of the arm unit 5145 for simplification. In reality, the shapes, the number, and the arrangement of the joint portions 5147a to 5147c and the links 5149a and 5149b, directions of rotation axes of the joint portions 5147a to 5147c, and the like can be appropriately set so that the arm unit 5145 has a desired degree of freedom. For example, the arm unit 5145 can favorably have six degrees of freedom or more. With the configuration, the endoscope 5115 can be freely moved within a movable range of the arm unit 5145. Therefore, the lens barrel 5117 of the endoscope 5115 can be inserted from a desired direction into the body cavity of the patient 5185.

Actuators are provided in the joint portions 5147a to 5147c, and the joint portions 5147a to 5147c are configured to be rotatable around predetermined rotation axes by driving of the actuators. The driving of the actuators is controlled by the arm control device 5159, so that rotation angles of the joint portions 5147a to 5147c are controlled and driving of the arm unit 5145 is controlled. With the control, control of the position and posture of the endoscope 5115 can be realized. At this time, the arm control device 5159 can control the driving of the arm unit 5145 by various known control methods such as force control or position control.

For example, by the operator 5181 appropriately performing an operation input via the input device 5161 (including a foot switch 5171), the driving of the arm unit 5145 may be appropriately controlled by the arm control device 5159 according to the operation input, and the position and posture of the endoscope 5115 may be controlled. With the control, the endoscope 5115 at the distal end of the arm unit 5145 can be moved from an arbitrary position to an arbitrary position, and then can be fixedly supported at the position after the movement. Note that the arm unit 5145 may be operated by a so-called master-slave system. In this case, the arm unit 5145 can be remotely operated by the user via the input device 5161 installed at a place distant from the operating room.

Furthermore, in a case where the force control is applied, the arm control device 5159 receives external force from the user, and may perform so-called power assist control to drive the actuators of the joint portions 5147a to 5147c so that the arm unit 5145 can smoothly move according to the external force. With the control, the user can move the arm unit 5145 with relatively light force when moving the arm unit 5145 while being in direct contact with the arm unit 5145. Accordingly, the user can more intuitively move the endoscope 5115 with a simpler operation, and the user's convenience can be improved.

Here, in the endoscopic surgery, the endoscope 5115 has been generally supported by a doctor called scopist. In contrast, by use of the support arm device 5141, the position of the endoscope 5115 can be reliably fixed without manual operation, and thus an image of the operation site can be stably obtained and the surgical operation can be smoothly performed.

Note that the arm control device 5159 is not necessarily provided in the cart 5151. Furthermore, the arm control device 5159 is not necessarily one device. For example, the arm control device 5159 may be provided in each of the joint portions 5147a to 5147c of the arm unit 5145 of the support arm device 5141, and the drive control of the arm unit 5145 may be realized by mutual cooperation of the plurality of arm control devices 5159.

(Light Source Device)

The light source device 5157 supplies irradiation light, which is used in imaging the operation site, to the endoscope 5115. The light source device 5157 includes, for example, an LED, a laser light source, or a white light source configured by a combination of the laser light sources. In a case where the white light source is configured by a combination of RGB laser light sources, output intensity and output timing of the respective colors (wavelengths) can be controlled with high accuracy. Therefore, white balance of a captured image can be adjusted in the light source device 5157. Furthermore, in this case, the object to be observed is irradiated with the laser light from each of the RGB laser light sources in a time division manner, and the driving of the imaging element of the camera head 5119 is controlled in synchronization with the irradiation timing, so that images each corresponding to RGB can be imaged in a time division manner. According to the method, a color image can be obtained without providing a color filter to the imaging element.

Further, driving of the light source device 5157 may be controlled to change intensity of light to be output every predetermined time. The driving of the imaging element of the camera head 5119 is controlled in synchronization with change timing of the intensity of light, and images are acquired in a time division manner and are synthesized, so that a high-dynamic range image without clipped blacks and flared highlights can be generated.

Furthermore, the light source device 5157 may be configured to be able to supply light in a predetermined wavelength band corresponding to special light observation. In the special light observation, for example, so-called narrow band imaging is performed by radiating light in a narrower band than the irradiation light (that is, white light) at the time of normal observation, using wavelength dependence of absorption of light in a body tissue, to image a predetermined tissue such as a blood vessel in a mucosal surface layer at high contrast. Alternatively, in the special light observation, fluorescence observation to obtain an image by fluorescence generated by radiation of exciting light may be performed.

In the fluorescence observation, irradiating the body tissue with exciting light to observe fluorescence from the body tissue (self-fluorescence observation), injecting a reagent such as indocyanine green (ICG) into the body tissue and irradiating the body tissue with exciting light corresponding to a fluorescence wavelength of the reagent to obtain a fluorescence image, or the like can be performed. The light source device 5157 may be configured to be able to supply narrow-band light and/or exciting light corresponding to such special light observation.

(Camera Head and CCU)

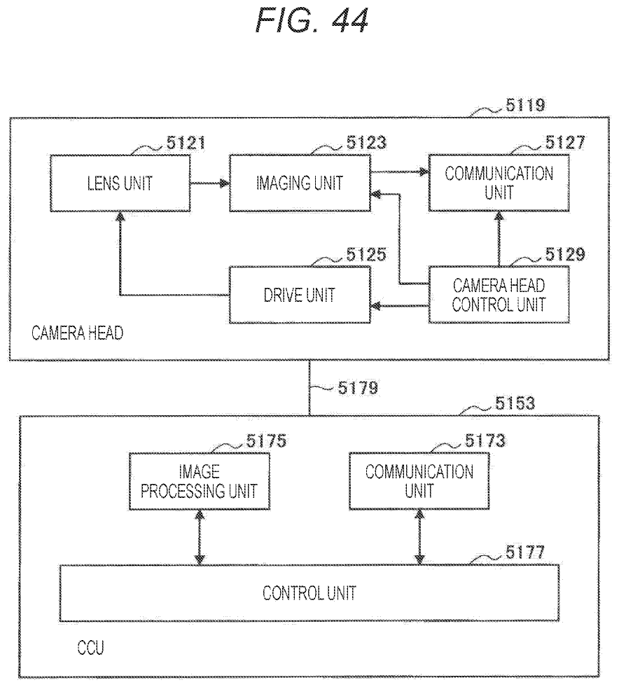

Functions of the camera head 5119 and the CCU 5153 of the endoscope 5115 will be described in more detail with reference to FIG. 44. FIG. 44 is a block diagram illustrating an example of functional configurations of the camera head 5119 and the CCU 5153 illustrated in FIG. 43.

Referring to FIG. 44, the camera head 5119 has a lens unit 5121, an imaging unit 5123, a drive unit 5125, a communication unit 5127, and a camera head control unit 5129 as its functions. Furthermore, the CCU 5153 includes a communication unit 5173, an image processing unit 5175, and a control unit 5177 as its functions. The camera head 5119 and the CCU 5153 are communicatively connected with each other by a transmission cable 5179.

First, a functional configuration of the camera head 5119 will be described. The lens unit 5121 is an optical system provided in a connection portion between the lens unit 5121 and the lens barrel 5117. Observation light taken through the distal end of the lens barrel 5117 is guided to the camera head 5119 and enters the lens unit 5121. The lens unit 5121 is configured by a combination of a plurality of lenses including a zoom lens and a focus lens. Optical characteristics of the lens unit 5121 are adjusted to condense the observation light on a light receiving surface of the imaging element of the imaging unit 5123. Furthermore, the zoom lens and the focus lens have their positions on the optical axis movable for adjustment of the magnification and focal point of the captured image.

The imaging unit 5123 includes the imaging element, and is disposed at a rear stage of the lens unit 5121. The observation light having passed through the lens unit 5121 is focused on the light receiving surface of the imaging element, and an image signal corresponding to the observed image is generated by photoelectric conversion. The image signal generated by the imaging unit 5123 is provided to the communication unit 5127.

As the imaging element configuring the imaging unit 5123, for example, a complementary metal oxide semiconductor (CMOS)-type image sensor having Bayer arrangement and capable of color imaging is used. Note that, as the imaging element, for example, an imaging element that can image a high-resolution image of 4K or more may be used. By obtainment of the image of the operation site with high resolution, the operator 5181 can grasp the state of the operation site in more detail and can more smoothly advance the surgical operation.

Furthermore, the imaging element configuring the imaging unit 5123 includes a pair of imaging elements for respectively obtaining image signals for right eye and for left eye corresponding to 3D display. With the 3D display, the operator 5181 can more accurately grasp the depth of biological tissue in the operation site. Note that, in a case where the imaging unit 5123 is configured by multiple imaging elements, a plurality of systems of the lens units 5121 may be provided corresponding to the imaging elements.

Furthermore, the imaging unit 5123 is not necessarily provided in the camera head 5119. For example, the imaging unit 5123 may be provided immediately after the object lens inside the lens barrel 5117.

The drive unit 5125 includes an actuator, and moves the zoom lens and the focus lens of the lens unit 5121 by a predetermined distance along the optical axis under the control of the camera head control unit 5129. With the movement, the magnification and focal point of the captured image by the imaging unit 5123 can be appropriately adjusted.

The communication unit 5127 includes a communication device for transmitting or receiving various types of information to or from the CCU 5153. The communication unit 5127 transmits the image signal obtained from the imaging unit 5123 to the CCU 5153 through the transmission cable 5179 as raw data. At this time, to display the captured image of the operation site with low latency, the image signal is favorably transmitted by optical communication. This is because, in the surgical operation, the operator 5181 performs the surgical operation while observing a state of an affected part with the captured image, and thus display of a moving image of the operation site in as real time as possible is demanded for a safer and more reliable surgical operation. In the case of the optical communication, the communication unit 5127 is provided with a photoelectric conversion module that converts an electrical signal into an optical signal. The image signal is converted into the optical signal by the photoelectric conversion module and is then transmitted to the CCU 5153 via the transmission cable 5179.

Furthermore, the communication unit 5127 receives a control signal for controlling driving of the camera head 5119 from the CCU 5153. The control signal includes information regarding the imaging conditions such as information for specifying a frame rate of the captured image, information for specifying an exposure value at the time of imaging, and/or information for specifying the magnification and the focal point of the captured image, for example. The communication unit 5127 provides the received control signal to the camera head control unit 5129. Note that the control signal from the CCU 5153 may also be transmitted by the optical communication. In this case, the communication unit 5127 is provided with a photoelectric conversion module that converts an optical signal into an electrical signal, and the control signal is converted into an electrical signal by the photoelectric conversion module and is then provided to the camera head control unit 5129.

Note that the imaging conditions such as the frame rate, exposure value, magnification, and focal point are automatically set by the control unit 5177 of the CCU 5153 on the basis of the acquired image signal. That is, so-called an auto exposure (AE) function, an auto focus (AF) function, and an auto white balance (AWB) function are incorporated in the endoscope 5115.

The camera head control unit 5129 controls the driving of the camera head 5119 on the basis of the control signal received from the CCU 5153 via the communication unit 5127. For example, the camera head control unit 5129 controls driving of the imaging element of the imaging unit 5123 on the basis of the information for specifying the frame rate of the captured image and/or the information for specifying exposure at the time of imaging. Furthermore, for example, the camera head control unit 5129 appropriately moves the zoom lens and the focus lens of the lens unit 5121 via the drive unit 5125 on the basis of the information for specifying the magnification and focal point of the captured image. The camera head control unit 5129 may further have a function to store information for identifying the lens barrel 5117 and the camera head 5119.

Note that the configuration of the lens unit 5121, the imaging unit 5123, and the like is arranged in a hermetically sealed structure having high airtightness and waterproofness, so that the camera head 5119 can have resistance to autoclave sterilization processing.

Next, a functional configuration of the CCU 5153 will be described. The communication unit 5173 includes a communication device for transmitting or receiving various types of information to or from the camera head 5119. The communication unit 5173 receives the image signal transmitted from the camera head 5119 through the transmission cable 5179. At this time, as described above, the image signal can be favorably transmitted by the optical communication. In this case, the communication unit 5173 is provided with a photoelectric conversion module that converts an optical signal into an electrical signal, corresponding to the optical communication. The communication unit 5173 provides the image signal converted into the electrical signal to the image processing unit 5175.

Furthermore, the communication unit 5173 transmits the control signal for controlling driving of the camera head 5119 to the camera head 5119. The control signal may also be transmitted by the optical communication.

The image processing unit 5175 applies various types of image processing to the image signal as raw data transmitted from the camera head 5119. The image processing includes, for example, various types of known signal processing such as development processing, high image quality processing (such as band enhancement processing, super resolution processing, noise reduction (NR) processing, and/or camera shake correction processing), and/or enlargement processing (electronic zoom processing). Furthermore, the image processing unit 5175 performs wave detection processing for the image signal, for performing AE, AF, and AWB.

The image processing unit 5175 includes a processor such as a CPU or a GPU, and the processor operates according to a predetermined program, thereby performing the above-described image processing and wave detection processing. Note that in a case where the image processing unit 5175 includes a plurality of GPUs, the image processing unit 5175 appropriately divides the information regarding the image signal and performs the image processing in parallel by the plurality of GPUs.

The control unit 5177 performs various types of control related to imaging of the operation site by the endoscope 5115 and display of the captured image. For example, the control unit 5177 generates the control signal for controlling driving of the camera head 5119. At this time, in a case where the imaging conditions are input by the user, the control unit 5177 generates the control signal on the basis of the input by the user. Alternatively, in a case where the AE function, the AF function, and the AWB function are incorporated in the endoscope 5115, the control unit 5177 appropriately calculates optimum exposure value, focal length, and white balance according to a result of the wave detection processing by the image processing unit 5175, and generates the control signal.

Furthermore, the control unit 5177 displays the image of the operation portion or the like in the display device 5155 on the basis of the image signal to which the image processing has been applied by the image processing unit 5175. At this time, the control unit 5177 recognizes various objects in the image of the operation site, using various image recognition technologies. For example, the control unit 5177 can recognize a surgical instrument such as forceps, a specific living body portion, blood, mist at the time of use of the energy treatment tool 5135, or the like, by detecting a shape of an edge, a color, or the like of an object included in the captured image. The control unit 5177 superimposes and displays various types of surgery support information on the image of the operation site, in displaying the image of the operation site on the display device 5155, using the result of recognition. The surgery support information is superimposed, displayed, and presented to the operator 5181, so that the surgical operation can be more safely and reliably advanced.

The transmission cable 5179 that connects the camera head 5119 and the CCU 5153 is an electrical signal cable supporting communication of electrical signals, an optical fiber supporting optical communication, or a composite cable thereof.

Here, in the illustrated example, the communication has been performed in a wired manner using the transmission cable 5179. However, the communication between the camera head 5119 and the CCU 5153 may be wirelessly performed. In a case where the communication between the camera head 5119 and the CCU 5153 is wirelessly performed, it is not necessary to lay the transmission cable 5179 in the operating room. Therefore, the situation in which movement of medical staffs in the operating room is hindered by the transmission cable 5179 can be eliminated.

An example of the operating room system 5100 to which the technology according to the present disclosure is applicable has been described. Note that, here, a case in which the medical system to which the operating room system 5100 is applied is the endoscopic surgical system 5113 has been described as an example. However, the configuration of the operating room system 5100 is not limited to the example. For example, the operating room system 5100 may be applied to a flexible endoscopic system for examination or a microsurgery system, instead of the endoscopic surgical system 5113.

21. Applications to Image Display Device

Furthermore, the light source unit and the light source device of the present technology can be applied to an image display device such as a projector, a head-up display, and a head-mounted display. For example, in the case of using the light source unit of the present technology for a projector, an image may be displayed by emitting light modulated according to image information from the light source of the light source unit, reflecting and diffusing the light by the diffuse reflection surface, and irradiating a screen with the diffused reflected light. For example, in the case of using the light source unit of the present technology for a head-up display or a head-mounted display, a virtual image may be displayed by emitting light modulated according to image information from the light source of the light source unit, reflecting and diffusing the light by the diffuse reflection surface, and irradiating a member (for example, a windshield or a combiner) having a transmissive reflection property provided in a moving body with the diffused reflected light.

Furthermore, the present technology can have the following configurations.

(1) A light source unit including:

a light source; and

a holder configured to hold the light source, in which

the holder has a diffuse reflection surface that reflects and diffuses at least part of light from the light source toward an object.

(2) The light source unit according to (1), in which

the holder has a recess in which the light source is housed, and

the diffuse reflection surface is located in the recess, and reflects and diffuses the at least part of light from the light source toward an opening of the recess.

(3) The light source unit according to (2), in which the holder has a window that covers the opening of the recess.

(4) The light source unit according to any one of (1) to (3), in which the diffuse reflection surface is inclined with respect to an emission direction of the light source.

(5) The light source unit according to (4), in which an inclination angle of the diffuse reflection surface with respect to the emission direction of the light source is 30° to 60°.

(6) The light source unit according to any one of (1) to (5), in which an emission surface of the light source and the diffuse reflection surface face each other.

(7) The light source unit according to any one of (1) to (6), in which the light emitted from the light source directly enters the diffuse reflection surface.

(8) The light source unit according to any one of (1) to (7), in which the at least part is equal to or larger than 60% of the light from the light source.

(9) The light source unit according to (2) or (3), in which

the light source is provided on a bottom surface of the recess, and

an angle made by an emission direction of the light source with respect to the bottom surface is 0° to 45°.

(10) The light source unit according to any one of (2), (3), and (9), in which the diffuse reflection surface is located between the light source and a part of a peripheral wall of the recess.

(11) The light source unit according to any one of (2), (3), (9), and (10), in which the peripheral wall of the recess has a light-shielding property.

(12) The light source unit according to any one of (2), (3), and (9) to (11), in which at least a part of an inner peripheral surface of the peripheral wall of the recess has a light attenuation function.

(13) The light source unit according to any one of (2), (3), and (9) to (12), in which the diffuse reflection surface is provided on the peripheral wall of the recess.

(14) The light source unit according to any one of (3) and (9) to (12), in which the diffuse reflection surface is provided on the window.

(15) The light source unit according to any one of (2), (3), and (9) to (12), in which the diffuse reflection surface is provided on a bottom surface of the recess.

(16) The light source unit according to any one of (1) to (15), in which

the holder includes a diffuse reflection portion having the diffuse reflection surface, and

at least one surface of the diffuse reflection portion other than the diffuse reflection surface has a light attenuation function.

(17) The light source unit according to (12) or (16), in which the light attenuation function is implemented by any one of fine unevenness processing, an antireflection film, and black coating.

(18) The light source unit according to any one of (1) to (17), in which the holder includes a diffuse reflection portion having the diffuse reflection surface, and

the light source unit further includes a light receiving element that receives at least part of light emitted from the light source and through the diffuse reflection portion.

(19) The light source unit according to (18), in which the light receiving element receives light emitted from the light source and transmitted through the diffuse reflection surface.

(20) The light source unit according to (19), in which the light receiving element receives light reflected and diffused by the diffuse reflection surface and reflected by the window.

(21) The light source unit according to (19), in which the light receiving element receives light emitted from the light source and reflected by a surface adjacent to the diffuse reflection surface of the diffuse reflection portion.

(22) The light source unit according to any one of (1) to (21), in which the light source is a laser light source.

(23) A distance measuring device including:

the light source unit according to any one of (1) to (22);

a light receiving unit configured to receive light emitted from the light source unit and reflected by an object; and

a control unit configured to calculate a distance to the object on the basis of at least an output of the light receiving unit.

(24) The distance measuring device according to (23), in which the light source unit, the light receiving unit, and the control unit are integrally provided.

(25) The distance measuring device according to (23) or (24), in which the light receiving unit includes a sensor having a first light receiving region that receives light emitted from the light source unit and reflected by an object and a second light receiving region that receives light emitted from the light source and through the diffuse reflection surface.

(26) An image display device including: the light source unit according to any one of (1) to (25), in which the light source emits light modulated according to image information.

(27) An object system including:

the distance measuring device according to any one of (23) to (25); and

an object on which the distance measuring device is mounted.

(28) The object system according to (27), in which the object is a moving body.

(29) A light source device including:

a light source; and

a reflection member configured to reflect at least part of light from the light source to generate reflected light, in which

the reflection member includes a plurality of curved mirrors regularly arranged along a reference plane that the light from the light source enters, and

each of the plurality of curved mirrors has curvatures in a first axis direction and a second axis direction orthogonal to each other in the reference plane.

(30) The light source device according to (29), in which the plurality of concave mirrors is regularly arranged according to a target shape of a cross section perpendicular to an optical axis of the reflected light.

(31) The light source device according to (29) or (30), in which each of the plurality of curved mirrors is inclined with respect to the reference plane, and a shape viewed from a third axis direction orthogonal to the first axis direction is a shape according to the target shape of a cross section perpendicular to an optical axis of the reflected light.

(32) The light source device according to (31), in which the third axis direction approximately coincides with an optical axis direction of the light from the light source.

(33) The light source device according to (31) or (32), in which, in each of the plurality of curved mirrors, a length in the first axis direction of the shape viewed from the third axis direction, a length in a fourth axis direction orthogonal to both the first axis direction and the third axis direction in the shape viewed from the third axis direction, a curvature in the first axis direction, and a curvature in the second axis direction are set according to a ratio of a length in a direction corresponding to the first axis direction and a length in a direction corresponding to the fourth axis direction in the target shape.

(34) The light source device according to any one of (31) to (33), in which, in each of the plurality of curved mirrors, a ratio of a length in a fourth axis direction orthogonal to both the first axis direction and the third axis direction to a length in the first axis direction in the shape viewed from the third axis direction is equal to a ratio of a length in a direction corresponding to the fourth axis direction to a length in a direction corresponding to the first axis direction in the target shape, the curvature in the first axis direction and the curvature in the second axis direction are equal to each other.

(35) The light source device according to any one of (31) to (34), in which the plurality of curved mirrors is at least three curved mirrors and is two-dimensionally arranged as viewed from the third axis direction.

(36) The light source device according to (35), in which the plurality of curved mirrors is at least four curved mirrors and is arranged in a two-dimensional grid manner in the first axis direction and in a fourth axis direction orthogonal to both the first axis direction and the third axis direction as viewed from the third axis direction.

(37) The light source device according to (36), in which the plurality of curved mirrors includes the curved mirrors having curvatures with opposite positive and negative properties in the first axis direction and the second axis direction.

(38) The light source device according to (37), in which

the positive and negative properties of the curvatures in the first axis direction of at least the two curved mirrors arranged in the fourth axis direction as viewed from the third axis direction are equal to each other, and

the positive and negative properties of the curvatures in the second axis direction of at least the two curved mirrors arranged in the first axis direction as viewed from the third axis direction are equal to each other.

(39) The light source device according to any one of (31) to (38), in which

at least one of the plurality of curved mirrors has a convex curve shape in a cut end cut in a plane orthogonal to a fourth axis direction orthogonal to both the first axis direction and the third axis direction, and

0°<α≤60° is satisfied where an angle formed by a tangent line at each end of a convex curve drawn by the cut end and a line segment connecting both ends of the convex curve is α/2.

(40) The light source device according to any one of (31) to (39), in which

at least one of the plurality of curved mirrors has a convex curve shape in a cut end cut in a plane orthogonal to the first axis direction, and 0°<β≤60°−(⅔)φ is satisfied where an angle formed by a tangent line at each end of a convex curve drawn by the cut end and a line segment connecting both ends of the convex curve is β/2, and an angle formed by a fourth axis direction orthogonal to both the first axis direction and the third axis direction as viewed from the first axis direction with respect to the reference plane is 90°−φ.

(41) The light source device according to any one of (31) to (38) and (40), in which

at least one of the plurality of curved mirrors has a concave curve shape in a cut end cut in a plane orthogonal to a fourth axis direction orthogonal to both the first axis direction and the third axis direction, and

0°<α≤90° is satisfied where an angle formed by a tangent line at each end of a concave curve drawn by the cut end and a line segment connecting both ends of the concave curve is α/2.

(42) The light source device according to any one of (31) to (39), in which

at least one of the plurality of curved mirrors has a concave curve shape in a cut end cut in a plane orthogonal to the first axis direction, and

0°<β≤90°−φ is satisfied where an angle formed by a tangent line at each end of a concave curve drawn by the cut end and a line segment connecting both ends of the concave curve is β/2, and an angle formed by a fourth axis direction orthogonal to both the first axis direction and the third axis direction as viewed from the first axis direction with respect to the reference plane is 90°−φ.

(43) The light source device according to any one of (31) to (38), in which

at least one of the plurality of curved mirrors has a concave curve shape in a cut end cut in a plane orthogonal to a fourth axis direction orthogonal to both the first axis direction and the third axis direction, and

0°<α≤90° is satisfied where an angle formed by a tangent line at each end of a concave curve drawn by the cut end and a line segment connecting both ends of the concave curve is α/2, and

at least one of the plurality of curved mirrors has a concave curve shape in a cut end cut in a plane orthogonal to the first axis direction, and

0°<β≤90°−φ is satisfied where an angle formed by a tangent line at each end of a concave curve drawn by the cut end and a line segment connecting both ends of the concave curve is β/2, and an angle formed by the fourth axis direction orthogonal to both the first axis direction and the third axis direction as viewed from the first axis direction with respect to the reference plane is 90°−φ.

(44) The light source device according to any one of (39) to (43), in which the cut end has an arc shape.

(45) The light source device according to any one of (31) to (44), in which, in the plurality of curved mirrors, ratios of a length in a fourth axis direction orthogonal to both the first axis direction and the third axis direction with respect to a length in the first axis direction in the shape viewed from the third axis direction are equal to each other.

(46) The light source device according to (45), in which, in the plurality of curved mirrors, lengths in the first axis direction are equal to each other and lengths in the fourth axis direction are equal to each other in the shape viewed from the third axis direction.

(47) The light source device according to any one of (29) to (46), in which the plurality of curved mirrors has curvatures in the first axis direction that are equal to each other and has curvatures in the second axis direction that are equal to each other.

(48) The light source device according to any one of (29) to (47), further including: a collimator lens arranged on an optical path between the light source and the reflection member.

(49) The light source device according to any one of (29) to (48), in which the light source is a laser light source.

(50) A distance measuring device including:

the light source device according to any one of (29) to (49);

a light receiving device configured to receive light emitted from the light source device and reflected by an object; and

a control device configured to calculate a distance to the object on the basis of an output of the light receiving device.

(51) The distance measuring device according to (50), in which the light receiving device includes an image sensor, and the target shape approximately coincides with a shape of a pixel arrangement region of the image sensor.

(52) The distance measuring device according to (50) or (51), in which the shape of the pixel arrangement region is rectangular.

(53) An object system including:

the distance measuring device according to any one of (50) to (52); and an object on which the distance measuring device is mounted.

(54) An image display device including: the light source device according to any one of (29) to (49), in which the light source emits light modulated according to image information.

(55) A method of manufacturing a reflection member including a plurality of convex mirrors or concave mirrors that incident light enters, and reflects the incident light to generate reflected light, the method including the steps of:

applying a resist on one surface of a base material to form a plurality of resist patterns;

melting each of the plurality of resist patterns to be formed into a dome shape by surface tension;

performing etching by applying an etching gas to the plurality of resist patterns in the dome shape from a direction inclined with respect to the one surface to form a plurality of convex surfaces or concave surfaces in a shape according to a target shape of a cross section perpendicular to an optical axis of the reflected light as viewed from the inclined direction; and

forming a reflection film on each of the plurality of convex surfaces or concave surfaces.

### REFERENCE SIGNS LIST

10, 100 Distance measuring device
12, 122, 123, 123A, 124, 125, 126, 127 Light source unit (light source device)
14, 147 Light receiving unit (light receiving device)
16 Control unit (control device)
20 Light source
24, 240 Holder
24a, 240a Recess
26a Mounting surface (bottom surface of recess)
24a1, 240a1 Opening of recess
22, 220, 2200, 2200A, 2200B, 22A, 22B Diffuse reflection member (diffuse reflection portion reflection member)
22a, 220a, 2200a, 280a1, 22Aa, 22Ba Diffuse reflection surface
28, 2800 Peripheral wall
30 Transmissive member (window)
40 Light receiving element
380 Image sensor (sensor)
RA First light receiving region
RB Second light receiving region
ED Emission direction
ES Emission surface
θ Inclination angle
22c Convex mirror (curved mirror)
220c Concave mirror (curved mirror)
2200Ack, 2200Bck Curved mirror
22d, 220d, 2200Ad, 2200Bd Reference plane
23 Collimator lens
38, 380 Image sensor
RL Reflected light
EOAD Optical axis direction of emitted light (optical axis direction of light from light source)
ROA Optical axis of reflected light
TS Target shape

1. A light source unit comprising:
a light source; and
a holder configured to hold the light source, wherein
the holder has a diffuse reflection surface that reflects and diffuses at least part of light from the light source toward an object.

2. The light source unit according to claim 1, wherein
the holder has a recess in which the light source is housed, and
the diffuse reflection surface is located in the recess, and reflects and diffuses the at least part of light from the light source toward an opening of the recess.

3. The light source unit according to claim 2, wherein the holder has a window that covers the opening of the recess.

4. The light source unit according to claim 1, wherein the diffuse reflection surface is inclined with respect to an emission direction of the light source.

5. The light source unit according to claim 4, wherein an inclination angle of the diffuse reflection surface with respect to the emission direction of the light source is 30° to 60°.

6. The light source unit according to claim 4, wherein an emission surface of the light source and the diffuse reflection surface face each other.

7. The light source unit according to claim 6, wherein the light emitted from the light source directly enters the diffuse reflection surface.

8. The light source unit according to claim 2, wherein
the light source is provided on a bottom surface of the recess, and
an angle made by an emission direction of the light source with respect to the bottom surface is 0° to 45°.

9. The light source unit according to claim 8, wherein the diffuse reflection surface is located between the light source and a part of a peripheral wall of the recess.

10. The light source unit according to claim 9, wherein the peripheral wall of the recess has a light-shielding property.

11. The light source unit according to claim 9, wherein at least a part of an inner peripheral surface of the peripheral wall of the recess has a light attenuation function.

12. The light source unit according to claim 2, wherein the diffuse reflection surface is provided on the peripheral wall of the recess.

13. The light source unit according to claim 3, wherein the diffuse reflection surface is provided on the window.

14. The light source unit according to claim 2, wherein the diffuse reflection surface is provided on a bottom surface of the recess.

15. The light source unit according to claim 1, wherein
the holder includes a diffuse reflection portion having the diffuse reflection surface, and
at least one surface of the diffuse reflection portion other than the diffuse reflection surface has a light attenuation function.

16. The light source unit according to claim 11, wherein the light attenuation function is implemented by any one of fine unevenness processing, an antireflection film, and black coating.

17. The light source unit according to claim 3, wherein
the holder includes a diffuse reflection portion having the diffuse reflection surface, and
the light source unit further comprises a light receiving element that receives at least part of light emitted from the light source and through the diffuse reflection portion.

18. The light source unit according to claim 1, wherein the light source is a laser light source.

19. A distance measuring device comprising:
the light source unit according to claim 1;
a light receiving unit configured to receive light emitted from the light source unit and reflected by an object; and
a control unit configured to calculate a distance to the object on a basis of at least an output of the light receiving unit.

20. The distance measuring device according to claim 19, wherein the light receiving unit includes a sensor having a first light receiving region that receives light emitted from the light source unit and reflected by an object and a second light receiving region that receives light emitted from the light source and through the diffuse reflection surface.

21. A light source device comprising:
a light source; and
a reflection member configured to reflect at least part of light from the light source to generate reflected light, wherein
the reflection member includes a plurality of curved mirrors regularly arranged along a reference plane that the light from the light source enters, and
each of the plurality of curved mirrors has curvatures in a first axis direction and a second axis direction orthogonal to each other in the reference plane.

22. The light source device according to claim 21, wherein the plurality of curved mirrors is regularly arranged according to a target shape of a cross section perpendicular to an optical axis of the reflected light.

23. The light source device according to claim 21, wherein each of the plurality of curved mirrors is inclined with respect to the reference plane, and a shape viewed from a third axis direction orthogonal to the first axis direction is a shape according to the target shape of a cross section perpendicular to an optical axis of the reflected light.

24. The light source device according to claim 23, wherein the third axis direction approximately coincides with an optical axis direction of the light from the light source.

25. The light source device according to claim 23, wherein, in each of the plurality of curved mirrors, a length in the first axis direction of the shape viewed from the third axis direction, a length in a fourth axis direction orthogonal to both the first axis direction and the third axis direction in the shape viewed from the third axis direction, a curvature in the first axis direction, and a curvature in the second axis direction are set according to a ratio of a length in a direction corresponding to the first axis direction and a length in a direction corresponding to the fourth axis direction in the target shape.

26. The light source device according to claim 23, wherein, in each of the plurality of curved mirrors, a ratio of a length in a fourth axis direction orthogonal to both the first axis direction and the third axis direction to a length in the first axis direction in the shape viewed from the third axis direction is equal to a ratio of a length in a direction corresponding to the fourth axis direction to a length in a direction corresponding to the first axis direction in the target shape, the curvatures in the first axis direction are equal to each other, and the curvatures in the second axis direction are equal to each other.

27. The light source device according to claim 23, wherein the plurality of curved mirrors is at least three curved mirrors and is two-dimensionally arranged as viewed from the third axis direction.

28. The light source device according to claim 27, wherein the plurality of curved mirrors is at least four curved mirrors and is arranged in a two-dimensional grid manner in the first axis direction and in a fourth axis direction orthogonal to both the first axis direction and the third axis direction as viewed from the third axis direction.

29. The light source device according to claim 28, wherein the plurality of curved mirrors includes the curved mirrors having curvatures with opposite positive and negative properties in the first axis direction and the second axis direction.

30. The light source device according to claim 29, wherein
the positive and negative properties of the curvatures in the first axis direction of at least the two curved mirrors arranged in the fourth axis direction as viewed from the third axis direction are equal to each other, and
the positive and negative properties of the curvatures in the second axis direction of at least the two curved mirrors arranged in the first axis direction as viewed from the third axis direction are equal to each other.

31. The light source device according to claim 23, wherein
at least one of the plurality of curved mirrors has a convex curve shape in a cut end cut in a plane orthogonal to a fourth axis direction orthogonal to both the first axis direction and the third axis direction, and
0°<α≤60° is satisfied where an angle formed by a tangent line at each end of a convex curve drawn by the cut end and a line segment connecting both ends of the convex curve is α/2.

32. The light source device according to claim 23, wherein
at least one of the plurality of curved mirrors has a convex curve shape in a cut end cut in a plane orthogonal to the first axis direction, and
0°<β≤60°−(⅔)ρ is satisfied where an angle formed by a tangent line at each end of a convex curve drawn by the cut end and a line segment connecting both ends of the convex curve is β/2, and an angle formed by a fourth axis direction orthogonal to both the first axis direction and the third axis direction as viewed from the first axis direction with respect to the reference plane is 90°−φ.

33. The light source device according to claim 23, wherein
at least one of the plurality of curved mirrors has a concave curve shape in a cut end cut in a plane orthogonal to a fourth axis direction orthogonal to both the first axis direction and the third axis direction, and
0°<α≤90° is satisfied where an angle formed by a tangent line at each end of a concave curve drawn by the cut end and a line segment connecting both ends of the concave curve is α/2.

34. The light source device according to claim 23, wherein
at least one of the plurality of curved mirrors has a concave curve shape in a cut end cut in a plane orthogonal to the first axis direction, and
0°<β≤90°−φ is satisfied where an angle formed by a tangent line at each end of a concave curve drawn by the cut end and a line segment connecting both ends of the concave curve is β/2, and an angle formed by a fourth axis direction orthogonal to both the first axis direction and the third axis direction as viewed from the first axis direction with respect to the reference plane is 90°−φ.

35. The light source device according to claim 31, wherein the cut end has an arc shape.

36. The light source device according to claim 21, wherein the plurality of curved mirrors has curvatures in the first axis direction that are equal to each other and has curvatures in the second axis direction that are equal to each other.

37. The light source device according to claim 23, wherein, in the plurality of curved mirrors, ratios of a length in a fourth axis direction orthogonal to both the first axis direction and the third axis direction with respect to a length in the first axis direction in the shape viewed from the third axis direction are equal to each other.

38. The light source device according to claim 37, wherein, in the plurality of curved mirrors, lengths in the first axis direction are equal to each other and lengths in the fourth axis direction are equal to each other in the shape viewed from the third axis direction.

39. The light source device according to claim 21, wherein the light source is a laser light source.

40. A distance measuring device comprising:
the light source device according to claim 21;
a light receiving device configured to receive light emitted from the light source device and reflected by an object; and
a control device configured to calculate a distance to the object on a basis of an output of the light receiving device.
